(19) United States
(12) Patent Application Publication
(10) Pub. No.: US 2022/0181554 A1
(43) Pub. Date: Jun. 9, 2022

(54) SOLID-STATE IMAGING ELEMENT, METHOD FOR MANUFACTURING SOLID-STATE IMAGING ELEMENT, AND SOLID-STATE IMAGING APPARATUS

(71) Applicants: Sony Group Corporation, Tokyo (JP); Sony Semiconductor Solutions Corporation, Kanagawa (JP)

(72) Inventors: Yosuke SAITO, Tokyo (JP); Takashi OOE, Kanagawa (JP); Yushiro NAKAGOME, Kanagawa (JP)

(21) Appl. No.: 17/599,381

(22) PCT Filed: Mar. 16, 2020
(86) PCT No.: PCT/JP2020/011450

§ 371 Date: Sep. 28, 2021

(30) Foreign Application Priority Data
Mar. 28, 2019 (JP) 2019-062398

(51) Int. Cl. H01L 51/00; H01L 27/30

(52) U.S. Cl. CPC H01L 51/0055; H01L 27/307; H01L 51/4246; H01L 51/0068; H01L 51/0047

(57) ABSTRACT

The present technology relates to a solid-state imaging element, a method for manufacturing a solid-state imaging element, and a solid-state imaging apparatus, capable of improving blue light photoelectric conversion efficiency of an organic photoelectric conversion element.

An organic photoelectric conversion layer is formed by mixing a first organic semiconductor containing a perylene derivative having characteristics of absorbing blue light, a second organic semiconductor having characteristics of absorbing blue light and also having characteristics as a hole transport material having crystallinity, and a third organic semiconductor containing a fullerene derivative. The present technology can be applied to a solid-state imaging element.

### TECHNICAL FIELD

The present technology relates to a solid-state imaging element, a method for manufacturing a solid-state imaging element, and a solid-state imaging apparatus, particularly to a solid-state imaging element, a method for manufacturing a solid-state imaging element, and a solid-state imaging apparatus, capable of achieving photoelectric conversion of blue light with high efficiency.

### BACKGROUND ART

An imaging element called a longitudinal spectroscopic solid-state imaging element, which is required to have high color reproducibility, is desired.

As this longitudinal spectroscopic solid-state imaging element, in recent years, a longitudinal spectroscopic solid-state imaging element having a multilayer structure in which film-like photoelectric conversion films containing an organic material are laminated has been proposed.

For example, a solid-state imaging element in which organic photoelectric conversion films using an organic material containing a perylene derivative are laminated has been proposed (see Patent Document 1).

### CITATION LIST

### Patent Document

Patent Document 1: Japanese Patent Application Laid-Open No. 2010-141140

### SUMMARY OF THE INVENTION

### Problems to be Solved by the Invention

However, in the organic photoelectric conversion film using an organic material containing a perylene derivative in Patent Document 1 described above, blue photoelectric conversion efficiency cannot be sufficiently ensured.

The present technology has been achieved in view of such a situation, and particularly achieves an organic photoelectric conversion film containing an organic material using a perylene derivative, capable of selectively photoelectrically converting blue light with high efficiency.

### Solutions to Problems

A solid-state imaging element and a solid-state imaging apparatus according to a first aspect of the present technology each include an organic photoelectric conversion element including at least two electrodes, an organic photoelectric conversion layer is disposed between the two electrodes, the organic photoelectric conversion layer includes at least a first organic semiconductor, a second organic semiconductor, and a third organic semiconductor, the first organic semiconductor is a perylene derivative having characteristics of absorbing blue light and represented by the following chemical formula (11), the second organic semiconductor is a semiconductor having characteristics of absorbing blue light and also having characteristics as a hole transport material having crystallinity, the third organic semiconductor is a fullerene derivative, and R1 to R12 in the chemical formula (11) are each independently selected from the group consisting of a hydrogen atom, a halogen atom, a linear, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, an aryl group, a heteroaryl group, a carboxy group, a carboxoamide group, a carboalkoxy group, an acyl group, a sulfonyl group, a cyano group, and a nitro group.

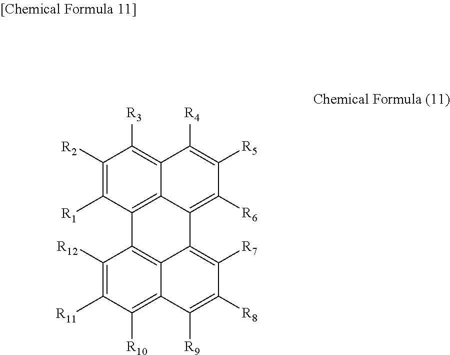

In the first aspect of the present technology, an organic photoelectric conversion element including at least two electrodes is disposed, an organic photoelectric conversion layer is disposed between the two electrodes, the organic photoelectric conversion layer includes at least a first organic semiconductor, a second organic semiconductor, and a third organic semiconductor, the first organic semiconductor is a perylene derivative having characteristics of absorbing blue light and represented by the above-described chemical formula (11), the second organic semiconductor is a semiconductor having characteristics of absorbing blue light and also having characteristics as a hole transport material having crystallinity, the third organic semiconductor is a fullerene derivative, and R1 to R12 in the chemical formula (11) are each independently selected from the group consisting of a hydrogen atom, a halogen atom, a linear, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, an aryl group, a heteroaryl group, a carboxy group, a carboxoamide group, a carboalkoxy group, an acyl group, a sulfonyl group, a cyano group, and a nitro group.

A method for manufacturing a solid-state imaging element according to a second aspect of the present technology includes: a first step of forming a first electrode; a second step of forming an organic photoelectric conversion layer on an upper layer of the first electrode; and a third step of forming a second electrode on the organic photoelectric conversion layer, in which the organic photoelectric conversion layer includes at least a first organic semiconductor, a second organic semiconductor, and a third organic semiconductor, the first organic semiconductor is a perylene derivative having characteristics of absorbing blue light and represented by the above-described chemical formula (11), the second organic semiconductor is a semiconductor having characteristics of absorbing blue light and also having characteristics as a hole transport material having crystallinity, and the third organic semiconductor is a fullerene derivative.

In the second aspect of the present technology, a first electrode is formed in a first step, an organic photoelectric conversion layer is formed on an upper layer of the first electrode in a second step, a second electrode is formed on an upper layer of the organic photoelectric conversion layer in a third step, the organic photoelectric conversion layer includes at least a first organic semiconductor, a second organic semiconductor, and a third organic semiconductor, the first organic semiconductor is a perylene derivative having characteristics of absorbing blue light and represented by the above-described chemical formula (11), the second organic semiconductor is a semiconductor having characteristics of absorbing blue light and also having characteristics as a hole transport material having crystallinity, and the third organic semiconductor is a fullerene derivative.

### BRIEF DESCRIPTION OF DRAWINGS

FIG. 1 is a diagram for explaining a configuration example of an embodiment of a solid-state imaging apparatus to which the present technology is applied.

FIG. 2 is a diagram for explaining a configuration example of an embodiment of a solid-state imaging element of FIG. 1.

FIG. 3 is a diagram for explaining a configuration example of the solid-state imaging element of FIG. 2.

FIG. 4 is a diagram for explaining a configuration example of an organic photoelectric conversion element that photoelectrically converts blue light.

FIG. 5 is a flowchart for explaining a method for manufacturing an organic photoelectric conversion element.

FIG. 6 is a diagram for explaining a configuration example of an evaluation element.

FIG. 7 is a diagram for explaining an example of characteristics of an organic material layer according to a combination of materials of a first organic semiconductor, a second organic semiconductor, and a third organic semiconductor.

FIG. 8 is a schematic diagram for explaining a structure of a solid-state imaging element to which a photoelectric conversion element according to the present technology is applied.

FIG. 9 is a block diagram for explaining a configuration of an electronic apparatus to which the photoelectric conversion element according to the present technology is applied.

FIG. 10 is a diagram illustrating an example of a schematic configuration of an endoscopic surgical system.

FIG. 11 is a block diagram illustrating examples of functional configurations of a camera head and a CCU.

FIG. 12 is a block diagram illustrating an example of a schematic configuration of a vehicle control system.

FIG. 13 is an explanatory diagram illustrating examples of installation positions of a vehicle external information detection unit and an imaging unit.

### MODE FOR CARRYING OUT THE INVENTION

<Configuration Example of Embodiment of Solid-State Imaging Apparatus to which Present Technology is Applied>

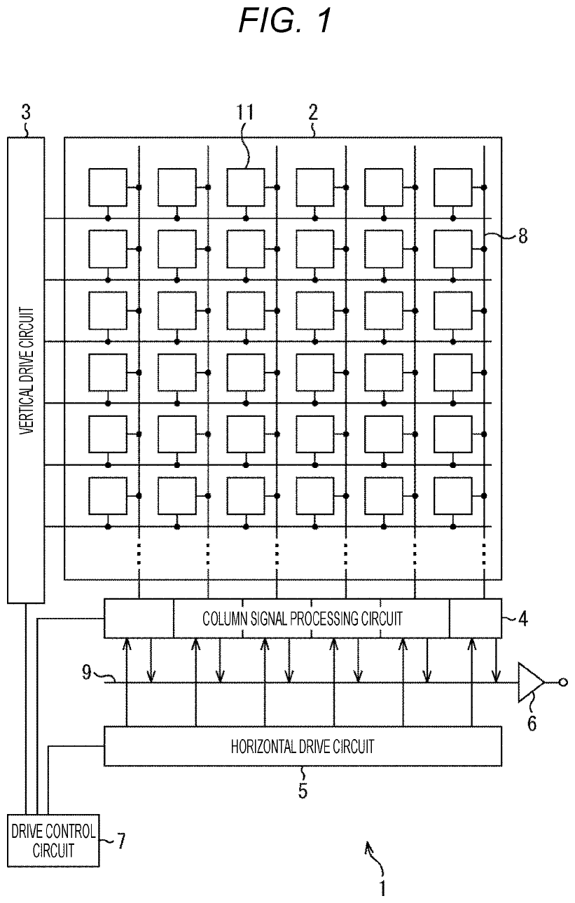

FIG. 1 illustrates a configuration example of an embodiment of a solid-state imaging apparatus to which the present technology is applied. A solid-state imaging apparatus 1 of FIG. 1 includes an imaging region 2 in which laminated solid-state imaging elements 11 are arrayed two-dimensionally, and a vertical drive circuit 3, a column signal processing circuit 4, a horizontal drive circuit 5, an output circuit 6, a drive control circuit 7, and the like as drive circuits (peripheral circuits) of the laminated solid-state imaging elements 11.

Note that these circuits can be constituted by known circuits, and furthermore, can be constituted using other circuit configurations (for example, various circuits used in a conventional charge coupled device (CCD) imaging apparatus and a complementary metal oxide semiconductor (CMOS) imaging apparatus).

The drive control circuit 7 generates a clock signal or a control signal as a reference of actions of the vertical drive circuit 3, the column signal processing circuit 4, and the horizontal drive circuit 5 on the basis of a vertical synchronizing signal, a horizontal synchronizing signal, and a master clock. Then, the generated clock signal or control signal is input to the vertical drive circuit 3, the column signal processing circuit 4, and the horizontal drive circuit 5.

For example, the vertical drive circuit 3 is constituted by a shift register, and sequentially selects and scans the solid-state imaging elements 11 in the imaging region 2 in a row unit in a vertical direction. Then, a pixel signal (image signal) based on a current (signal) generated according to the amount of light received by each of the solid-state imaging elements 11 is sent to the column signal processing circuit 4 via a signal line (data output line) 8 and a vertical signal transfer line (VSL).

For example, the column signal processing circuit 4 is disposed for each column of the solid-state imaging elements 11. Image signals output from the solid-state imaging elements 11 in one row are subjected to signal processing such as noise removal or signal amplification with a signal from a black reference pixel (not illustrated, but formed around an effective pixel region) for each of the imaging elements. In an output stage of the column signal processing circuit 4, a horizontal selection switch (not illustrated) is connected and disposed between the column signal processing circuit 4 and a horizontal signal line 9.

For example, the horizontal drive circuit 5 is constituted by a shift register. By sequentially outputting a horizontal scanning pulse, the horizontal drive circuit 5 sequentially selects each of the column signal processing circuits 4, and outputs a signal from each of the column signal processing circuits 4 to the horizontal signal line 9.

The output circuit 6 performs signal processing to a signal sequentially supplied from each of the column signal processing circuits 4 via the horizontal signal line 9, and outputs the signal.

<Configuration Example of Embodiment of Solid-State Imaging Element of FIG. 1>

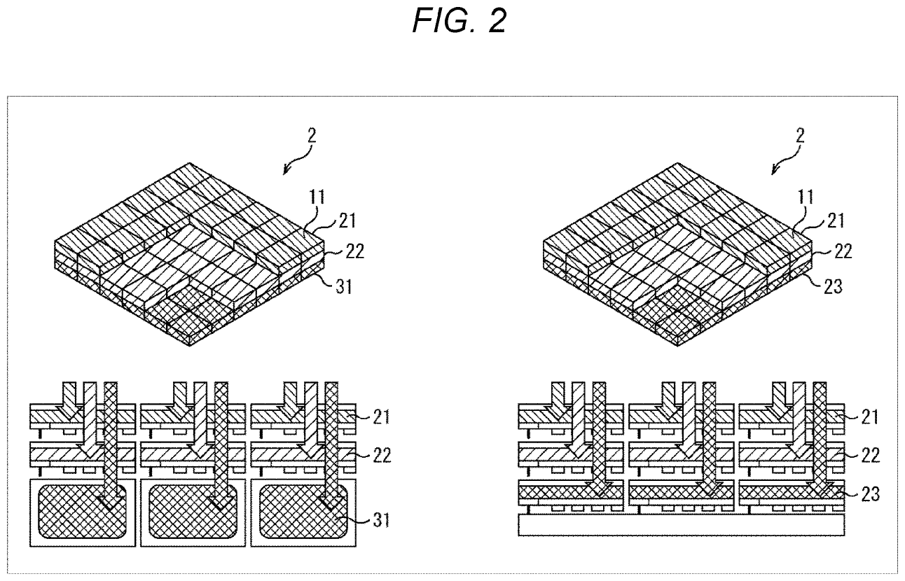

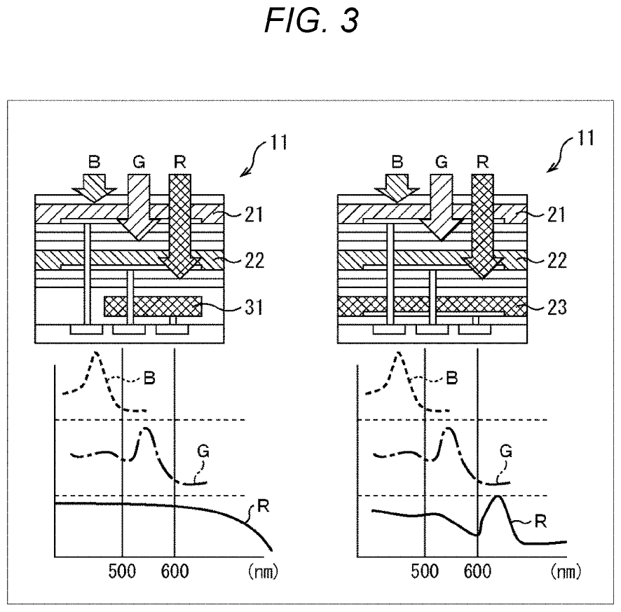

Each of FIGS. 2 and 3 is a diagram illustrating a configuration example of an embodiment of the longitudinal spectroscopic solid-state imaging element 11 using an organic photoelectric conversion film applied to the solid-state imaging apparatus of FIG. 1.

Examples of the configuration example of the longitudinal spectroscopic solid-state imaging element using the organic photoelectric conversion film include two types of configurations including a first solid-state imaging element 11 and a second solid-state imaging element 11 illustrated in the left part and the right part of FIG. 2, respectively. In either of the two types of configurations, a photoelectric conversion element constituted by either a photoelectric conversion element or a photodiode is laminated from a light source in an upper portion in FIGS. 2 and 3 toward a lower portion in the drawings.

More specifically, as illustrated in a lower left part of FIG. 2 and an upper left part of FIG. 3, in the first solid-state imaging element 11, photoelectric conversion elements 21 and 22 constituted by organic photoelectric conversion films that photoelectrically convert B (blue) light and G (green) light, respectively are disposed in order from an uppermost layer, and a photoelectric conversion element 31 constituted by a R (red) silicon photodiode is laminated below the photoelectric conversion elements 21 and 22.

With such a configuration, as illustrated in a lower left part of FIG. 3, photoelectric conversion is sequentially performed by the photoelectric conversion elements 21 and 22 with light in B (blue) and G (green) wavelength bands in an ascending order of the wavelength bands. Thereafter, photoelectric conversion is performed by the photoelectric conversion element 31 with R (red) light. As a result, RGB (red, green, and blue) is separated in a longitudinal direction to perform photoelectric conversion.

Furthermore, as illustrated in a lower right part of FIG. 2 and an upper right part of FIG. 3, in the second solid-state imaging element 11, photoelectric conversion elements 21, 22, and 23 constituted by organic photoelectric conversion films that photoelectrically convert B (blue) light, G (green) light, and R (red) light, respectively are laminated in order from an uppermost layer.

With such a configuration, as illustrated in a lower right part of FIG. 3, photoelectric conversion is sequentially performed by the photoelectric conversion elements 21, 22, and 23 with light in B (blue), G (green), and R (red) wavelength bands in an ascending order of the wavelength bands. As a result, RGB (red, green, and blue) is separated in a longitudinal direction to generate an image signal.

More specifically, as indicated by dotted waveforms in a lower left part and a lower right part of FIG. 3, the photoelectric conversion element 21 selectively absorbs light having a wavelength of about 400 to 500 nm and generally classified as blue light, and generates charges by photoelectric conversion.

Furthermore, as indicated by alternate long and short dash waveforms in a lower left part and a lower right part of FIG. 3, the photoelectric conversion element 22 selectively absorbs light having a wavelength of about 500 to 600 nm and generally classified as green light, and generates charges by photoelectric conversion.

Moreover, as indicated by solid waveforms in a lower left part and a lower right part of FIG. 3, the photoelectric conversion element 23 or the photoelectric conversion element 31 selectively absorbs light having a wavelength of about 600 nm or more and generally classified as red light, and generates charges by photoelectric conversion.

Note that, in a lower part of FIG. 3, the horizontal axis in the drawing indicates the wavelength of incident light, and the vertical axis indicates the amount of charges generated by photoelectric conversion.

<Configuration Example of Photoelectric Conversion Element that Photoelectrically Converts Blue Light>

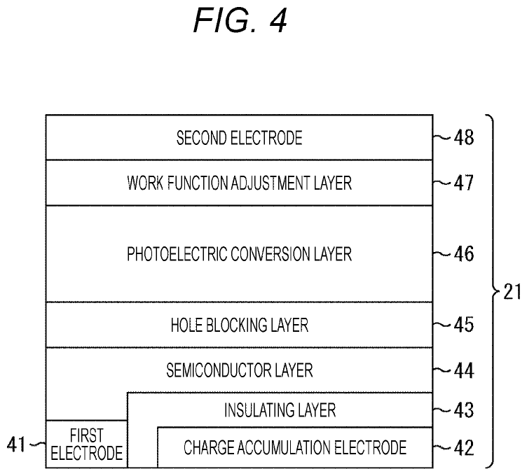

Next, a configuration example of the photoelectric conversion element 21 constituted by an organic photoelectric conversion film will be described with reference to FIG. 4.

The photoelectric conversion element 21 has a configuration in which a first electrode 41, a charge accumulation electrode 42, an insulating layer 43, a semiconductor layer 44, a hole blocking layer 45, a photoelectric conversion layer 46, a work function adjustment layer 47, and a second electrode 48 are laminated as illustrated in FIG. 4. Note that, although not illustrated, the photoelectric conversion element 21 is laminated on a semiconductor substrate including a floating diffusion amplifier for signal reading, a transfer transistor, an amplifier transistor, and multilayer wiring. Furthermore, optical members such as a protective layer, a planarization layer, and an on-chip lens are disposed on a light incident side of the photoelectric conversion element 21.

The first electrode 41 and the charge accumulation electrode 42 are each constituted by a light-transmitting conductive film, for example, indium tin oxide (ITO). However, as a constituent material of each of the first electrode 41 and the charge accumulation electrode 42, in addition to the ITO, a tin oxide (SnO₂)-based material to which a dopant is added or a zinc oxide-based material obtained by adding a dopant to aluminum zinc oxide (ZnO) may be used. Examples of the zinc oxide-based material include aluminum zinc oxide (AZO) doped with aluminum (Al), gallium zinc oxide (GZO) doped with gallium (Ga), and indium zinc oxide (IZO) doped with indium (In). Furthermore, in addition to these materials, CuI, InSbO₄, ZnMgO, CuInO₂, MgIN₂O₄, CdO, ZnSnO₃, and the like may be used. The insulating layer 43 is formed so as to surround the charge accumulation electrode 42.

The semiconductor layer 44 is disposed between the insulating layer 43 and the hole blocking layer 45 for accumulating signal charges (here, electrons) generated in the photoelectric conversion layer 46. In the present embodiment, electrons are used as signal charges. Therefore, the semiconductor layer 44 is preferably formed using an n-type semiconductor material. For example, it is preferable to use a material having an energy level shallower than the work function of the semiconductor layer 44 at a lowermost end of a conduction band. Examples of such an n-type semiconductor material include In—Ga—Zn—O-based oxide semiconductor (IGZO), Zn—Sn—O-based oxide semiconductor (ZTO), In—Ga—Zn—Sn—O-based oxide semiconductor (IGZTO), Ga—Sn—O-based oxide semiconductor (GTO), and In—Ga—O-based oxide semiconductor (IGO). For the semiconductor layer 44, it is preferable to use at least one of the oxide semiconductor materials described above. Among the materials, IGZO is preferably used. The thickness of the semiconductor layer 44 is, for example, 30 nm or more and 200 nm or less, and preferably 60 nm or more and 150 nm or less. By disposing the semiconductor layer 44 containing the above material below the hole blocking layer 45, it is possible to prevent charge recombination at the time of charge accumulation and to improve transfer efficiency.

The hole blocking layer 45 is disposed between the semiconductor layer 44 and the photoelectric conversion layer 46 for transferring signal charges (here, electrons) generated in the photoelectric conversion layer 46 to the semiconductor layer 44, and preventing hole injection from the semiconductor layer 44 to the photoelectric conversion layer 46.

The hole blocking layer 45 contains, for example, substance (1) (4,6-Bis(3,5 di(pyridin-4-yl) phenyl)-2-methylpyrimidine (B4PyMPM)) represented by the following chemical formula (1).

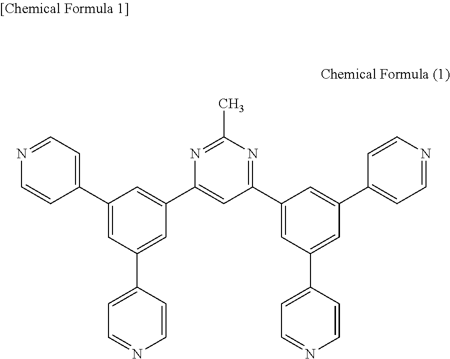 [SMILES: Cc1nc(-c2cc(-c3ccncc3)cc(-c3ccncc3)c2)cc(-c2cc(-c3ccncc3)cc(-c3ccncc3)c2)n1]

In the present embodiment, the hole blocking layer 45 uses electrons as signal charges. Therefore, the hole blocking layer 45 is preferably formed using an n-type semiconductor material. For example, it is preferable to use a material having an electron affinity equal to the electron affinity at a lower end of a conductor of the semiconductor layer 44, or having an energy level shallower than the energy level at the lower end of the conductor of the semiconductor layer 44. Examples of such an n-type semiconductor material constituting the hole blocking layer 45 include a naphthalene diimide derivative, a triazine derivative, and a fullerene derivative in addition to substance (1) (B4PyMPM).

The photoelectric conversion layer 46 is constituted by a mixed layer including a first organic semiconductor, a second organic semiconductor, and a third organic semiconductor, and generates electrons and holes (charges) by photoelectric conversion according to the amount of blue light.

The first organic semiconductor is a semiconductor that absorbs blue light and generates electrons and holes (charges) by photoelectric conversion, and is, for example, substance (2) (Solvent Green 5 (SG5)) represented by the following chemical formula (2).

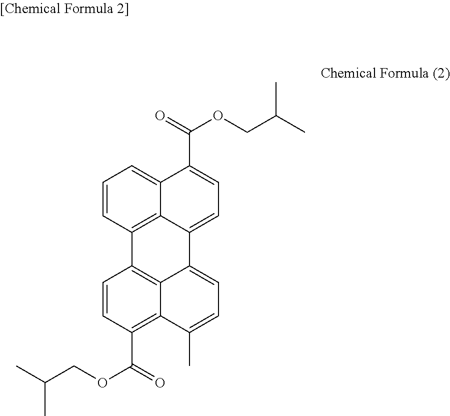 [SMILES: Cc1ccc2c3ccc(C(=O)OCC(C)C)c4cccc(c5ccc(C(=O)OCC(C)C)c1c25)c43]

The second organic semiconductor is a hole transport material that absorbs blue light and transports holes, has crystallinity, and is, for example, substance (3) (compound a: Benzo[1,2-b:4,5-b′] dithiophene, 2,6-bis([1,1′-biphenyl]-4-yl)-) represented by the following chemical formula (3).

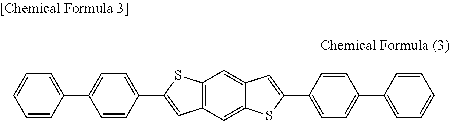 [SMILES: c1ccc(-c2ccc(-c3cc4cc5sc(-c6ccc(-c7ccccc7)cc6)cc5cc4s3)cc2)cc1]

The third organic semiconductor is a fullerene derivative, and is, for example, substance (4) (C60) represented by the following chemical formula (4).

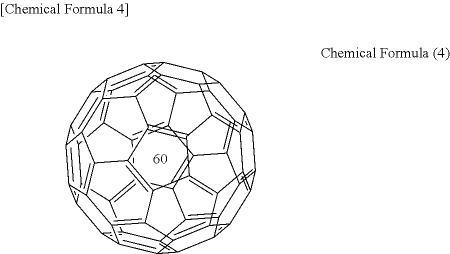

The work function adjustment layer 47 is disposed between the photoelectric conversion layer 46 and the second electrode 48 for changing an internal electric field in the photoelectric conversion layer 46 to promptly transfer and accumulate signal charges generated in the photoelectric conversion layer 46 to the semiconductor layer 44. The work function adjustment layer 47 has a light-transmitting property and preferably has, for example, a light absorption ratio of 10% or less with respect to visible light. Furthermore, the work function adjustment layer 47 is preferably formed using a carbon-containing compound having an electron affinity larger than the work function of the semiconductor layer 44. Examples of such a material include a tetracyanoquinodimethane derivative, a hexaazatriphenylene derivative, a hexaazatrinaphthylene derivative, a phthalocyanine derivative, and a fluorinated fullerene such as C60F36 or C60F48. Alternatively, the work function adjustment layer 47 is preferably formed using an inorganic compound having a work function larger than the work function of the charge accumulation electrode 42. Examples of such a material include a transition metal oxide such as molybdenum oxide (MoO₃), tungsten oxide (WO₃), vanadium oxide (V₂O₅), or rhenium oxide (ReO₃), and a salt such as copper iodide (CuI), antimony chloride (SbCl₅), iron oxide (FeCl₃), or sodium chloride (NaCl).

Another layer may be disposed between the photoelectric conversion layer 46 and the second electrode 48 (for example, between the photoelectric conversion layer 46 and the work function adjustment layer 47) or between the photoelectric conversion layer 46 and the charge accumulation electrode 42. Specifically, for example, an electron blocking layer may be laminated between the photoelectric conversion layer 46 and the work function adjustment layer 47. The ionization potential of the electron blocking layer preferably has an energy level shallower than the work function of the work function adjustment layer 47. Furthermore, for example, the electron blocking layer is preferably formed using an organic material having a glass transition point higher than 100° C.

The second electrode 48 is disposed for collecting holes (h+) generated by photoelectric conversion with blue light by the photoelectric conversion layer 46. Similarly to the first electrode 41 and the charge accumulation electrode 42, the second electrode is constituted by a light-transmitting conductive film. In an imaging apparatus using the photoelectric conversion element 21 as one pixel, the second electrode 48 may be separated for each of pixels, or may be formed as an electrode common to the pixels. The thickness of the second electrode 48 is, for example, 10 nm to 200 nm.

In a configuration example of the photoelectric conversion element that photoelectrically converts blue light of the present embodiment, a light incident direction may be either up or down. More specifically, in FIG. 4, light may be incident from either the second electrode 48 side or the charge accumulation electrode 42 side.

Furthermore, the second electrode 48 located on a light incident side may be common to the plurality of solid-state imaging elements 11. That is, the second electrode 48 can be a so-called solid electrode. The photoelectric conversion layer 46 may be common to the plurality of solid-state imaging elements 11. That is, one photoelectric conversion layer 46 may be formed in the plurality of solid-state imaging elements 11, or may be disposed for each of the solid-state imaging elements 11.

Moreover, the photoelectric conversion layer 46 may have a laminated structure including a lower semiconductor layer and an upper photoelectric conversion layer. With the laminated structure, recombination at the time of charge accumulation can be prevented by the lower semiconductor layer, transfer efficiency of charges accumulated in the photoelectric conversion layer 46 to the first electrode 41 can be increased, and generation of a dark current can be suppressed.

<Method for Manufacturing Photoelectric Conversion Element that Photoelectrically Converts Blue Light>

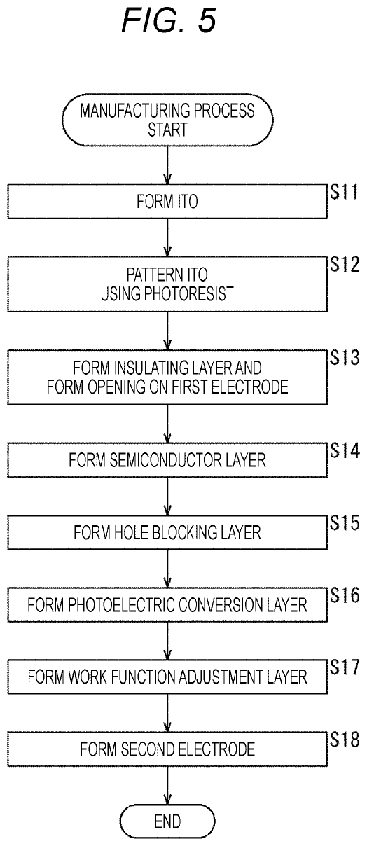

Next, a method for manufacturing a photoelectric conversion element that photoelectrically converts blue light will be described with reference to the flowchart of FIG. 5. In a case where the longitudinal spectroscopic solid-state imaging element as illustrated in FIGS. 2 and 3 is manufactured, a silicon substrate (not illustrated) is usually used. In brief, a circuit layer in which a floating diffusion amplifier, a transfer transistor, an amplifier transistor, and multilayer wiring are formed is formed on a silicon substrate (not illustrated), and photoelectric conversion films that photoelectrically convert R, G, and B light are formed on the circuit layer together with readout wiring. Furthermore, the photoelectric conversion films are insulated from each other by an interlayer insulating film.

In step S11, in an element in which a circuit layer disposed on a silicon substrate (not illustrated), an R layer, and a G layer are laminated in this order, an ITO layer having a predetermined thickness (for example, 100 nm) is formed on an interlayer insulating film on the G layer by sputtering.

In step S12, a photoresist is formed at a predetermined position on the ITO layer. Thereafter, etching is performed to remove the photoresist. As a result, the first electrode 41 and the charge accumulation electrode 42 illustrated in FIG. 4 are patterned.

In step S13, the insulating layer 43 is formed on an interlayer insulating layer, the first electrode 41, and the charge accumulation electrode 42, and then the insulating layer 43 on the first electrode 41 is removed to form an opening on the first electrode 41.

In step S14, the semiconductor layer 44 having a predetermined thickness (for example, 100 nm) is formed on the insulating layer 43 by sputtering.

In step S15, the hole blocking layer 45 is formed on the semiconductor layer 44 by a vacuum deposition method. For example, a substrate 55 is placed on a substrate holder in a vacuum deposition device in a state where the pressure is reduced to 1×10⁻³ Pa or less, and a film of substance (1) (B4PyMPM) is formed so as to have a predetermined thickness on the semiconductor layer 44 at a temperature of 0° C. while the substrate 55 is rotated at a temperature of 0° C. More specifically, the hole blocking layer 45 containing substance (1) (B4PyMPM) is formed so as to have a predetermined thickness of, for example, 5 nm in a state where the substrate 55 is at a temperature of 0° C.

In step S16, the photoelectric conversion layer 46 is formed on the hole blocking layer 45 by a vacuum deposition method. For example, the substrate 55 is placed on a substrate holder in a vacuum deposition device in a state where the pressure is reduced to 1×10⁻⁵ Pa or less, and each of the first organic semiconductor, the second organic semiconductor, and the third organic semiconductor is mixed at a predetermined film formation rate while the substrate 55 is rotated at a temperature of 0° C. to form the photoelectric conversion layer 46 having a predetermined thickness (for example, 200 nm) on the hole blocking layer 45.

In step S17, the work function adjustment layer 47 is formed on the photoelectric conversion layer 46 by a vacuum deposition method. For example, the substrate 55 is placed on a substrate holder in a vacuum deposition device in a state where the pressure is reduced to 1×10⁻³ Pa or less, and a film of substance (5) represented by the following chemical formula (5) (1,4,5,8,9,12 hexaazatriphenylene-2,3,6,7,10,11-hexacarbonitrile) is formed so as to have a predetermined thickness on the photoelectric conversion layer 46 at a temperature of 0° C. while the substrate 55 is rotated at a temperature of 0° C. More specifically, the work function adjustment layer 47 is formed so as to have a predetermined thickness of, for example, 10 nm in a state where the substrate 55 is at a temperature of 0° C.

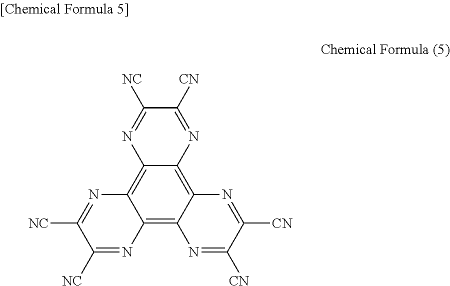

In step S18, a film of ITO is formed so as to have a predetermined thickness (for example, 50 nm) as the second electrode 48.

In the method for manufacturing a photoelectric conversion element that photoelectrically converts blue light described above, the case of the configuration when light is incident from the second electrode 48 side has been described, but this configuration may be vertically inverted. Specifically, the second electrode 48 may be on the substrate 55 side, and light may be incident from the charge accumulation electrode 42 side.

The first organic semiconductor, the second organic semiconductor, and the third organic semiconductor are mixed by the above processing to form the photoelectric conversion layer 46 that reduces absorption of light of colors other than blue, reduces the amount of charges generated by photoelectric conversion of light of colors other than blue, increases absorption of blue light, and increases the amount of charges generated by photoelectric conversion by absorption of blue light.

The characteristics of the photoelectric conversion layer 46 vary depending on a combination and a mixing ratio of materials of the first organic semiconductor, the second organic semiconductor, and the third organic semiconductor. Therefore, it is desirable to form the photoelectric conversion layer 46 with a combination and a mixing ratio of materials of the first organic semiconductor, the second organic semiconductor, and the third organic semiconductor that can more easily absorb blue light, suppress absorption of light of colors other than blue light, and enhance photoelectric conversion efficiency by blue light in the photoelectric conversion layer 46.

(Acquisition of Blue Signal by Photoelectric Conversion Element 21)

Among light beams incident on the first solid-state imaging element 11 or the second solid-state imaging element 11, first, blue light is selectively detected (absorbed) by the photoelectric conversion element 21 and is photoelectrically converted.

As for electrons and holes generated in the photoelectric conversion layer 46, by applying a positive application bias to the charge accumulation electrode 42 side and applying a negative application bias to the second electrode 48 side, the electrons are accumulated in the semiconductor layer 44, and the holes are transferred to the second electrode 48. Furthermore, when electrons are accumulated in the semiconductor layer 44, the potential of the first electrode 41 is made negative with respect to the potential of the charge accumulation electrode 42, and a potential barrier is formed such that electrons do not flow.

Electrons are accumulated in the semiconductor layer 44 for a certain period, the potential of the first electrode 41 is made positive with respect to the potential of the charge accumulation electrode 42. As a result, the electrons are transferred to the first electrode 41 side. The electrons collected by the first electrode are subjected to voltage conversion by, for example, a capacitor unit of a floating diffusion amplifier connected to an end of the first electrode 41, and processed as a pixel signal.

<Example of Characteristics of Organic Material Layer According to Combination of Materials of First Organic Semiconductor, Second Organic Semiconductor, and Third Organic Semiconductor>

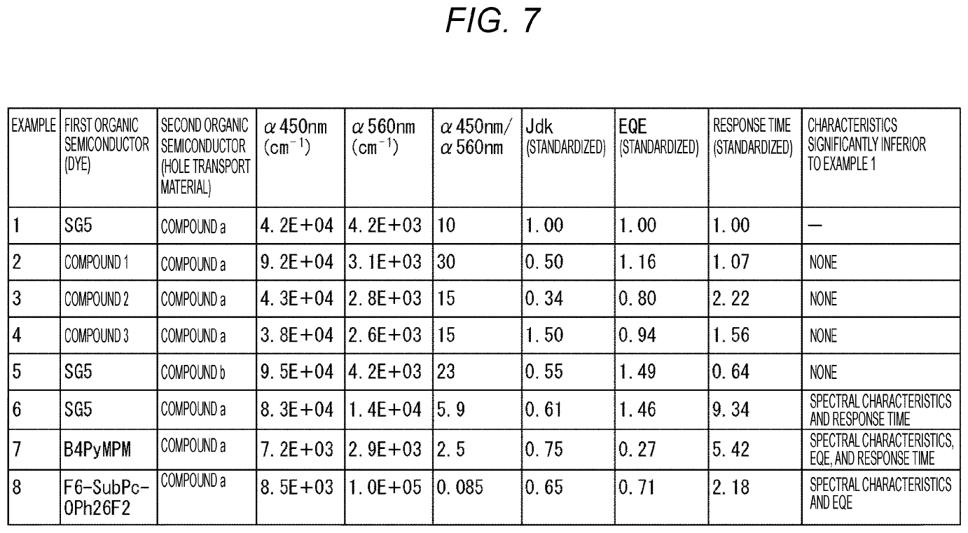

Next, an example of characteristics of the photoelectric conversion layer 46 according to a combination of materials of the first organic semiconductor (dye), the second organic semiconductor (hole transport material), and the third organic semiconductor (fullerene derivative) will be described with reference to FIG. 7.

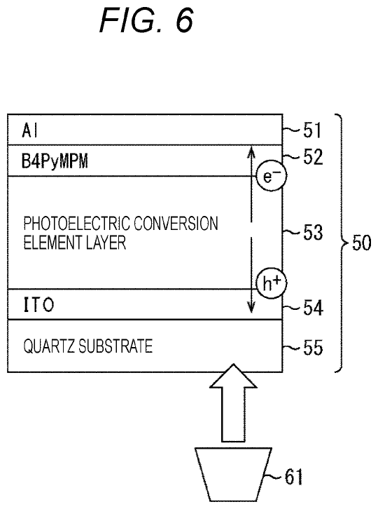

A test cell evaluated here is an evaluation element for simple evaluation. Specifically, the evaluation element has an element structure as illustrated by an evaluation element 50 in FIG. 6, and has a configuration in which a quartz substrate is used as the substrate 55, and an ITO 54 as a second electrode, a photoelectric conversion layer 53, a hole blocking layer 52 containing substance (1) B4PyMPM, and a first electrode 51 containing Al are sequentially laminated on the quartz substrate. Here, the second electrode (ITO) 54, the photoelectric conversion layer 53, the hole blocking layer 52, and the first electrode 51 correspond to the second electrode 48, the photoelectric conversion layer 46, the hole blocking layer 45, and the first electrode 41 in FIG. 3, respectively. That is, the evaluation element 50 has an element structure obtained by removing the charge accumulation electrode 42, the insulating layer 43, the semiconductor layer 44, and the work function adjustment layer 47 from the photoelectric conversion element 21 illustrated in FIG. 3 and vertically inverting the resulting structure.

Furthermore, here, in a case where the dye is substance (2) (Solvent Green 5 (SG5)) represented by chemical formula (2), the hole transport material is substance (3) (compound a) represented by chemical formula (3) or substance (6) (compound b: 2,9-Diphenyl-dinaphtho[2,3-b] naphtho[2′,3′:4,5] thieno[2,3-d] thiophene) represented by the following chemical formula (6), and the fullerene derivative is substance (4) (C60) represented by chemical formula (4), a comparison of characteristics of the photoelectric conversion layer 46 will be described in a case where a mixing ratio is changed by adjusting a film formation rate.

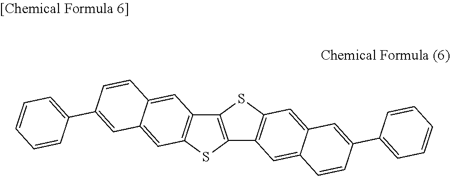 [SMILES: c1ccc(-c2ccc3cc4c(cc3c2)sc2c3cc5ccc(-c6ccccc6)cc5cc3sc42)cc1]

Furthermore, FIG. 7 illustrates characteristics of examples 1 to 7 of the photoelectric conversion layer 46 for comparison in order from the top.

Note that, as for the characteristics of the photoelectric conversion layer 46, as illustrated in FIG. 6, characteristics when blue light (light having a wavelength of 450 nm) is emitted from a light emitting unit 61 disposed in a lower part of the drawing and the electrode 51 is not disposed are illustrated.

Moreover, for each of the examples, an absorption coefficient (α 450 nm (cm⁻¹)) of light (blue light) having a wavelength of 450 nm and an absorption coefficient (α 560 nm (cm⁻¹)) of light (green light) having a wavelength of 560 nm are illustrated from the left in FIG. 7, and on the right side thereof, a coefficient ratio (α 450 nm/α 560 nm) of the absorption coefficient (α 450 nm (cm⁻¹)) with respect to the absorption coefficient (α 560 nm (cm⁻¹)) is illustrated. Furthermore, on the right side of the coefficient ratio (α 450 nm/α 560 nm), relative values of a dark current (Jdk), an external quantum efficiency (EQE), and a response time in each of the examples with respect to example 1 are illustrated from the left. Moreover, characteristics significantly inferior to example 1 are illustrated.

Here, the light emitting unit 61 measures a current-voltage curve by setting the wavelength of light emitted from a blue LED light source to the photoelectric conversion element 21 via a band pass filter to 450 nm, setting the light amount to 1.62 μW/cm², controlling a bias voltage applied between electrodes of the photoelectric conversion element using a semiconductor parameter analyzer, and sweeping a voltage applied to the lower electrode (second electrode 54) with respect to the upper electrode (first electrode 51) in FIG. 6. Furthermore, a dark current value (Jdk) and a bright current value in a state where −2.6 V is applied to the lower electrode (second electrode 54) with respect to the upper electrode (first electrode 51) are measured, the dark current value is subtracted from the bright current value, and an external quantum efficiency EQE is calculated from the resulting value.

Moreover, a bias voltage applied between electrodes of the photoelectric conversion element 21 is controlled, the photoelectric conversion element 21 is irradiated with a light pulse on a rectangle having a wavelength of 450 nm and a light amount of 1.62 μW/cm² in a state where a voltage of −2.6 V is applied to the lower electrode (second electrode 54) with respect to the upper electrode (first electrode 51), an attenuation waveform of a current is observed using an oscilloscope, and a time during which the current attenuates from a current at the time of light pulse irradiation to 3% immediately after the light pulse irradiation is defined as a response time which is an index of a response speed.

### Example 1

As illustrated in the uppermost row of FIG. 7, example 1 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (2) (Solvent Green 5 (SG5)), substance (3) (compound a), and substance (4) (C60), respectively, and are mixed at film formation rates of 0.50 Å/sec, 0.50 Å/sec, and 0.25 Å/sec, respectively, and the photoelectric conversion layer 46 is formed so as to have a predetermined thickness (for example, 200 nm).

In the case of example 1 in the uppermost row of FIG. 7, a mixing ratio of the first organic semiconductor (dye):the second organic semiconductor (hole transport material):the third organic semiconductor (fullerene derivative) corresponds to a ratio of a film formation rate, and is therefore 4:4:2 (=0.50 Å/sec:0.50 Å/sec:0.25 Å/sec).

At this time, the absorption coefficient (α 450 nm (cm⁻¹)) is 4.2E+4, the absorption coefficient (α 560 nm (cm⁻¹)) is 4.2E+3, and the coefficient ratio (α 450 nm/a 560 nm) is 10.

Note that, example 1 serves as a reference, and therefore the dark current, EQE, and the response time are all 1.00.

The photoelectric conversion element 21 using the photoelectric conversion layer 46 of example 1 illustrates an experimental result using a ternary photoelectric conversion layer containing substance (2) (SG5) represented by the following chemical formula (7), substance (3) (compound a), and substance (4) (C60) at a ratio of 4:4:2, in which an absorption coefficient at 450 nm in a blue light region is relatively high, an absorption coefficient at 560 nm in a green light region is relatively low, and favorable dark current characteristics, EQE characteristics, and response characteristics are illustrated.

### Example 2

As illustrated in the second row from the top of FIG. 7, example 2 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (7) (compound 1: 3,9-Di(naphthalen-2-yl) perylene and 3,10 di(naphthalen-2-yl) perylene mixture)) represented by the following chemical formula (7), substance (3) (compound a), and substance (4) (C60), respectively, and are mixed at film formation rates of 0.50 Å/sec, 0.50 Å/sec, and 0.25 Å/sec, respectively, and the photoelectric conversion layer 46 is formed so as to have a predetermined thickness (for example, 200 nm).

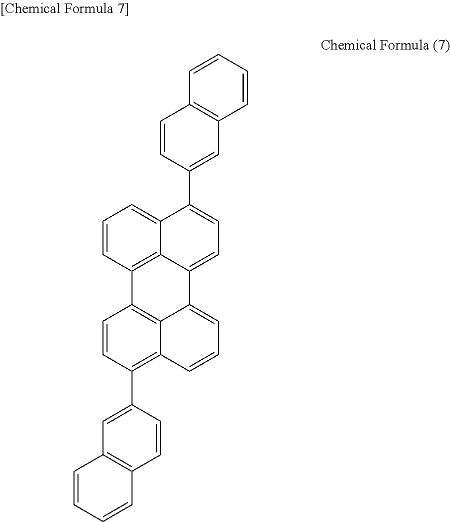 [SMILES: c1ccc2cc(-c3ccc4c5cccc6c(-c7ccc8ccccc8c7)ccc(c7cccc3c74)c65)ccc2c1]

In the case of example 2 in the second row from the top of FIG. 7, the absorption coefficient (α 450 nm (cm⁻¹)) is 9.2E+4, the absorption coefficient (α 560 nm (cm⁻¹)) is 3.1E+3, and the coefficient ratio (α 450 nm/α 560 nm) is 30.

Moreover, the dark current is 0.50 with respect to example 1, the EQE is 1.16 with respect to example 1, and the response time is 1.07 with respect to example 1.

The photoelectric conversion element 21 using the photoelectric conversion layer 46 of example 2 illustrates an experimental result using a ternary photoelectric conversion layer containing substance (7) (compound 1), substance (3) (compound a), and substance (4) (C60) at a ratio of 4:4:2, in which the values are close to the results of example 1, an absorption coefficient at 450 nm in a blue light region is relatively high, an absorption coefficient at 560 nm in a green light region is relatively low, and favorable dark current characteristics, EQE characteristics, and response characteristics are illustrated. Therefore, in example 2, it can be considered that there is no characteristics significantly inferior to example 1.

### Example 3

As illustrated in the third row from the top of FIG. 7, example 3 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (8) (compound 2: 2,5,8,11-Tetra-tert-butylperylene) represented by the following chemical formula (8), substance (3) (compound a), and substance (4) (C60), respectively, and are mixed at film formation rates of 0.50 Å/sec, 0.50 Å/sec, and 0.25 Å/sec, respectively, and the photoelectric conversion layer 46 is formed so as to have a predetermined thickness (for example, 200 nm).

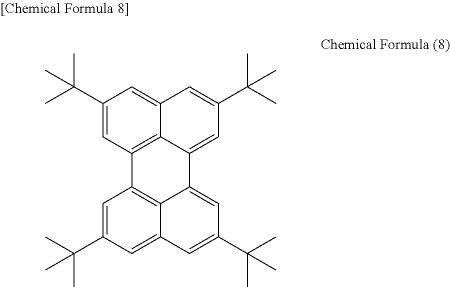 [SMILES: CC(C)(C)c1cc2cc(C(C)(C)C)cc3c4cc(C(C)(C)C)cc5cc(C(C)(C)C)cc(c(c1)c23)c54]

In the case of example 3 in the third row from the top of FIG. 7, the absorption coefficient (α 450 nm (cm⁻¹)) is 4.3E+4, the absorption coefficient (α 560 nm (cm⁻¹)) is 2.8E+3, and the coefficient ratio (α 450 nm/α 560 nm) is 15.

Moreover, the dark current is 0.34 with respect to example 1, the EQE is 0.80 with respect to example 1, and the response time is 2.22 with respect to example 1.

The photoelectric conversion element 21 using the photoelectric conversion layer 46 of example 3 illustrates an experimental result using a ternary photoelectric conversion layer containing substance (8) (compound 2), substance (3) (compound a), and substance (4) (C60) at a ratio of 4:4:2, in which the values are close to the results of example 1, an absorption coefficient at 450 nm in a blue light region is relatively high, an absorption coefficient at 560 nm in a green light region is relatively low, and favorable dark current characteristics, EQE characteristics, and response characteristics are illustrated. Therefore, in example 3, it can be considered that there is no characteristics significantly inferior to example 1.

### Example 4

As illustrated in the fourth row from the top of FIG. 7, example 4 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (9) (compound 3: Pryln-(COOiBu)4) represented by the following chemical formula (9), substance (3) (compound a), and substance (4) (C60), respectively, and are mixed at film formation rates of 0.50 Å/sec, 0.50 Å/sec, and 0.25 Å/sec, respectively, and the photoelectric conversion layer 46 is formed so as to have a predetermined thickness (for example, 200 nm).

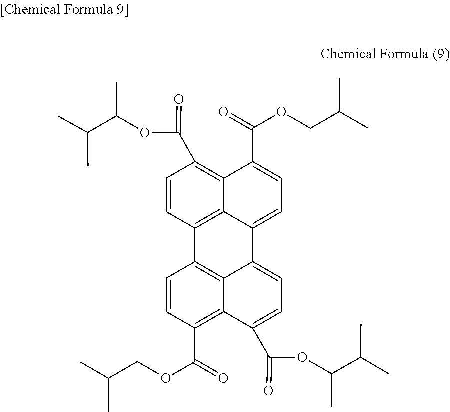 [SMILES: CC(C)COC(=O)c1ccc2c3ccc(C(=O)OC(C)C(C)C)c4c(C(=O)OCC(C)C)ccc(c5ccc(C(=O)OC(C)C(C)C)c1c25)c43]

In the case of example 4 in the fourth row from the top of FIG. 7, the absorption coefficient (α 450 nm (cm⁻¹)) is 3.8E+4, the absorption coefficient (α 560 nm (cm⁻¹)) is 2.6E+3, and the coefficient ratio (α 450 nm/α 560 nm) is 15.

Moreover, the dark current is 1.50 with respect to example 1, the EQE is 0.94 with respect to example 1, and the response time is 1.56 with respect to example 1.

The photoelectric conversion element 21 using the photoelectric conversion layer 46 of example 4 illustrates an experimental result using a ternary photoelectric conversion layer containing substance (9) (compound 3), substance (3) (compound a), and substance (4) (C60) at a ratio of 4:4:2, in which the values are close to the results of example 1, an absorption coefficient at 450 nm in a blue light region is relatively high, an absorption coefficient at 560 nm in a green light region is relatively low, and favorable dark current characteristics, EQE characteristics, and response characteristics are illustrated. Therefore, in example 4, it can be considered that there is no characteristics significantly inferior to example 1.

### Example 5

As illustrated in the fifth row from the top of FIG. 7, example 5 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (2) (SG5), substance (6) (compound b), and substance (4) (C60), respectively, and are mixed at film formation rates of 0.50 Å/sec, 0.50 Å/sec, and 0.25 Å/sec, respectively, and the photoelectric conversion layer 46 is formed so as to have a predetermined thickness (for example, 200 nm).

In the case of example 5 in the fifth row from the top of FIG. 7, the absorption coefficient (α 450 nm (cm⁻¹)) is 9.5E+4, the absorption coefficient (α 560 nm (cm⁻¹)) is 4.2E+3, and the coefficient ratio (α 450 nm/α 560 nm) is 23.

Moreover, the dark current is 0.55 with respect to example 1, the EQE is 1.49 with respect to example 1, and the response time is 0.64 with respect to example 1.

The photoelectric conversion element 21 using the photoelectric conversion layer 46 of example 5 illustrates an experimental result using a ternary photoelectric conversion layer containing substance (2) (SG5), substance (6) (compound b), and substance (4) (C60) at a ratio of 4:4:2, in which the values are close to the results of example 1, an absorption coefficient at 450 nm in a blue light region is relatively high, an absorption coefficient at 560 nm in a green light region is relatively low, and favorable dark current characteristics, EQE characteristics, and response characteristics are illustrated. Therefore, in example 5, it can be considered that there is no characteristics significantly inferior to example 1.

### Example 6

As illustrated in the sixth row from the top of FIG. 7, example 5 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (2) (SG5), substance (3) (compound a), and substance (4) (C60), respectively, and are mixed at film formation rates of 0.50 Å/sec, 0.00 Å/sec, and 0.50 Å/sec, respectively, and the photoelectric conversion layer 46 is formed so as to have a predetermined thickness (for example, 200 nm).

Note that the case where the film formation rate is 0.00 Å/sec means that a film is formed at an extremely small film formation rate extremely close to 0.00 Å/sec, rather than that a film is not formed at all. Therefore, description will be made by assuming that the photoelectric conversion layer 46 is a mixture of the first organic semiconductor (dye), the second organic semiconductor (hole transport material), and the third organic semiconductor (fullerene derivative) in principle. However, a case where the film formation rate is a value close to 0.00 Å/sec is substantially similar to a state where a film is not formed at all.

That is, in example 6, substance (3) (compound a) which is the second organic semiconductor (hole transport material) is hardly contained in the photoelectric conversion layer 46.

In the case of example 6 in the sixth row from the top of FIG. 7, a mixing ratio among the first organic semiconductor (dye), the second organic semiconductor (hole transport material), and the third organic semiconductor (fullerene derivative) corresponds to a ratio of a film formation rate, and is therefore 5:0:5 (=0.50 Å/sec:0.00 Å/sec:0.50 Å/sec).

Furthermore, the absorption coefficient (α 450 nm (cm⁻¹)) is 8.3E+4, the absorption coefficient (α 560 nm (cm⁻¹)) is 1.4E+4, and the coefficient ratio (α 450 nm/a 560 nm) is 5.9.

Moreover, the dark current is 0.61 with respect to example 1, the EQE is 1.46 with respect to example 1, and the response time is 9.34 with respect to example 1. The characteristics significantly inferior to example 1 are the coefficient ratio and the response time, which are spectral characteristics.

The photoelectric conversion element 21 using the photoelectric conversion layer 46 of example 6 illustrates an experimental result using a ternary photoelectric conversion layer containing substance (2) (SG5), substance (3) (compound a), and substance (4) (C60) at a ratio of 5:0:5, in which substance (3) (compound a) is hardly contained, the hole transport characteristics, which are the characteristics of substance (3) (compound a), are low, and therefore the response characteristics are significantly lower than those of example 1. Furthermore, substance (3) (compound a) is hardly contained, and the ratio of substances (4) (C60) is increased. Therefore, the absorption coefficient (α 560 nm (cm⁻¹)) of green light is high, and the coefficient ratio is small.

### Example 7

As illustrated in the seventh row from the top of FIG. 7, example 7 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (1) (B4PyMPM), substance (3) (compound a), and substance (4) (C60), respectively, and are mixed at film formation rates of 0.50 Å/sec, 0.50 Å/sec, and 0.25 Å/sec, respectively, and the photoelectric conversion layer 46 is formed so as to have a predetermined thickness (for example, 200 nm).

In the case of example 7 in the sixth row from the top of FIG. 7, the absorption coefficient (α 450 nm (cm⁻¹)) is 7.2E+3, the absorption coefficient (α 560 nm (cm⁻¹)) is 2.9E+3, and the coefficient ratio (α 450 nm/α 560 nm) is 2.5.

Moreover, the dark current is 0.75 with respect to example 1, the EQE is 0.27 with respect to example 1, and the response time is 5.42 with respect to example 1. The characteristics significantly inferior to example 1 are the coefficient ratio, EQE, and the response time, which are spectral characteristics.

The photoelectric conversion element 21 using the photoelectric conversion layer 46 of example 7 illustrates an experimental result using a ternary photoelectric conversion layer containing substance (1) (B4PyMPM), substance (3) (compound a), and substance (4) (C60) at a ratio of 4:4:2, in which the absorption coefficient (α 560 nm (cm⁻¹)) of blue light is low, and the coefficient ratio is small. Furthermore, since the light absorption characteristics of substance (1) (B4PyMPM) to blue light are low, the EQE characteristics and the response characteristics are lower than those of example 1.

### Example 8

As illustrated in the eighth row from the top of FIG. 7, example 8 illustrates an absorption coefficient (α 450 nm (cm⁻¹)) and an absorption coefficient (α 560 nm (cm⁻¹)), a ratio between the absorption coefficients (α 450 nm/α 560 nm), relative values of a dark current, EQE, and a response time with respect to example 1, and characteristics significantly inferior to example 1 in a case where the first organic semiconductor (dye), the second organic semiconductor (hole transport material), and the third organic semiconductor (fullerene derivative) are substance (10) (F6-SubPc-OPh26F2) represented by the following chemical formula (10), substance (3) (compound a), and substance (4) (C60), respectively, and are mixed at film formation rates of 0.50 Å/sec, 0.50 Å/sec, and 0.25 Å/sec, respectively, and the photoelectric conversion layer 46 is formed so as to have a predetermined thickness (for example, 200 nm).

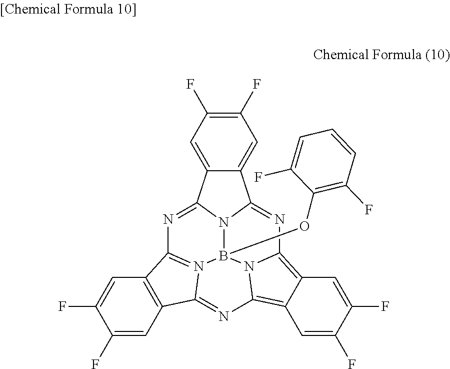

In the case of example 8 in the eighth row from the top of FIG. 7, the absorption coefficient (α 450 nm (cm⁻¹)) is 8.5E+3, the absorption coefficient (α 560 nm (cm⁻¹)) is 1.0E+5, and the coefficient ratio (α 450 nm/α 560 nm) is 0.085.

Moreover, the dark current is 0.65 with respect to example 1, the EQE is 0.71 with respect to example 1, and the response time is 2.18. The characteristics significantly inferior to example 1 are the coefficient ratio and EQE, which are spectral characteristics.

The photoelectric conversion element 21 using the photoelectric conversion layer 46 of example 7 illustrates an experimental result using a ternary photoelectric conversion layer containing substance (10) (F6-SubPc-OPh26F2)), substance (3) (compound a), and substance (4) (C60) at a ratio of 4:4:2, in which the absorption coefficient (α 450 nm (cm⁻¹)) of blue light is low, the absorption coefficient (α 560 nm (cm⁻¹)) of green light is high, and the coefficient ratio is small. Furthermore, since the light absorption characteristics of substance (10) (F6-SubPc-OPh26F2) to blue light are low, the EQE characteristics are lower than those of example 1.

When examples 1 to 8 illustrated in FIG. 7 above are compared with each other, it is considered that the photoelectric conversion element 21 including the photoelectric conversion layer 46 formed in each of examples 1 to 5 can selectively and photoelectrically convert blue light with high efficiency.

That is, it can be considered that desirable characteristics are obtained by forming the photoelectric conversion layer 46 by mixing the first organic semiconductor (dye) containing a perylene derivative, the second organic semiconductor (hole transport material), and the third organic semiconductor (fullerene derivative).

More specifically, the first organic semiconductor (dye) containing a perylene derivative is a film that absorbs blue light (including blue light in a range of, for example, 400 to 500 nm including 450 nm adopted in the experiment) but does not absorb green light (including green light in a range of, for example, 500 to 600 nm around 560 nm adopted in the experiment) or red light (including red light in a range of, for example, 600 to 700 nm). Specifically, the first organic semiconductor (dye) containing a perylene derivative only needs to have an absorption coefficient of 40,000 cm⁻¹ or more for blue light (including blue light in a range of, for example, 400 to 500 nm, including 450 nm adopted in the experiment), and an absorption coefficient of 10,000 cm⁻¹ or less for green light (including green light in a range of, for example, 500 to 600 nm around 560 nm adopted in the experiment) and red light (including red light in a range of, for example, 500 to 700 nm).

When the first organic semiconductor (dye) containing a perylene derivative is generalized, the first organic semiconductor (dye) containing a perylene derivative is, for example, substance (11) represented by the following chemical formula (11).

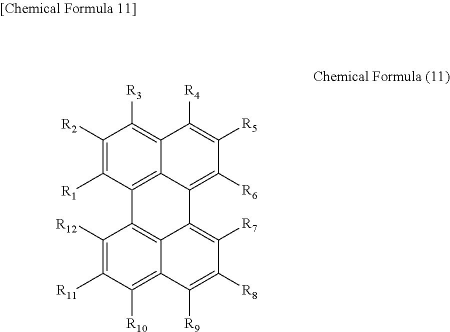

In chemical formula (11) representing substance (11), R1 to R12 are each independently selected from the group consisting of a hydrogen atom, a halogen atom, a linear, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, an aryl group, a heteroaryl group, a carboxy group, a carboxoamide group, a carboalkoxy group, an acyl group, a sulfonyl group, a cyano group, and a nitro group, in which any adjacent R1 to R12 may be a part of a fused aliphatic ring or a fused aromatic ring, and the fused aliphatic ring or the fused aromatic ring may contain one or more atoms other than a carbon atom.

Furthermore, in the perylene derivative, R1 and R7 that are point-symmetrical with respect to a center ring in chemical formula (11) representing substance (11) as a central axis may be the same, R6 and R12 that are point-symmetrical with respect to the center ring may be the same, R4 and R10 that are point-symmetrical with respect to the center ring may be the same, and R3 and R9 that are point-symmetrical with respect to the center ring may be the same.

Moreover, in the perylene derivative, R2, R5, R8, and R11 in chemical formula (11) representing substance (11) may be each a hydrogen atom or a carbon-bonded substituent.

Furthermore, in the perylene derivative, when R1 and R7 that are point-symmetrical with respect to a center ring in chemical formula (11) representing substance (11) as a central axis are the same, R6 and R12 that are point-symmetrical with respect to the center ring are the same, R4 and R10 that are point-symmetrical with respect to the center ring are the same, and R3 and R9 that are point-symmetrical with respect to the center ring are the same, R2, R5, R8, and R11 may be each independently a hydrogen atom, a substituted or unsubstituted alkyl group having 1 to 20 carbon atoms, a cycloalkyl group, an aryl group, or a heteroaryl group.

Moreover, the perylene derivative may be a polymer of substance (11) represented by chemical formula (11) as indicated by substance (12) represented chemical formula (12).

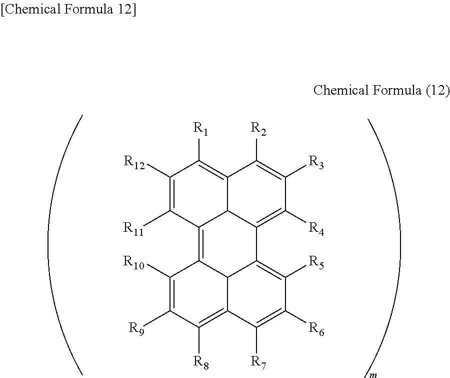

The perylene derivative that is the first organic semiconductor (dye) generalized as described above only needs to be a compound that can be represented by chemical formula (11) or (12), and therefore may be, for example, any one of substances (13) to (53) represented by the following chemical formulas (13) to (53).

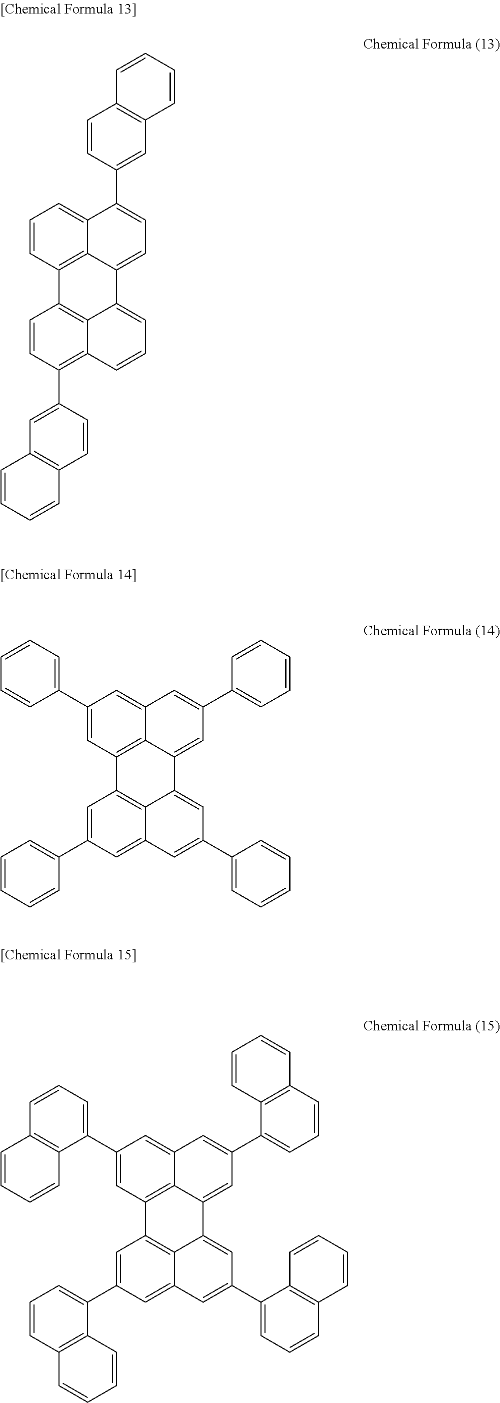

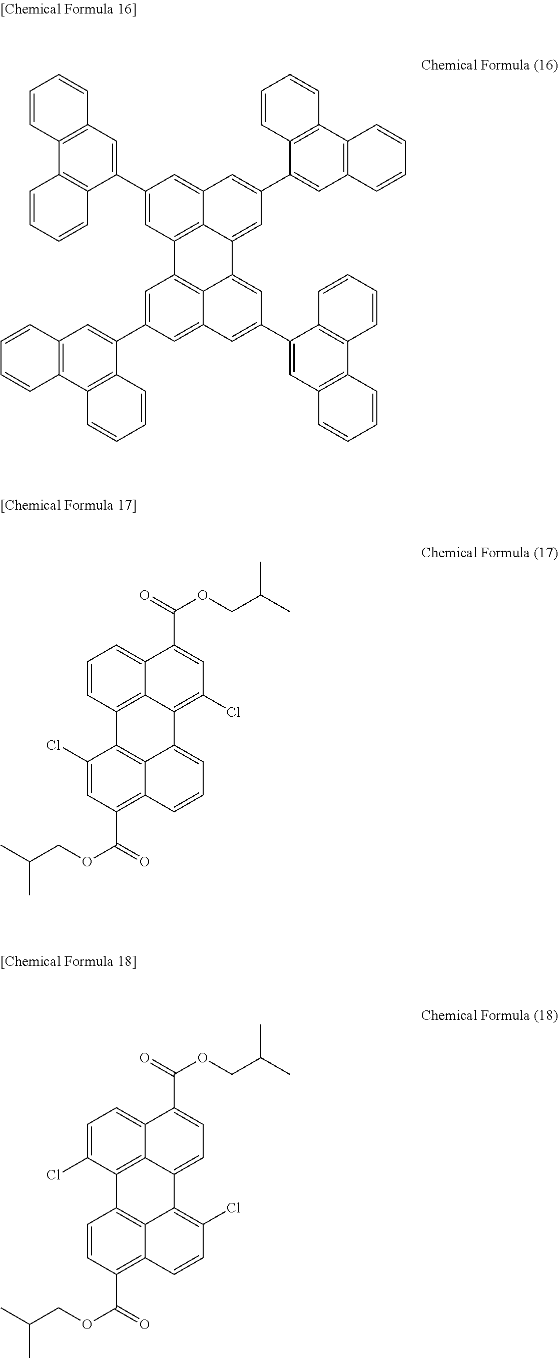

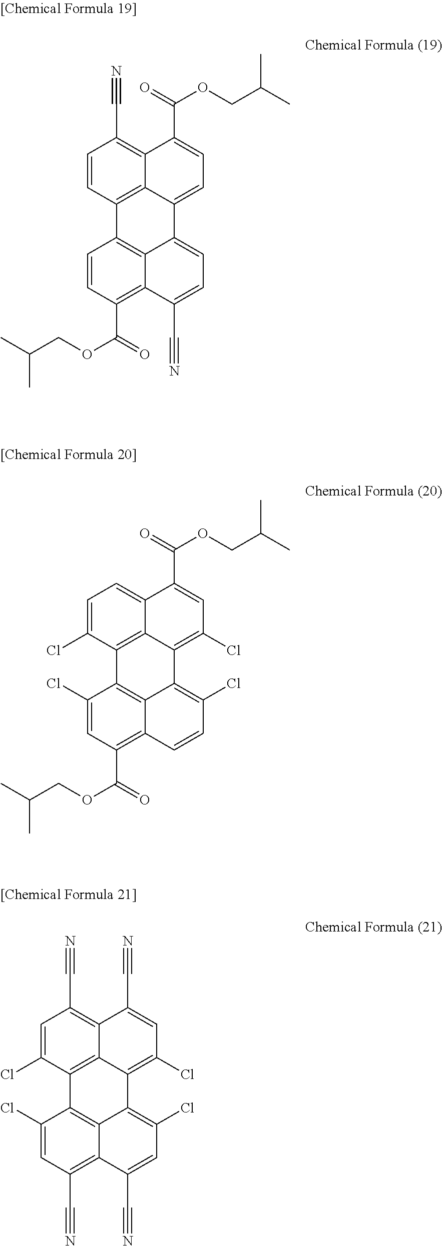

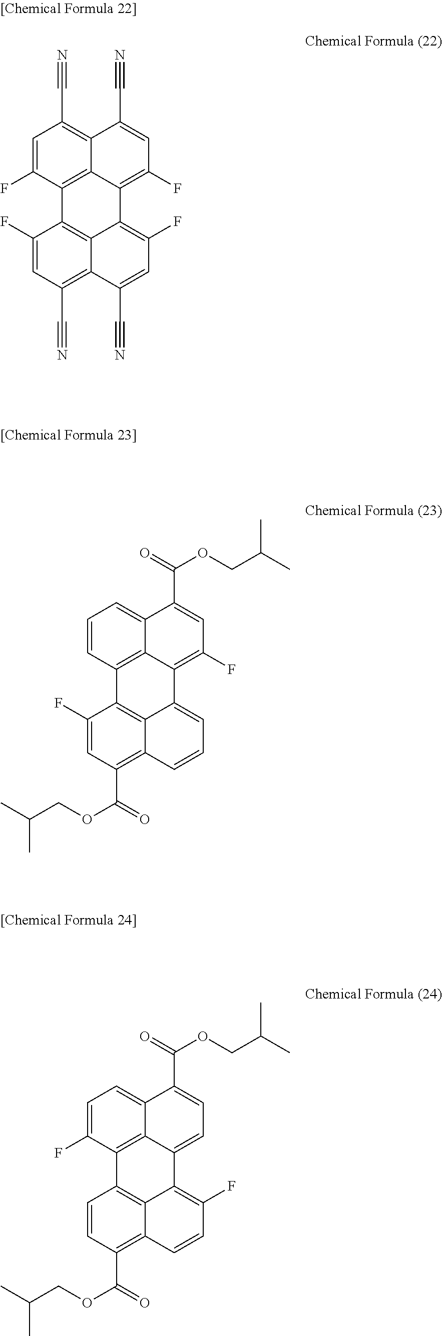

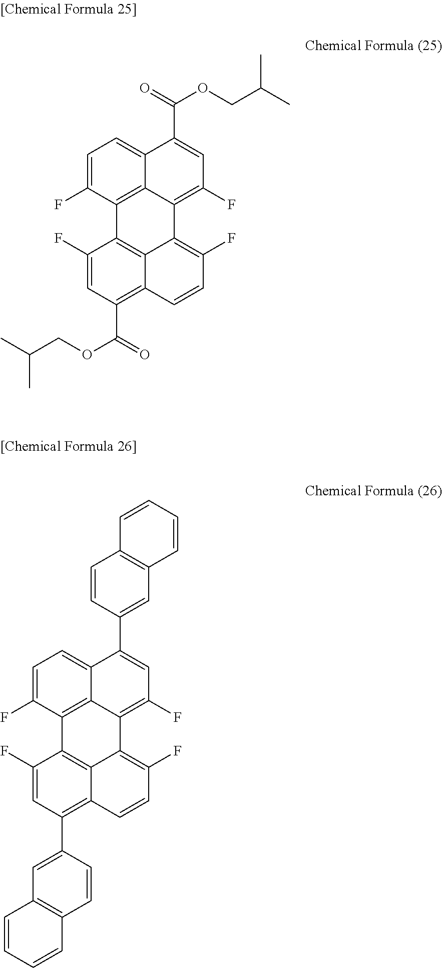 [SMILES: CC(C)COC(=O)c1cc(F)c2c3c(F)ccc4c(C(=O)OCC(C)C)cc(F)c(c5c(F)ccc1c52)c43 ; Fc1ccc2c(-c3ccc4ccccc4c3)cc(F)c3c4c(F)ccc5c(-c6ccc7ccccc7c6)cc(F)c(c1c23)c54]

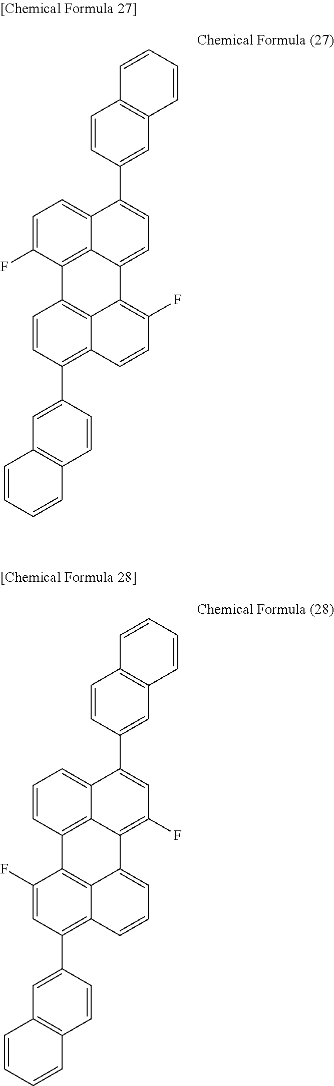 [SMILES: Fc1ccc2c(-c3ccc4ccccc4c3)ccc3c4c(F)ccc5c(-c6ccc7ccccc7c6)ccc(c1c23)c54 ; Fc1cc(-c2ccc3ccccc3c2)c2cccc3c4c(F)cc(-c5ccc6ccccc6c5)c5cccc(c1c23)c54]

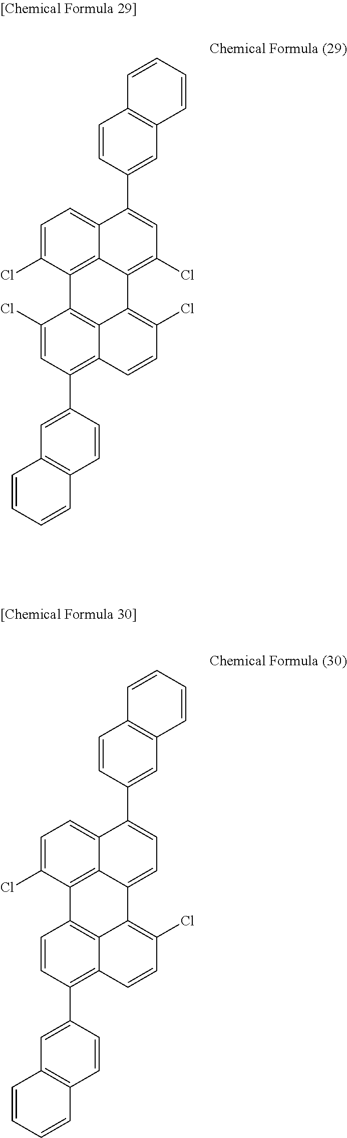 [SMILES: Clc1ccc2c(-c3ccc4ccccc4c3)cc(Cl)c3c4c(Cl)ccc5c(-c6ccc7ccccc7c6)cc(Cl)c(c1c23)c54 ; Clc1ccc2c(-c3ccc4ccccc4c3)ccc3c4c(Cl)ccc5c(-c6ccc7ccccc7c6)ccc(c1c23)c54]

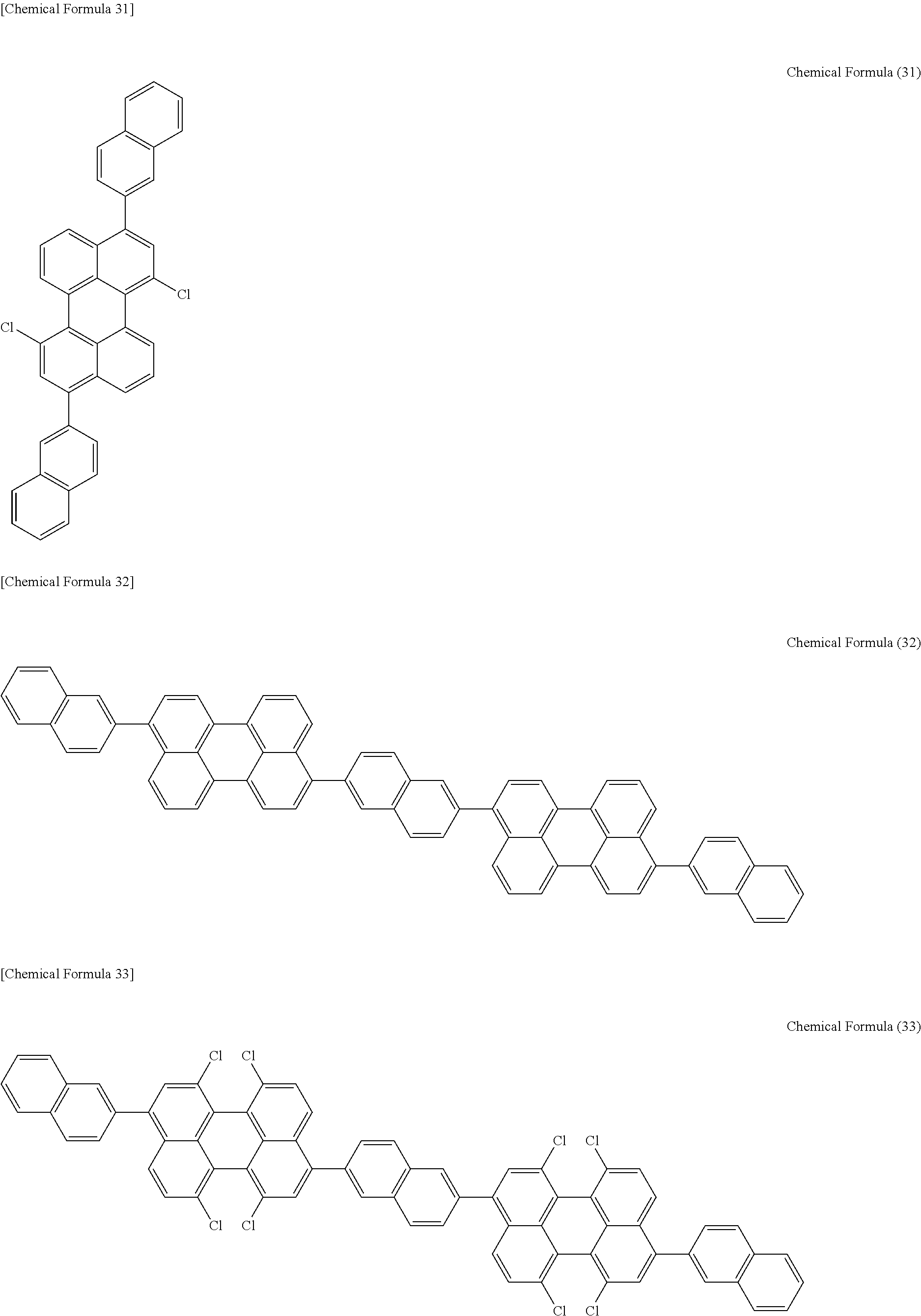

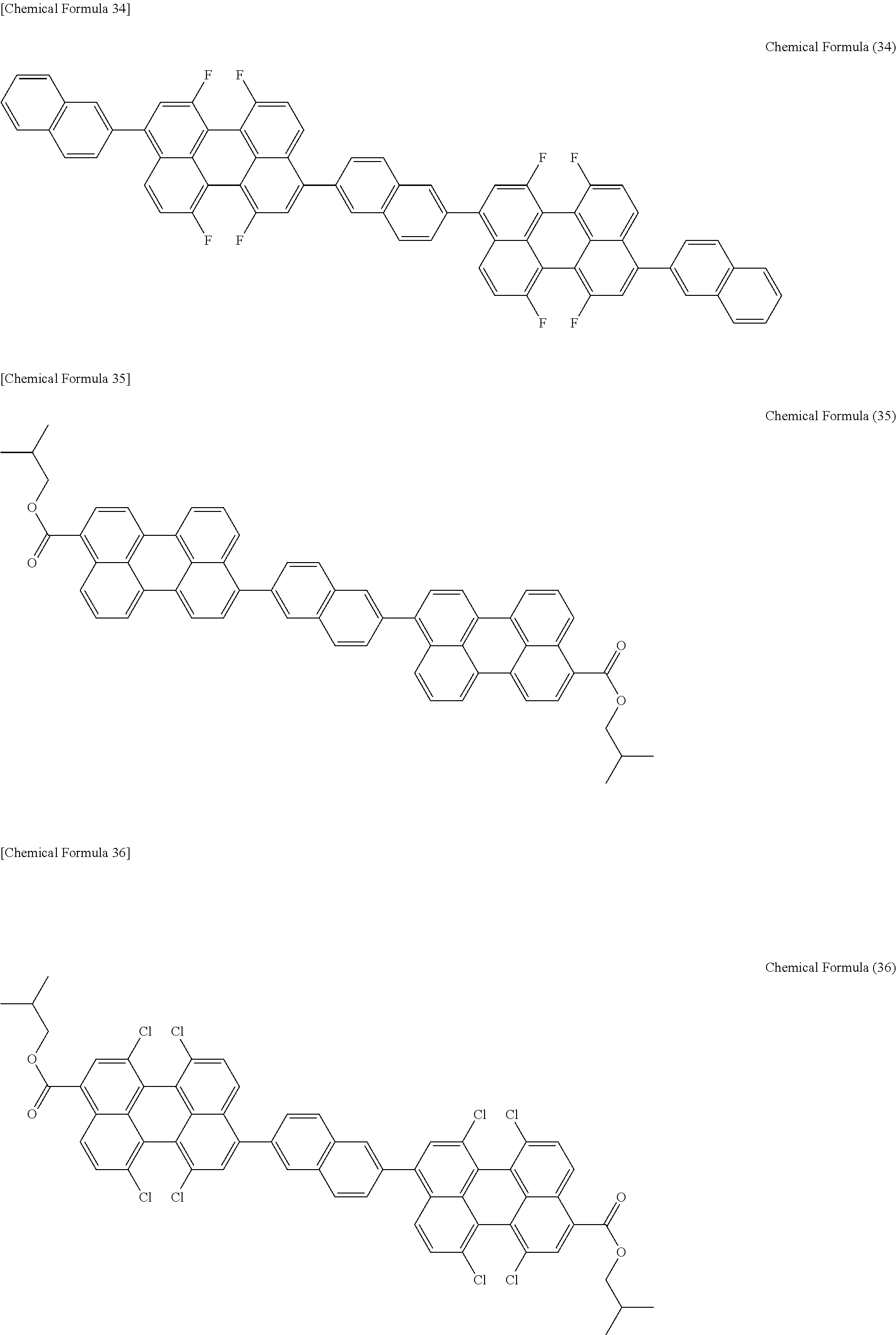

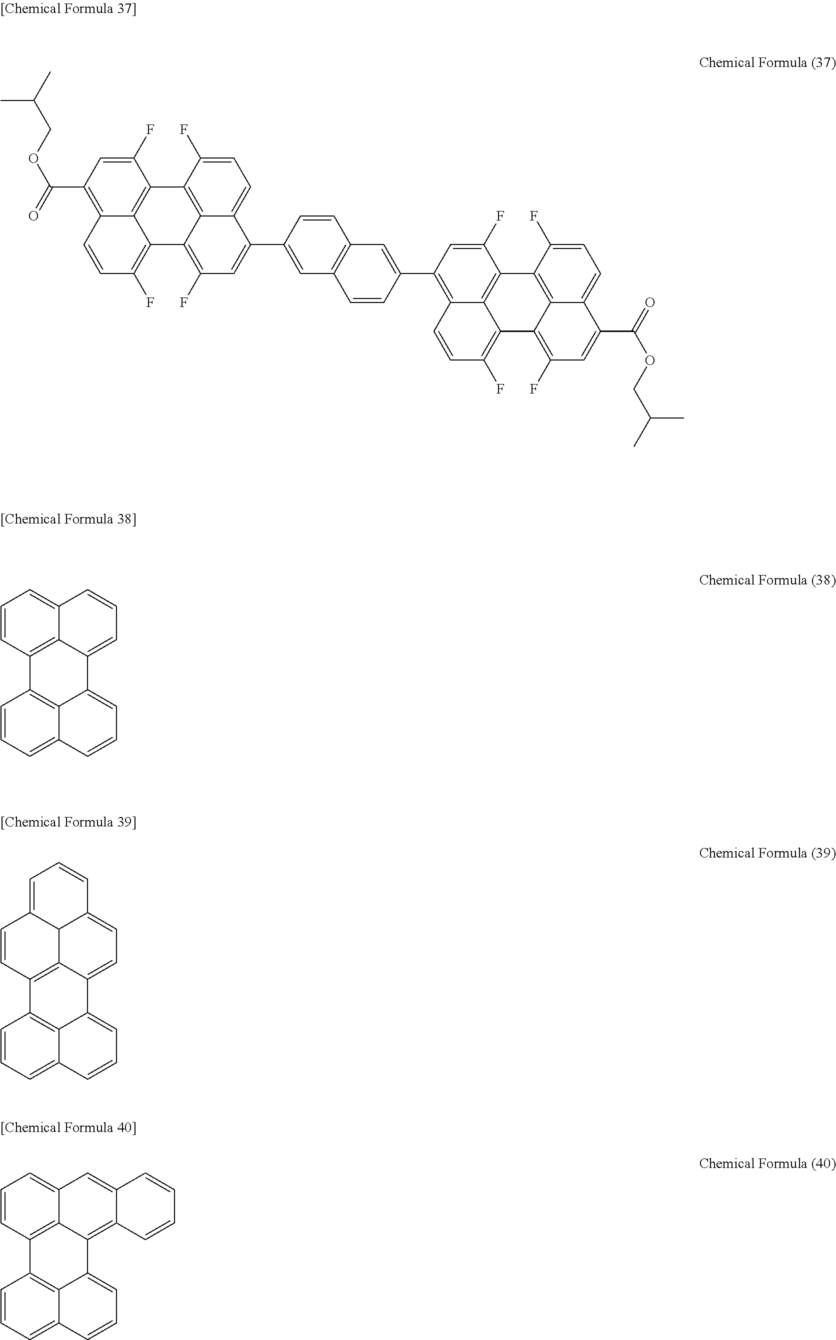

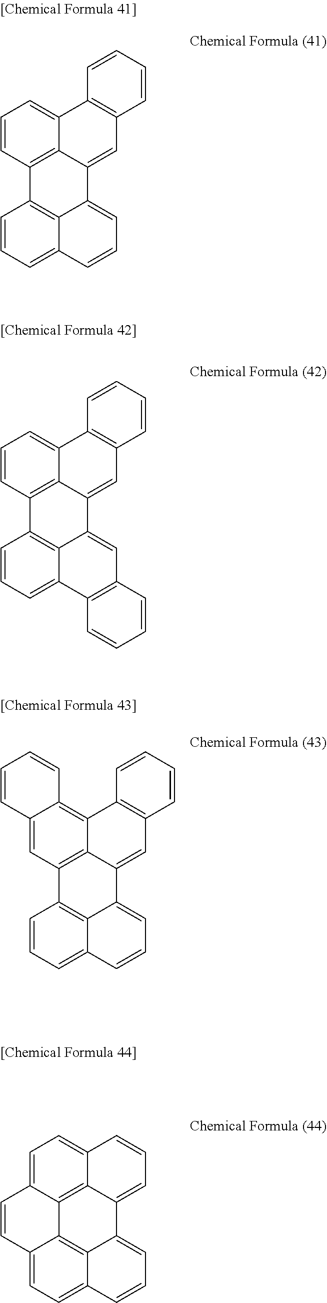

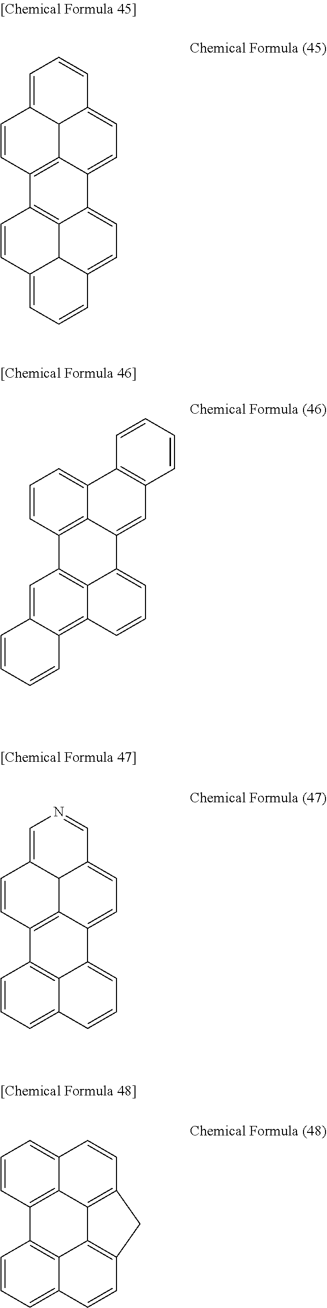

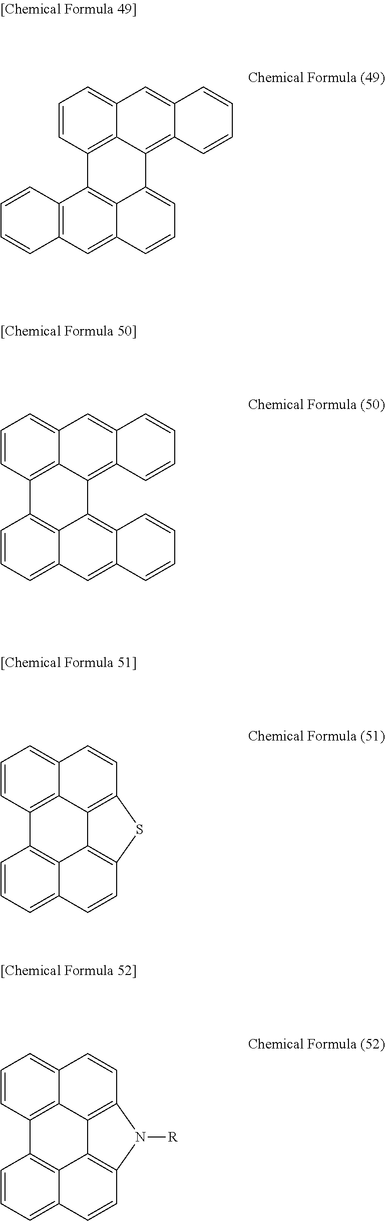

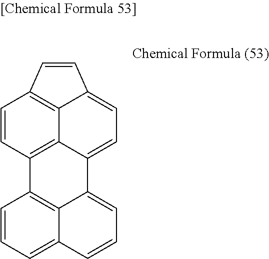 [SMILES: C1=Cc2ccc3c4cccc5cccc(c6ccc1c2c63)c54]

Furthermore, in the above, an example of using substance (3) (compound a) and substance (6) (compound b) as the second organic semiconductor has been described. However, another semiconductor may be used as long as the semiconductor is a hole transport material that absorbs blue light and has a herringbone structure and has crystallinity.

More specifically, as a first condition, a film on which the second organic semiconductor is deposited is a film that absorbs blue light (including blue light in a range of, for example, 400 to 500 nm including 450 nm adopted in the experiment) but does not absorb green light (including green light in a range of, for example, 500 to 600 nm including 560 nm adopted in the experiment) or red light (including red light in a range of, for example, 500 to 700 nm), has an absorption coefficient of 40,000 cm⁻¹ or more for blue light and an absorption ratio of 80% or more for blue light, and an absorption coefficient of 10,000 cm⁻¹ or less for each of green light and red light and an absorption ratio of less than 20% for each of green light and red light.

Furthermore, as a second condition, the film on which the second organic semiconductor is deposited is a hole transport material having a HOMO of 5.0 to 6.0 eV and has a hole mobility of 1E-6 cm⁻²/Vs or more.

Moreover, as a third condition, the film on which the second organic semiconductor is deposited exhibits a peak of crystallinity by out-of-plane X-ray measurement, and the photoelectric conversion element 21 containing the second organic semiconductor has a peak of crystallinity at a position equivalent to that of a single film by out-of-plane X-ray measurement.

That is, the second organic semiconductor only needs to be a semiconductor that satisfies the first to third conditions described above, and may be, for example, any one of substances (54) to (70) represented by the following chemical formulas (54) to (70).

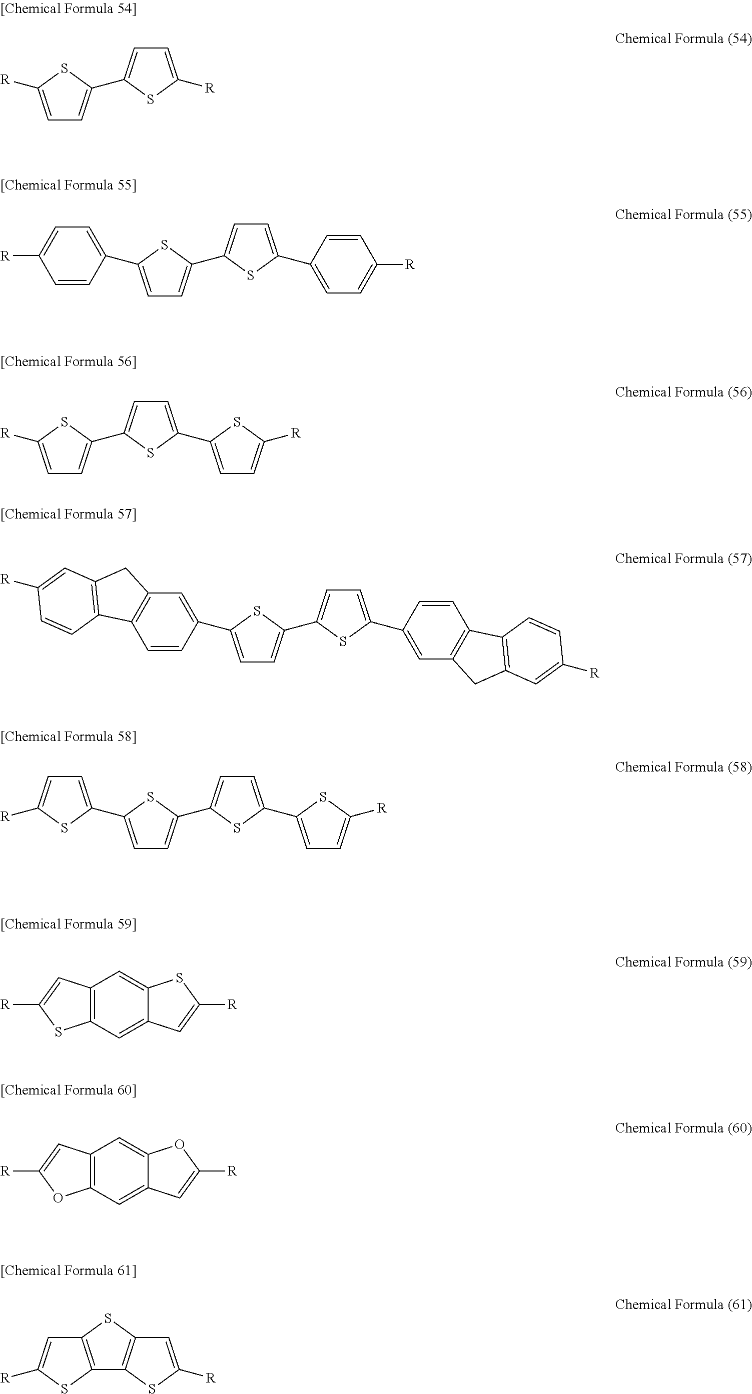

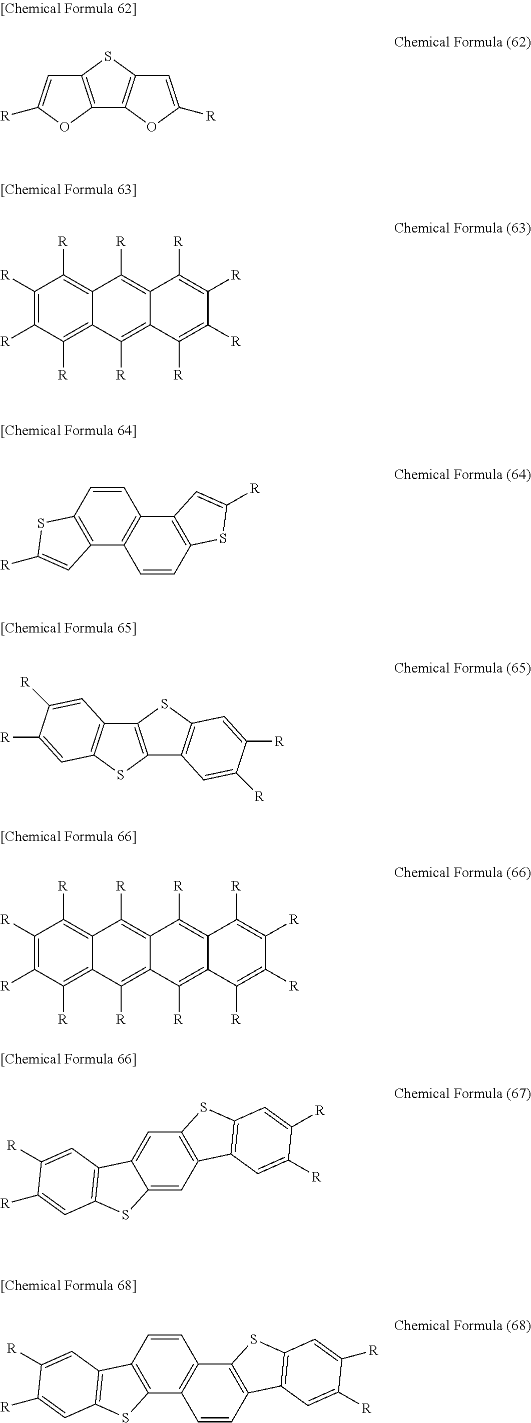

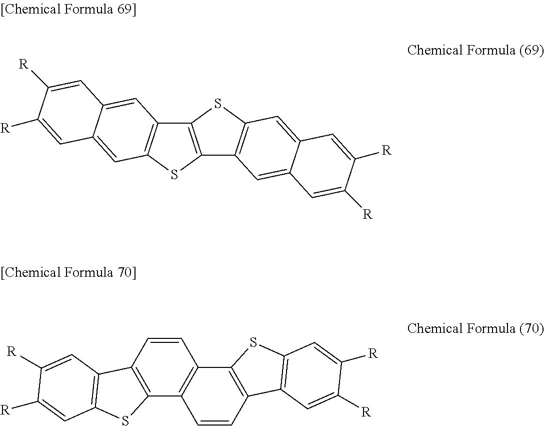

Moreover, the third organic semiconductor may be other than substance (4) (C60) as long as the third organic semiconductor is a fullerene derivative, and may be, for example, substance (71) (C70) represented by the following chemical formula (71).

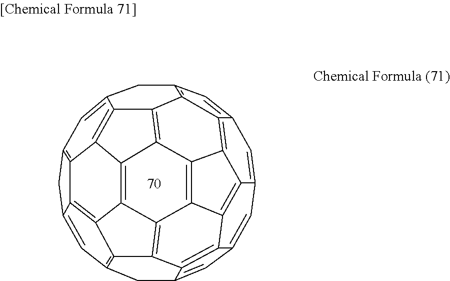 [SMILES: c1c2c3c4c(cc5c6c4c4c7c3c3c1Cc1cc8cc9cc%10cc(c%11c%10c%10c9c9c8c1c3c7c9c%10c4c%116)C5)C2]

<Configuration of Solid-State Imaging Element>

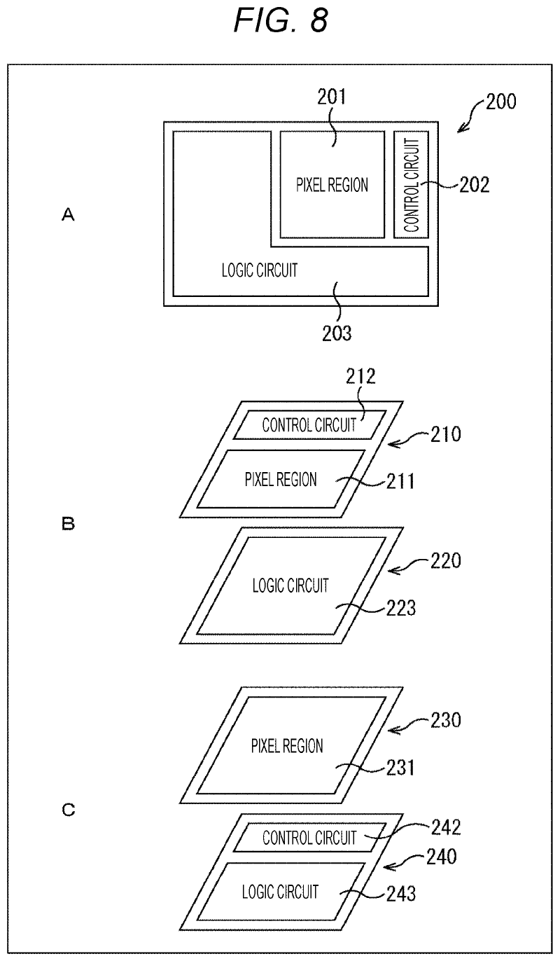

Next, a configuration of a solid-state imaging element to which the photoelectric conversion element according to the present technology is applied will be described with reference to FIG. 8. FIG. 8 is a schematic diagram for explaining a structure of a solid-state imaging element to which the photoelectric conversion element according to the present technology is applied.

Here, in FIG. 8, each of pixel regions 201, 211, and 231 is a region in which the photoelectric conversion element including the photoelectric conversion film according to the present technology is disposed. Furthermore, each of control circuits 202, 212, and 242 is an arithmetic processing circuit that controls each component of the solid-state imaging element, and each of logic circuits 203, 223, and 243 is a signal processing circuit for processing a signal photoelectrically converted by the photoelectric conversion element in the pixel region.

For example, as illustrated in configuration A of FIG. 8, in the solid-state imaging element to which the photoelectric conversion element according to the present technology is applied, the pixel region 201, the control circuit 202, and the logic circuit 203 may be formed in one semiconductor chip 200.

Furthermore, as illustrated in configuration B of FIG. 8, the solid-state imaging element to which the photoelectric conversion element according to the present technology is applied may be a laminated solid-state imaging element in which the pixel region 211 and the control circuit 212 are formed in a first semiconductor chip 210, and the logic circuit 223 is formed in a second semiconductor chip 220.

Moreover, as illustrated in configuration C of FIG. 8, the solid-state imaging element to which the photoelectric conversion element according to the present technology is applied may be a laminated solid-state imaging element in which the pixel region 231 is formed in a first semiconductor chip 230, and the control circuit 242 and the logic circuit 243 are formed in a second semiconductor chip 240.

In the solid-state imaging element illustrated in each of configurations B and C of FIG. 8, at least one of the control circuit or the logic circuit is formed in a semiconductor chip different from the semiconductor chip on which the pixel region is formed. Therefore, the solid-state imaging elements illustrated in each of configurations B and C of FIG. 8 can enlarge the pixel region more than the solid-state imaging element illustrated in configuration A, and therefore can increase the number of pixels mounted on the pixel region, and can improve planar resolution. Therefore, the solid-state imaging element to which the photoelectric conversion element according to the present technology is applied is more preferably the laminated solid-state imaging element illustrated in each of configurations B and configuration C of FIG. 8.

<Configuration of Electronic Apparatus>

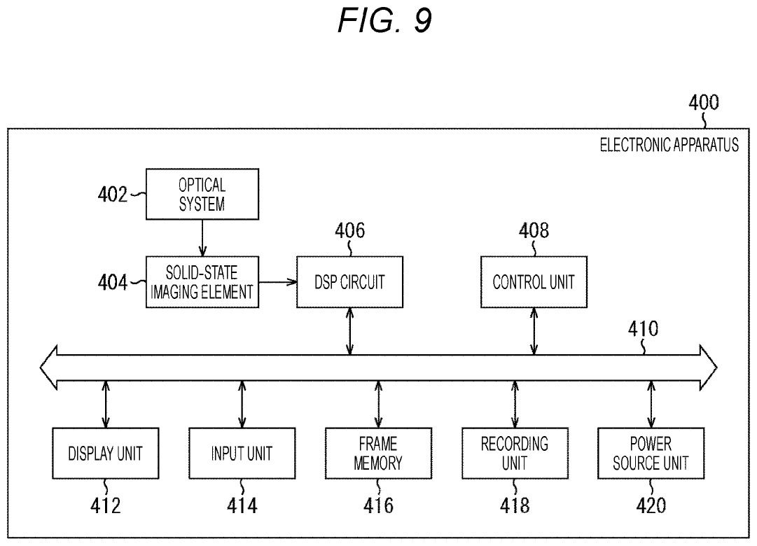

Next, a configuration of an electronic apparatus to which the photoelectric conversion element according to the present technology is applied will be described with reference to FIG. 9. FIG. 9 is a block diagram for explaining the configuration of the electronic apparatus to which the photoelectric conversion element according to the present technology is applied.

As illustrated in FIG. 9, an electronic apparatus 400 includes an optical system 402, a solid-state imaging element 404, a digital signal processor (DSP) circuit 406, a control unit 408, an output unit 412, an input unit 414, a frame memory 416, a recording unit 418, and a power source unit 420.

Here, the DSP circuit 406, the control unit 408, the output unit 412, the input unit 414, the frame memory 416, the recording unit 418, and the power source unit 420 are connected to each other via a bus line 410.

The optical system 402 captures incident light from a subject and forms an image on an imaging surface of the solid-state imaging element 404. Furthermore, the solid-state imaging element 404 includes the photoelectric conversion element according to the present technology, and converts the amount of incident light an image of which has been formed on the imaging surface by the optical system 402 into an electrical signal in a pixel unit, and outputs the electrical signal as a pixel signal.

The DSP circuit 406 processes the pixel signal transferred from the solid-state imaging element 404 and outputs the processed signal to the output unit 412, the frame memory 416, the recording unit 418, and the like.

Furthermore, the control unit 408 includes, for example, an arithmetic processing circuit, and controls an operation of each component of the electronic apparatus 400.

The output unit 412 is, for example, a panel type display device such as a liquid crystal display or an organic electroluminescence display, and displays a moving image or a still image imaged by the solid-state imaging element 404. Note that the output unit 412 may include an audio output device such as a speaker or a headphone. Furthermore, the input unit 414 is, for example, a device for a user to input an operation, such as a touch panel or a button, and issues an operation command for various functions of the electronic apparatus 400 according to the user's operation.

The frame memory 416 temporarily stores a moving image, a still image, and the like imaged by the solid-state imaging element 404. Furthermore, the recording unit 418 records a moving image, a still image, and the like imaged by the solid-state imaging element 404 on a removable storage medium such as a magnetic disk, an optical disk, a magneto-optical disk, or a semiconductor memory.

The power source unit 420 appropriately supplies various power sources serving as operation power sources of the DSP circuit 406, the control unit 408, the output unit 412, the input unit 414, the frame memory 416, and the recording unit 418 to these supply targets.

The electronic apparatus 400 to which the photoelectric conversion element according to the present technology is applied has been described above. The electronic apparatus 400 to which the photoelectric conversion element according to the present technology is applied may be, for example, an imaging apparatus.

Furthermore, although the solid-state imaging element and the electronic apparatus to which the photoelectric conversion element according to the present technology is applied have been described above, the photoelectric conversion element according to the present technology can also be applied to other techniques, and for example, can also be applied as a sensor using a solar cell or light.

Hitherto, an embodiment of the present technology has been described in detail with reference to the attached drawings, but the technical scope of the present technology is not limited to such examples. It is obvious that a person having ordinary knowledge in the technical field to which the present technology belongs can conceive of various change examples and modification examples within a range of the technical idea described in the claims, and it is understood that these change examples and modification examples are naturally within the technical scope of the present technology.

Furthermore, the effects described in the present specification are merely illustrative or exemplary, and are not limiting. That is, the present technology can exhibit another effect obvious to those skilled in the art from the description of the present specification together with the above effects or in place of the above effects.

<Application Example to Endoscopic Surgical System>

The technology according to the present disclosure (the present technology) can be applied to various products. For example, the technology according to the present disclosure may be applied to an endoscopic surgical system.

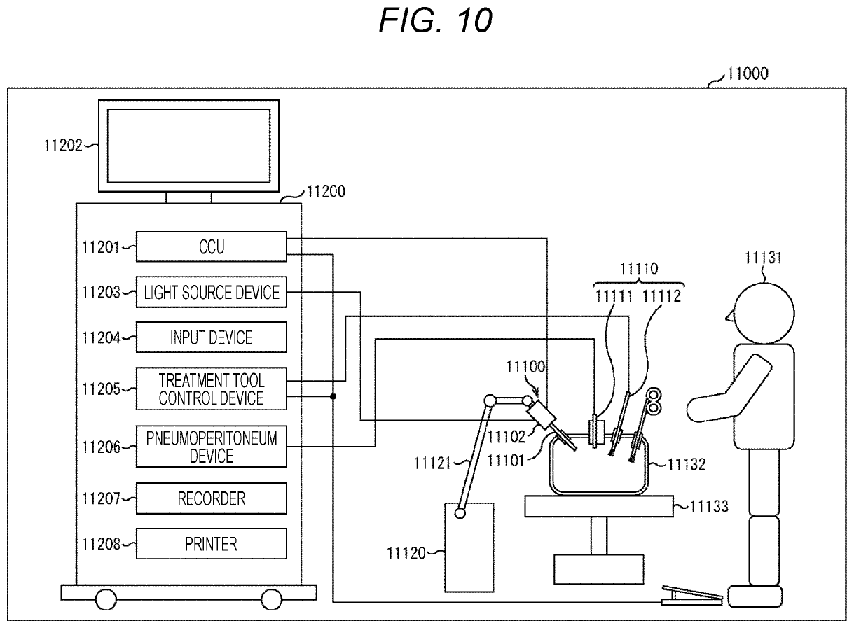

FIG. 10 is a diagram illustrating an example of a schematic configuration of an endoscopic surgical system to which the technology according to the present disclosure (the present technology) can be applied.

FIG. 10 illustrates a situation in which a surgeon (physician) 11131 is performing surgery on a patient 11132 on a patient bed 11133 using an endoscopic surgical system 11000. As illustrated in the drawing, the endoscopic surgical system 11000 includes an endoscope 11100, another surgical tool 11110 such as a pneumoperitoneum tube 11111 or an energy treatment tool 11112, a support arm device 11120 for supporting the endoscope 11100, and a cart 11200 on which various devices for endoscopic surgery are mounted.

The endoscope 11100 includes a lens barrel 11101 to be inserted into a body cavity of the patient 11132 in a region of a predetermined length from a tip thereof, and a camera head 11102 connected to a proximal end of the lens barrel 11101. In the illustrated example, the endoscope 11100 configured as a so-called rigid mirror including the rigid lens barrel 11101 is illustrated, but the endoscope 11100 may be configured as a so-called flexible mirror including a flexible lens barrel.

At the tip of the lens barrel 11101, an opening into which an objective lens is fitted is disposed. A light source device 11203 is connected to the endoscope 11100. Light generated by the light source device 11203 is guided to the tip of the lens barrel by a light guide extended inside the lens barrel 11101, and is emitted toward an observation target in a body cavity of the patient 11132 via the objective lens. Note that the endoscope 11100 may be a forward-viewing endoscope, an oblique-viewing endoscope, or a side-viewing endoscope.

An optical system and an imaging element are disposed inside the camera head 11102. Reflected light (observation light) from an observation target is converged on the imaging element by the optical system. The observation light is photoelectrically converted by the imaging element, and an electric signal corresponding to the observation light, that is, an image signal corresponding to an observation image is generated. The image signal is transmitted as RAW data to a camera control unit (CCU) 11201.

The CCU 11201 includes a central processing unit (CPU), a graphics processing unit (GPU), and the like, and integrally controls operations of the endoscope 11100 and the display device 11202. Moreover, the CCU 11201 receives an image signal from the camera head 11102, and performs, on the image signal, various image processing for displaying an image based on the image signal, such as development processing (demosaic processing), for example.

The display device 11202 displays an image based on an image signal subjected to image processing by the CCU 11201 under the control of the CCU 11201.

The light source device 11203 includes a light source such as a light emitting diode (LED), for example, and supplies irradiation light for imaging a surgical site or the like to the endoscope 11100.

An input device 11204 is an input interface to the endoscopic surgical system 11000. A user can input various kinds of information and instructions to the endoscopic surgical system 11000 via the input device 11204. For example, the user inputs an instruction or the like to change imaging conditions (type of irradiation light, magnification, focal length, and the like) by the endoscope 11100.

A treatment tool control device 11205 controls driving of the energy treatment tool 11112 for cauterizing and cutting a tissue, sealing a blood vessel, or the like. A pneumoperitoneum device 11206 feeds a gas into a body cavity via the pneumoperitoneum tube 11111 in order to inflate the body cavity of the patient 11132 for the purpose of securing a field of view by the endoscope 11100 and securing a working space of a surgeon. A recorder 11207 is a device capable of recording various kinds of information regarding surgery. A printer 11208 is a device capable of printing various kinds of information regarding surgery in various formats such as a text, an image, and a graph.

Note that the light source device 11203 for supplying irradiation light used for imaging a surgical site to the endoscope 11100 may include an LED, a laser light source, or a white light source constituted by a combination thereof, for example. In a case where the white light source is constituted by a combination of RGB laser light sources, the output intensity and the output timing of each color (each wavelength) can be controlled with high precision, and therefore adjustment of a white balance of an imaged image can be performed by the light source device 11203. Furthermore, in this case, by irradiating an observation target with laser light from each of the RGB laser light sources in a time division manner and controlling driving of an imaging element of the camera head 11102 in synchronization with the irradiation timing, it is also possible to image an image corresponding to each of RGB in a time division manner. According to this method, a color image can be obtained without disposing a color filter in the imaging element.

Furthermore, driving of the light source device 11203 may be controlled so as to change the intensity of light output at predetermined time intervals. By controlling driving of the imaging element of the camera head 11102 in synchronization with the timing of the change of the intensity of the light to acquire an image in a time division manner and synthesizing the image, a high dynamic range image without so-called blocked up shadows or blown out highlights can be generated.

Furthermore, the light source device 11203 may be configured so as to be able to supply light in a predetermined wavelength band corresponding to special light observation. In the special light observation, for example, by irradiation with light in a narrower band than irradiation light (in other words, white light) at the time of ordinary observation using wavelength dependency of light absorption in a body tissue, a predetermined tissue such as a blood vessel of a mucosal surface layer is imaged at a high contrast, that is, so-called narrow band imaging is performed. Alternatively, in the special light observation, fluorescence observation for obtaining an image by fluorescence generated by irradiation with excitation light may be performed. In the fluorescence observation, it is possible to observe fluorescence from a body tissue (autofluorescence observation) by irradiating the body tissue with excitation light, or to obtain a fluorescent image by injecting a reagent such as indocyanine green (ICG) into a body tissue and irradiating the body tissue with excitation light corresponding to a fluorescence wavelength of the reagent, for example. The light source device 11203 can be configured so as to be able to supply narrow band light and/or excitation light corresponding to such special light observation.

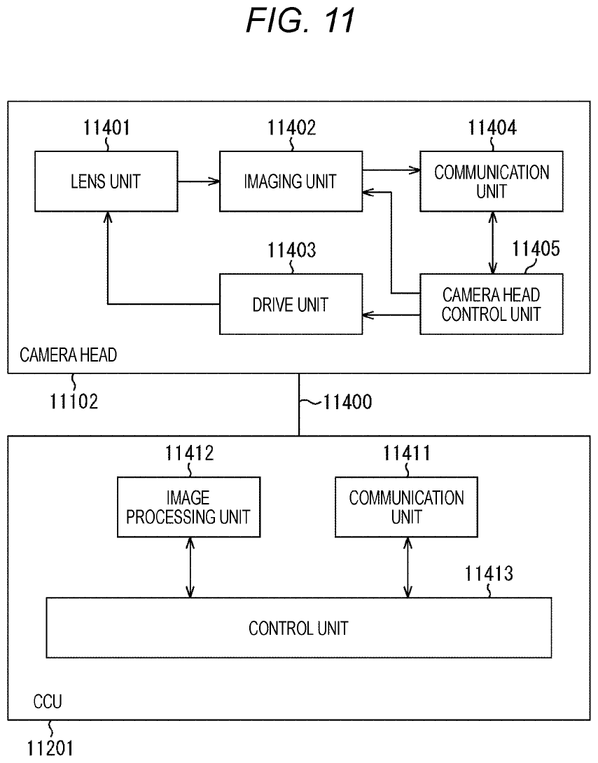

FIG. 11 is a block diagram illustrating examples of functional configurations of the camera head 11102 and the CCU 11201 illustrated in FIG. 10.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system disposed at a connecting portion with the lens barrel 11101. Observation light taken in from a tip of the lens barrel 11101 is guided to the camera head 11102 and is incident on the lens unit 11401. The lens unit 11401 includes a combination of a plurality of lenses including a zoom lens and a focus lens.

The imaging unit 11402 includes an imaging element. The imaging unit 11402 may include one imaging element (so-called single plate type) or a plurality of imaging elements (so-called multiplate type). In a case where the imaging unit 11402 includes multiplate type imaging elements, for example, an image signal corresponding to each of RGB may be generated by each imaging element, and a color image may be obtained by synthesizing these image signals. Alternatively, the imaging unit 11402 may include a pair of imaging elements for acquiring an image signal for each of the right eye and the left eye corresponding to three-dimensional (3D) display. By performing the 3D display, the surgeon 11131 can grasp the depth of a living tissue in a surgical site more accurately. Note that in a case where the imaging unit 11402 includes multiplate type imaging elements, a plurality of lens units 11401 can be disposed corresponding to the respective imaging elements.

Furthermore, the imaging unit 11402 is not necessarily disposed in the camera head 11102. For example, the imaging unit 11402 may be disposed just behind an objective lens inside the lens barrel 11101.

The drive unit 11403 includes an actuator, and moves a zoom lens and a focus lens of the lens unit 11401 by a predetermined distance along an optical axis under control of the camera head control unit 11405. Therefore, the magnification and the focus of an image imaged by the imaging unit 11402 can be appropriately adjusted.

The communication unit 11404 includes a communication device for transmitting and receiving various kinds of information to and from the CCU 11201. The communication unit 11404 transmits an image signal obtained from the imaging unit 11402 as RAW data to the CCU 11201 via the transmission cable 11400.

Furthermore, the communication unit 11404 receives a control signal for controlling driving of the camera head 11102 from the CCU 11201, and supplies the control signal to the camera head control unit 11405. The control signal includes information regarding imaging conditions such as information indicating designation of a frame rate of an imaged image, information indicating designation of an exposure value at the time of imaging, and/or information indicating designation of the magnification and the focus of an imaged image, for example.

Note that the imaging conditions such as the above-described frame rate, exposure value, magnification, and focus may be appropriately designated by a user, or may be automatically set by the control unit 11413 of the CCU 11201 on the basis of an acquired image signal. In the latter case, the endoscope 11100 has a so-called auto exposure (AE) function, a so-called auto focus (AF) function, and a so-called auto white balance (AWB) function.

The camera head control unit 11405 controls driving of the camera head 11102 on the basis of a control signal from the CCU 11201 received via the communication unit 11404.

The communication unit 11411 includes a communication device for transmitting and receiving various kinds of information to and from the camera head 11102. The communication unit 11411 receives an image signal transmitted from the camera head 11102 via the transmission cable 11400.

Furthermore, the communication unit 11411 transmits a control signal for controlling driving of the camera head 11102 to the camera head 11102. The image signal and the control signal can be transmitted by electric communication, optical communication, or the like.

The image processing unit 11412 performs various kinds of image processing on the image signal which is RAW data transmitted from the camera head 11102.

The control unit 11413 performs various kinds of control concerning imaging of a surgical site or the like by the endoscope 11100 and display of an imaged image obtained by imaging a surgical site or the like. For example, the control unit 11413 generates a control signal for controlling driving of the camera head 11102.

Furthermore, the control unit 11413 causes the display device 11202 to display an imaged image of a surgical site or the like on the basis of an image signal subjected to image processing by the image processing unit 11412. In this case, the control unit 11413 may recognize various objects in the imaged image using various image recognition techniques. For example, by detecting the shape, color, and the like of an edge of an object included in the imaged image, the control unit 11413 can recognize a surgical tool such as forceps, a specific living body part, bleeding, a mist at the time of using the energy treatment tool 11112, and the like. When the display device 11202 displays the imaged image, the control unit 11413 may cause the display device 11202 to superimpose and display various kinds of surgical support information on the image of the surgical site using the recognition result. The surgical support information is superimposed and displayed, and presented to the surgeon 11131. This makes it possible to reduce a burden on the surgeon 11131 and makes it possible for the surgeon 11131 to reliably perform surgery.

The transmission cable 11400 connecting the camera head 11102 to the CCU 11201 is an electric signal cable corresponding to communication of an electric signal, an optical fiber corresponding to optical communication, or a composite cable thereof.

Here, in the illustrated example, communication is performed by wire using the transmission cable 11400, but communication between the camera head 11102 and the CCU 11201 may be performed wirelessly.

An example of the endoscopic surgical system to which the technology according to the present disclosure can be applied has been described above. The technology according to the present disclosure can be applied to the endoscope 11100 and the imaging unit 11402 of the camera head 11102 among the above-described configurations. Specifically, the solid-state imaging element 11 of FIGS. 2 and 3 can be applied to the imaging unit 10402. By applying the technology according to the present disclosure to the imaging unit 10402, it is possible to achieve photoelectric conversion of blue light with high efficiency.

Note that the endoscopic surgical system has been described as an example here. However, the technology according to the present disclosure may also be applied to, for example, a microscopic surgery system or the like.

<Application Example to Mobile Body>

The technology according to the present disclosure (the present technology) can be applied to various products. For example, the technology according to the present disclosure may be achieved as an apparatus mounted on any type of mobile body such as an automobile, an electric vehicle, a hybrid electric vehicle, a motorcycle, a bicycle, a personal mobility, an airplane, a drone, a ship, or a robot.

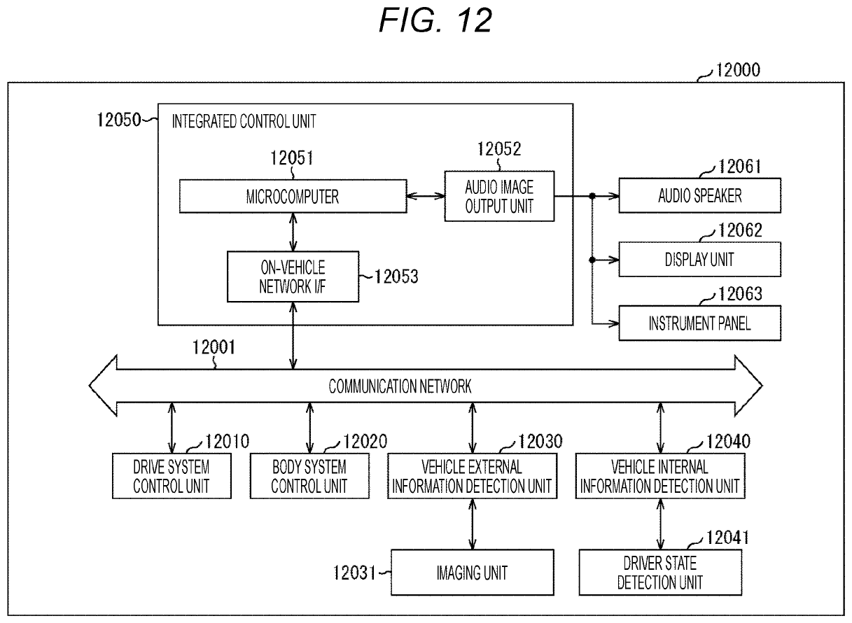

FIG. 12 is a block diagram illustrating an example of a schematic configuration of a vehicle control system which is an example of a mobile body control system to which the technology according to the present disclosure can be applied.

A vehicle control system 12000 includes a plurality of electronic control units connected to one another via a communication network 12001. In the example illustrated in FIG. 12, the vehicle control system 12000 includes a drive system control unit 12010, a body system control unit 12020, a vehicle external information detection unit 12030, a vehicle internal information detection unit 12040, and an integrated control unit 12050. Furthermore, as a functional configuration of the integrated control unit 12050, a microcomputer 12051, an audio image output unit 12052, and an on-vehicle network interface (I/F) 12053 are illustrated.

The drive system control unit 12010 controls an operation of a device related to a drive system of a vehicle according to various programs. For example, the drive system control unit 12010 functions as a control device of a driving force generating device for generating a driving force of a vehicle such as an internal combustion engine or a driving motor, a driving force transmitting mechanism for transmitting a driving force to wheels, a steering mechanism for adjusting a rudder angle of a vehicle, a braking device for generating a braking force of a vehicle, or the like.

The body system control unit 12020 controls operations of various devices mounted on a vehicle body according to various programs. For example, the body system control unit 12020 functions as a control device of a keyless entry system, a smart key system, a power window device, or various lamps such as a head lamp, a back lamp, a brake lamp, a turn indicator, and a fog lamp. In this case, to the body system control unit 12020, a radio wave transmitted from a portable device substituted for a key or signals of various switches can be input. The body system control unit 12020 receives input of the radio wave or signals and controls a door lock device, a power window device, a lamp, and the like of a vehicle.

The vehicle external information detection unit 12030 detects information outside a vehicle on which the vehicle control system 12000 is mounted. For example, to the vehicle external information detection unit 12030, an imaging unit 12031 is connected. The vehicle external information detection unit 12030 causes the imaging unit 12031 to image an image outside a vehicle and receives an imaged image. The vehicle external information detection unit 12030 may perform object detection processing or distance detection processing of a person, a car, an obstacle, a sign, a character on a road surface, or the like on the basis of the received image.

The imaging unit 12031 is a light sensor for receiving light and outputting an electric signal corresponding to the amount of light received. The imaging unit 12031 can output an electric signal as an image or output the electric signal as distance measurement information. Furthermore, the light received by the imaging unit 12031 may be visible light or invisible light such as infrared light.

The vehicle internal information detection unit 12040 detects information inside a vehicle. To the vehicle internal information detection unit 12040, for example, a driver state detection unit 12041 for detecting the state of a driver is connected. The driver state detection unit 12041 includes, for example, a camera for imaging a driver. The vehicle internal information detection unit 12040 may calculate the degree of fatigue or the degree of concentration of a driver or may determine whether or not the driver is dozing off on the basis of detection information input from the driver state detection unit 12041.

The microcomputer 12051 can calculate a control target value of a driving force generating device, a steering mechanism, or a braking device on the basis of information inside and outside a vehicle, acquired by the vehicle external information detection unit 12030 or the vehicle internal information detection unit 12040, and can output a control command to the drive system control unit 12010. For example, the microcomputer 12051 can perform cooperative control aiming at realizing a function of advanced driver assistance system (ADAS) including collision avoidance or impact mitigation of a vehicle, following travel based on inter-vehicle distance, vehicle speed maintenance travel, vehicle collision warning, vehicle lane departure warning, and the like.

Furthermore, the microcomputer 12051 can perform cooperative control aiming at, for example, automatic driving that autonomously travels without depending on driver's operation by controlling a driving force generating device, a steering mechanism, a braking device, or the like on the basis of information around a vehicle, acquired by the vehicle external information detection unit 12030 or the vehicle internal information detection unit 12040.

Furthermore, the microcomputer 12051 can output a control command to the body system control unit 12020 on the basis of vehicle external information acquired by the vehicle external information detection unit 12030. For example, the microcomputer 12051 can perform cooperative control aiming at antiglare such as switching from high beam to low beam by controlling a headlamp according to the position of a preceding vehicle or an oncoming vehicle detected by the vehicle external information detection unit 12030.

The audio image output unit 12052 transmits at least one of an audio output signal or an image output signal to an output device capable of visually or audibly notifying a passenger of a vehicle or the outside of the vehicle of information. In the example of FIG. 12, as the output device, an audio speaker 12061, a display unit 12062, and an instrument panel 12063 are illustrated. The display unit 12062 may include an on-board display and/or a head-up display, for example.

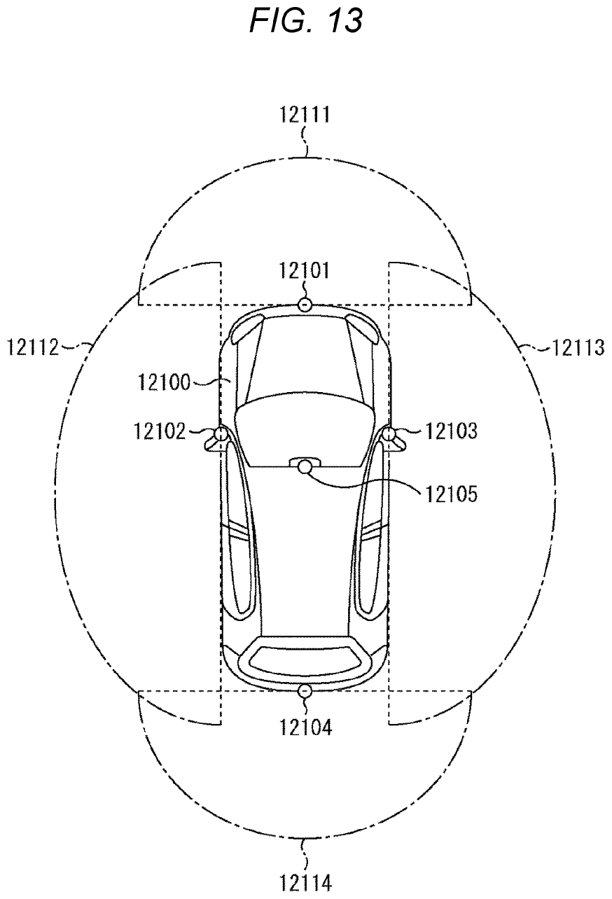

FIG. 13 is a diagram illustrating an example of an installation position of the imaging unit 12031.

In FIG. 13, the vehicle 12100 includes imaging units 12101, 12102, 12103, 12104, and 12105 as the imaging unit 12031.

The imaging units 12101, 12102, 12103, 12104, and 12105 are disposed, for example, in a front nose, a side mirror, a rear bumper, and a back door of the vehicle 12100, in an upper portion of a front glass in a passenger compartment, and the like. The imaging unit 12101 disposed in a front nose and the imaging unit 12105 disposed in an upper portion of a front glass in a passenger compartment mainly acquire images in front of the vehicle 12100. The imaging units 12102 and 12103 disposed in side mirrors mainly acquire images on sides of the vehicle 12100. The imaging unit 12104 disposed in a rear bumper or a back door mainly acquires an image behind the vehicle 12100. The front images acquired by the imaging units 12101 and 12105 are mainly used for detecting a preceding vehicle, a pedestrian, an obstacle, a traffic signal, a traffic sign, a lane, or the like.

Note that FIG. 13 illustrates examples of imaging ranges of the imaging units 12101 to 12104. An imaging range 12111 indicates an imaging range of the imaging unit 12101 disposed in a front nose. Imaging ranges 12112 and 12113 indicate imaging ranges of the imaging units 12102 and 12103 disposed in side mirrors, respectively. An imaging range 12114 indicates an imaging range of the imaging unit 12104 disposed in a rear bumper or a back door. For example, by superimposing image data imaged by the imaging units 12101 to 12104 on one another, an overhead view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 determines a distance to each three-dimensional object in the imaging range 12111 to 12114 and a temporal change (relative speed with respect to the vehicle 12100) of the distance on the basis of the distance information obtained from the imaging units 12101 to 12104, and can thereby particularly extract a three-dimensional object which is the nearest three-dimensional object on a traveling path of the vehicle 12100 and is traveling at a predetermined speed (for example, 0 km/h or more) in substantially the same direction as the vehicle 12100 as a preceding vehicle. Moreover, the microcomputer 12051 can set an inter-vehicle distance to be secured in advance in front of the preceding vehicle, and can perform automatic brake control (including following stop control), automatic acceleration control (including following start control), and the like. In this way, it is possible to perform cooperative control aiming at, for example, automatic driving that autonomously travels without depending on driver's operation.

For example, the microcomputer 12051 classifies three-dimensional object data related to a three-dimensional object into a two-wheeled vehicle, a regular vehicle, a large vehicle, a pedestrian, and another three-dimensional object such as a telegraph pole on the basis of the distance information obtained from the imaging units 12101 to 12104 and extracts data, and can use the extracted data for automatic avoidance of an obstacle. For example, the microcomputer 12051 identifies an obstacle around the vehicle 12100 as an obstacle that a driver of the vehicle 12100 can see and an obstacle that is difficult to see. Then, the microcomputer 12051 judges a collision risk indicating a risk of collision with each obstacle. When the collision risk is higher than a set value and there is a possibility of collision, the microcomputer 12051 can perform driving assistance for avoiding collision by outputting an alarm to a driver via the audio speaker 12061 or the display unit 12062, or performing forced deceleration or avoiding steering via the drive system control unit 12010.

At least one of the imaging units 12101 to 12104 may be an infrared camera for detecting an infrared ray. For example, the microcomputer 12051 can recognize a pedestrian by determining whether or not a pedestrian exists in imaged images of the imaging units 12101 to 12104. Such recognition of a pedestrian is performed by, for example, a procedure of extracting characteristic points in imaged images of the imaging units 12101 to 12104 as infrared cameras and a procedure of performing pattern matching processing on a series of characteristic points indicating an outline of an object and determining whether or not a pedestrian exists. If the microcomputer 12051 determines that a pedestrian exists in imaged images of the imaging units 12101 to 12104 and recognizes a pedestrian, the audio image output unit 12052 controls the display unit 12062 such that the display unit 12062 superimposes and displays a rectangular contour line for emphasis on the recognized pedestrian. Furthermore, the audio image output unit 12052 may control the display unit 12062 such that the display unit 12062 displays an icon or the like indicating a pedestrian at a desired position.

An example of the vehicle control system to which the technology according to the present disclosure can be applied has been described above. The technology according to the present disclosure can be applied to the imaging unit 12031 in the above-described configurations. Specifically, the solid-state imaging element 11 of FIGS. 2 and 3 can be applied to the imaging unit 12031. By applying the technology according to the present disclosure to the imaging unit 12031, it is possible to achieve photoelectric conversion of blue light with high efficiency.

Note that the present technology can have the following configurations.

<1> A solid-state imaging element including an organic photoelectric conversion element including at least two electrodes, in which

an organic photoelectric conversion layer is disposed between the two electrodes,

the organic photoelectric conversion layer includes at least a first organic semiconductor, a second organic semiconductor, and a third organic semiconductor,

the first organic semiconductor is a perylene derivative having characteristics of absorbing blue light and represented by the following chemical formula (11),

the second organic semiconductor is a semiconductor having characteristics of absorbing blue light and also having characteristics as a hole transport material having crystallinity,

the third organic semiconductor is a fullerene derivative, and

R1 to R12 in the chemical formula (11) are each independently selected from the group consisting of a hydrogen atom, a halogen atom, a linear, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, an aryl group, a heteroaryl group, a carboxy group, a carboxoamide group, a carboalkoxy group, an acyl group, a sulfonyl group, a cyano group, and a nitro group.

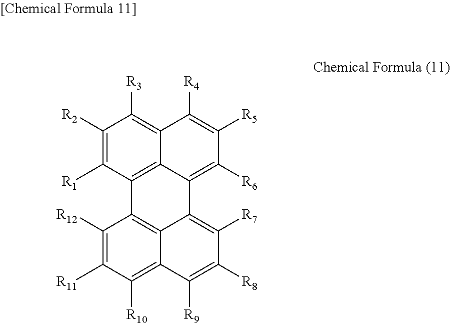

<2> The solid-state imaging element according to <1>, in which

any of the adjacent R1 to R12 in the chemical formula (11) are a part of a fused aliphatic ring or a fused aromatic ring.

<3> The solid-state imaging element according to <2>, in which

the fused aliphatic ring or the fused aromatic ring contains one or more atoms other than a carbon atom.

<4> The solid-state imaging element according to any one of <1> to <3>, in which

in the perylene derivative, R1 and R7 that are point-symmetrical with respect to a center ring in the chemical formula (11) as a central axis are the same, R6 and R12 that are point-symmetrical with respect to the center ring are the same, R4 and R10 that are point-symmetrical with respect to the center ring are the same, and R3 and R9 that are point-symmetrical with respect to the center ring are the same.

<5> The solid-state imaging element according to <4>, in which

in the perylene derivative, R2, R5, R8, and R11 in the chemical formula (11) are each a hydrogen atom or a carbon-bonded substituent.

<6> The solid-state imaging element according to any one of <1> to <5>, in which

in the perylene derivative, when R1 and R7 that are point-symmetrical with respect to a center ring in the chemical formula (11) as a central axis are the same, R6 and R12 that are point-symmetrical with respect to the center ring are the same, R4 and R10 that are point-symmetrical with respect to the center ring are the same, and R3 and R9 that are point-symmetrical with respect to the center ring are the same, R2, R5, R8, and R11 are each independently a hydrogen atom, a substituted or unsubstituted alkyl group having 1 to 20 carbon atoms, a cycloalkyl group, an aryl group, or a heteroaryl group.

<7> The solid-state imaging element according to any one of <1> to <6>, in which

the perylene derivative contains a polymer of a substance represented by the chemical formula (11).

<8> The solid-state imaging element according to any one of <1> to <7>, in which

the perylene derivative contains a substance represented by any one of the following chemical formulas (13) to (53).

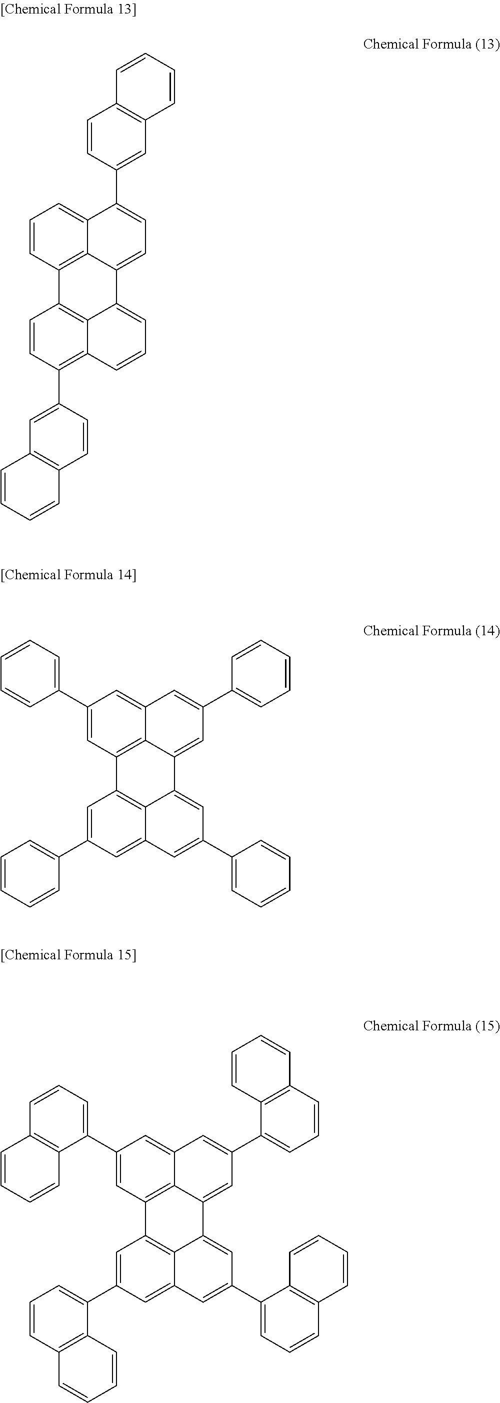

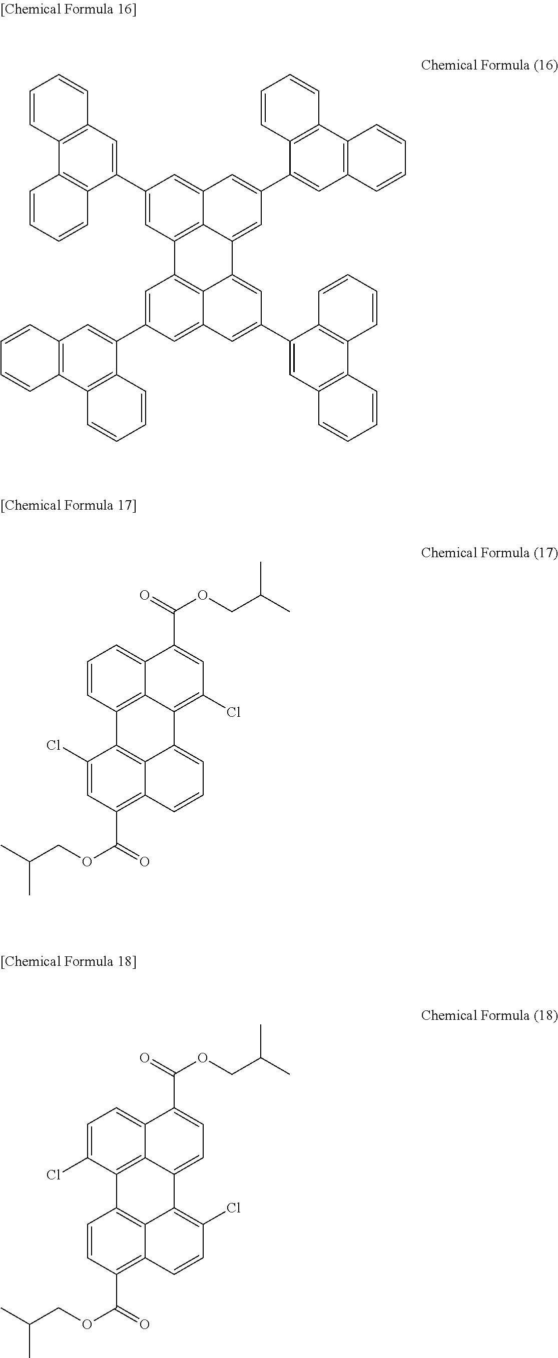

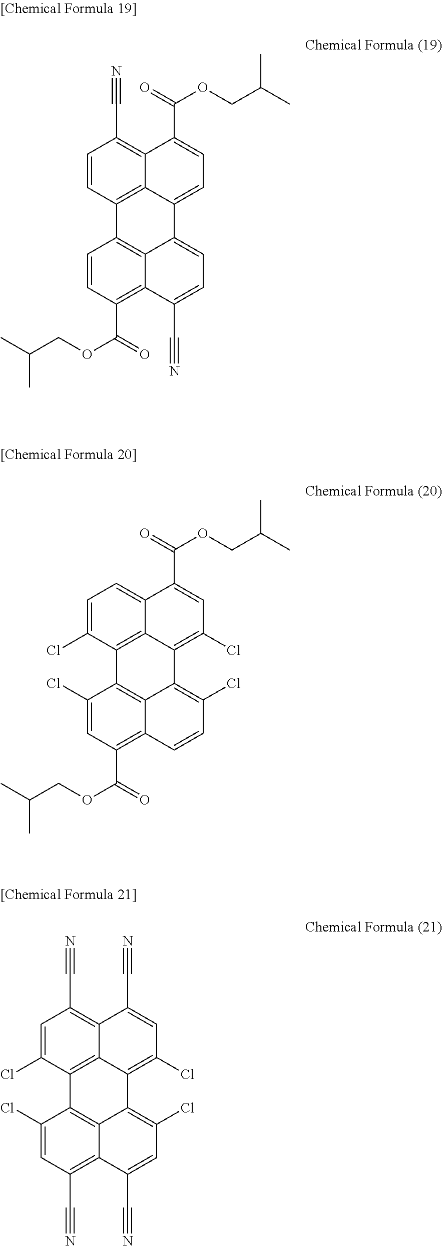

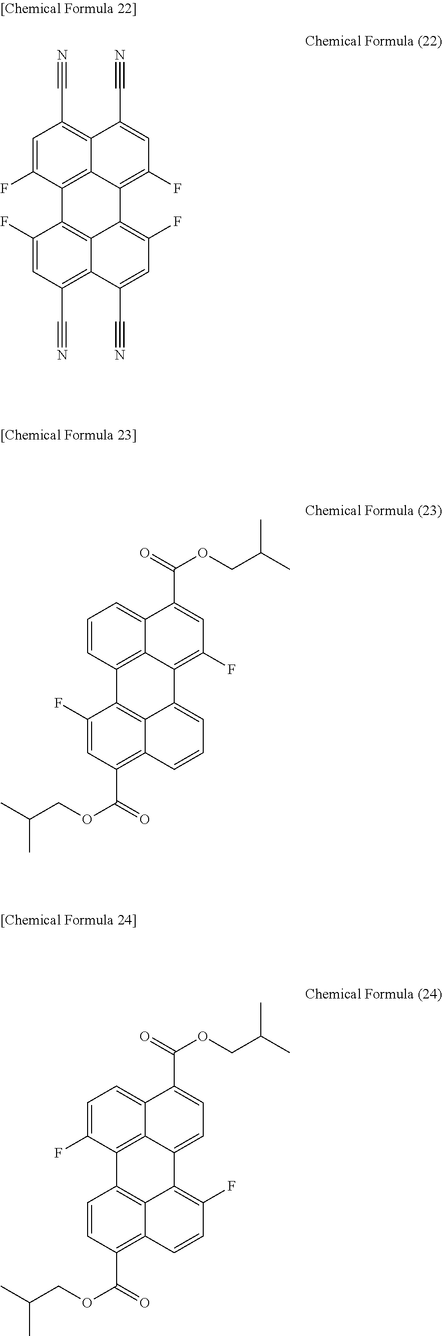

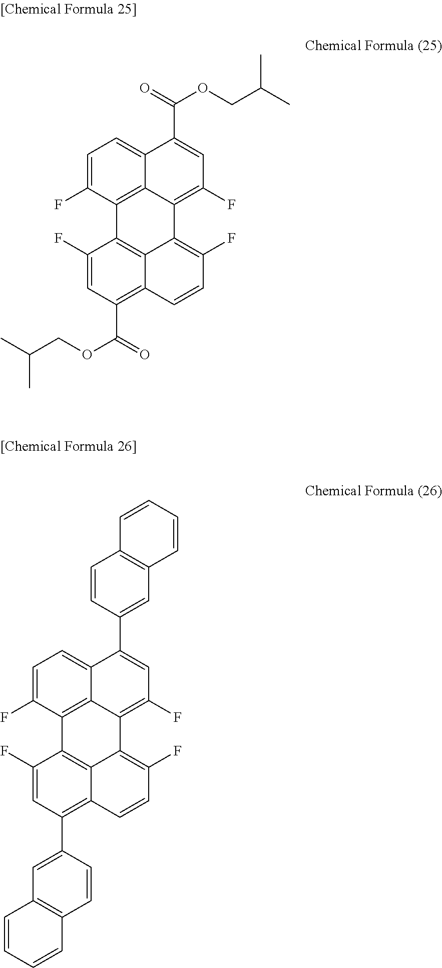 [SMILES: CC(C)COC(=O)c1cc(F)c2c3c(F)ccc4c(C(=O)OCC(C)C)cc(F)c(c5c(F)ccc1c52)c43 ; Fc1ccc2c(-c3ccc4ccccc4c3)cc(F)c3c4c(F)ccc5c(-c6ccc7ccccc7c6)cc(F)c(c1c23)c54]

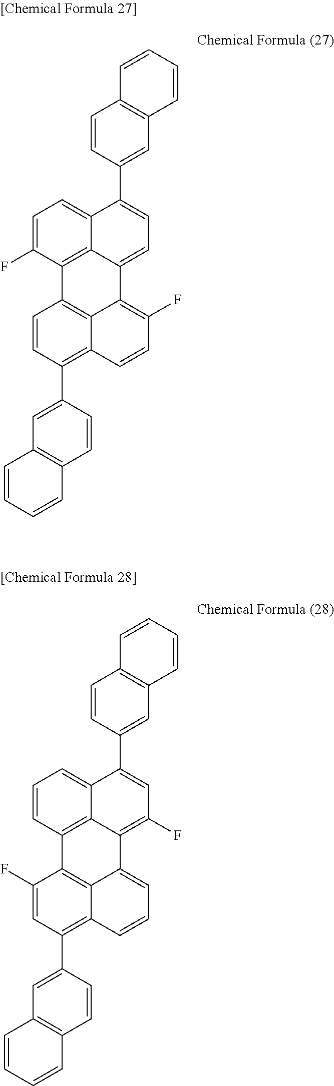 [SMILES: Fc1ccc2c(-c3ccc4ccccc4c3)ccc3c4c(F)ccc5c(-c6ccc7ccccc7c6)ccc(c1c23)c54 ; Fc1cc(-c2ccc3ccccc3c2)c2cccc3c4c(F)cc(-c5ccc6ccccc6c5)c5cccc(c1c23)c54]

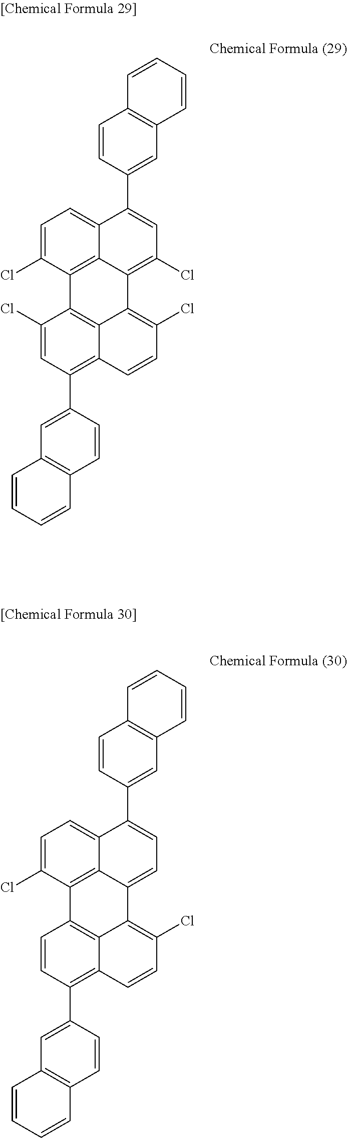 [SMILES: Clc1ccc2c(-c3ccc4ccccc4c3)cc(Cl)c3c4c(Cl)ccc5c(-c6ccc7ccccc7c6)cc(Cl)c(c1c23)c54 ; Clc1ccc2c(-c3ccc4ccccc4c3)ccc3c4c(Cl)ccc5c(-c6ccc7ccccc7c6)ccc(c1c23)c54]

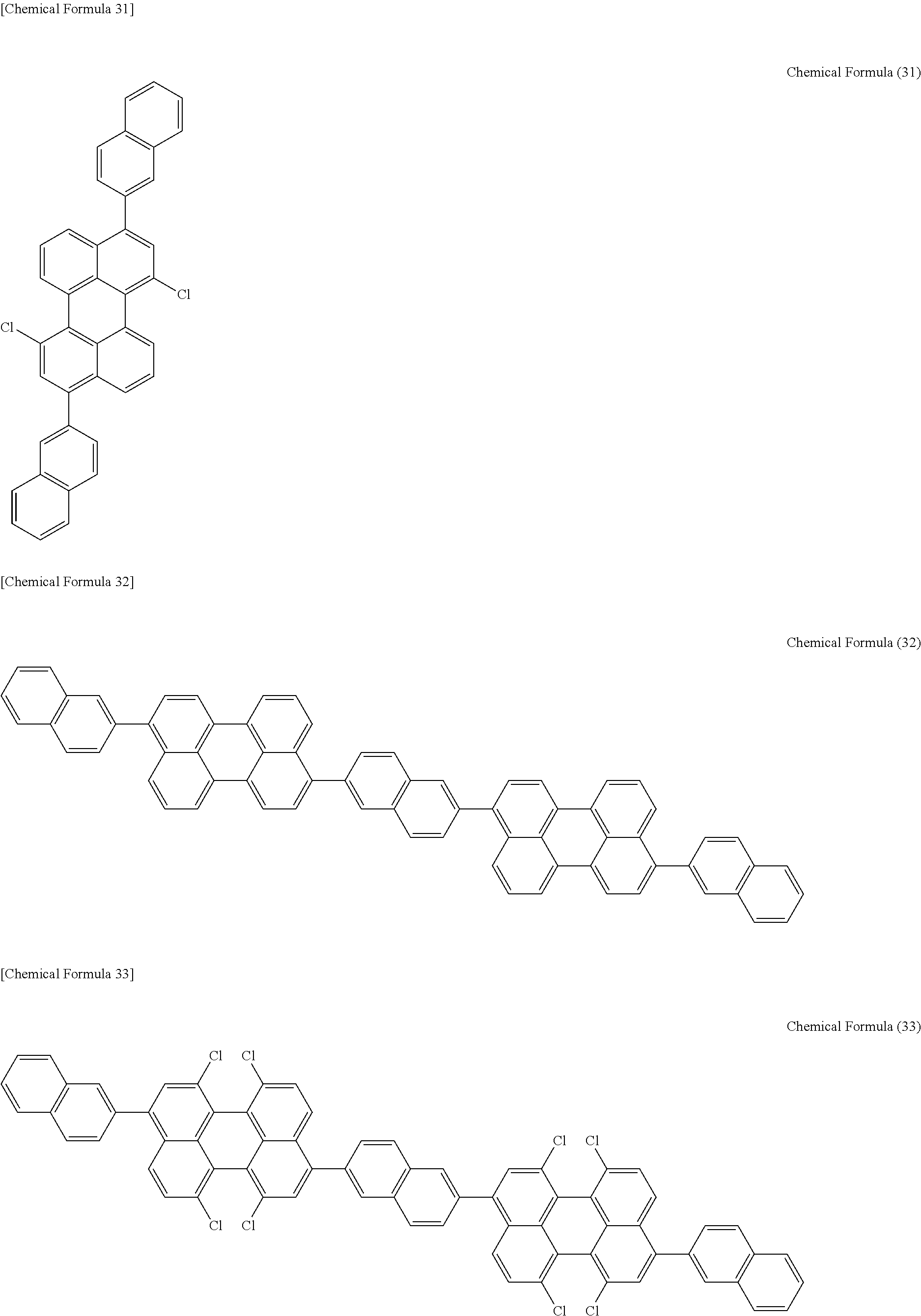

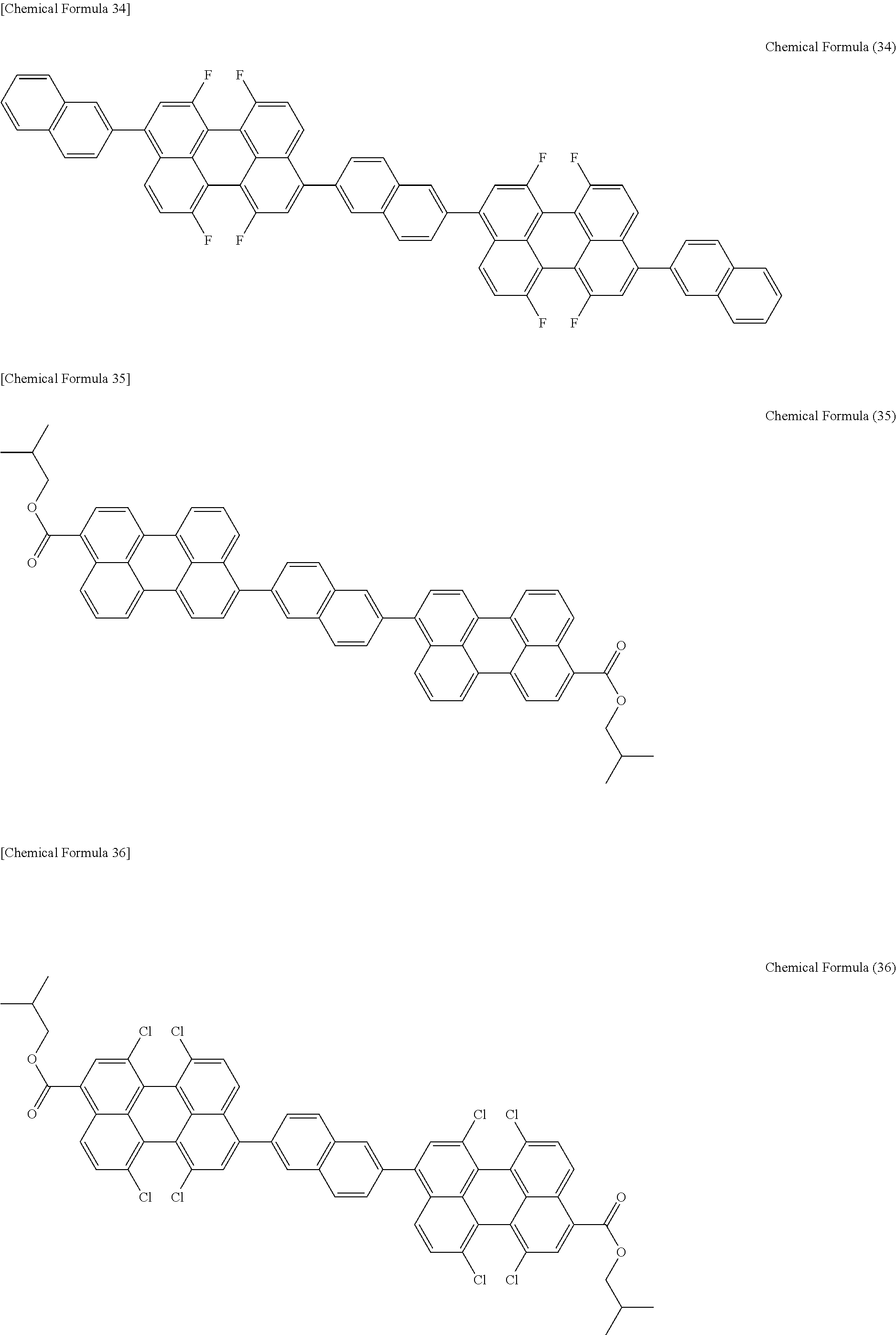

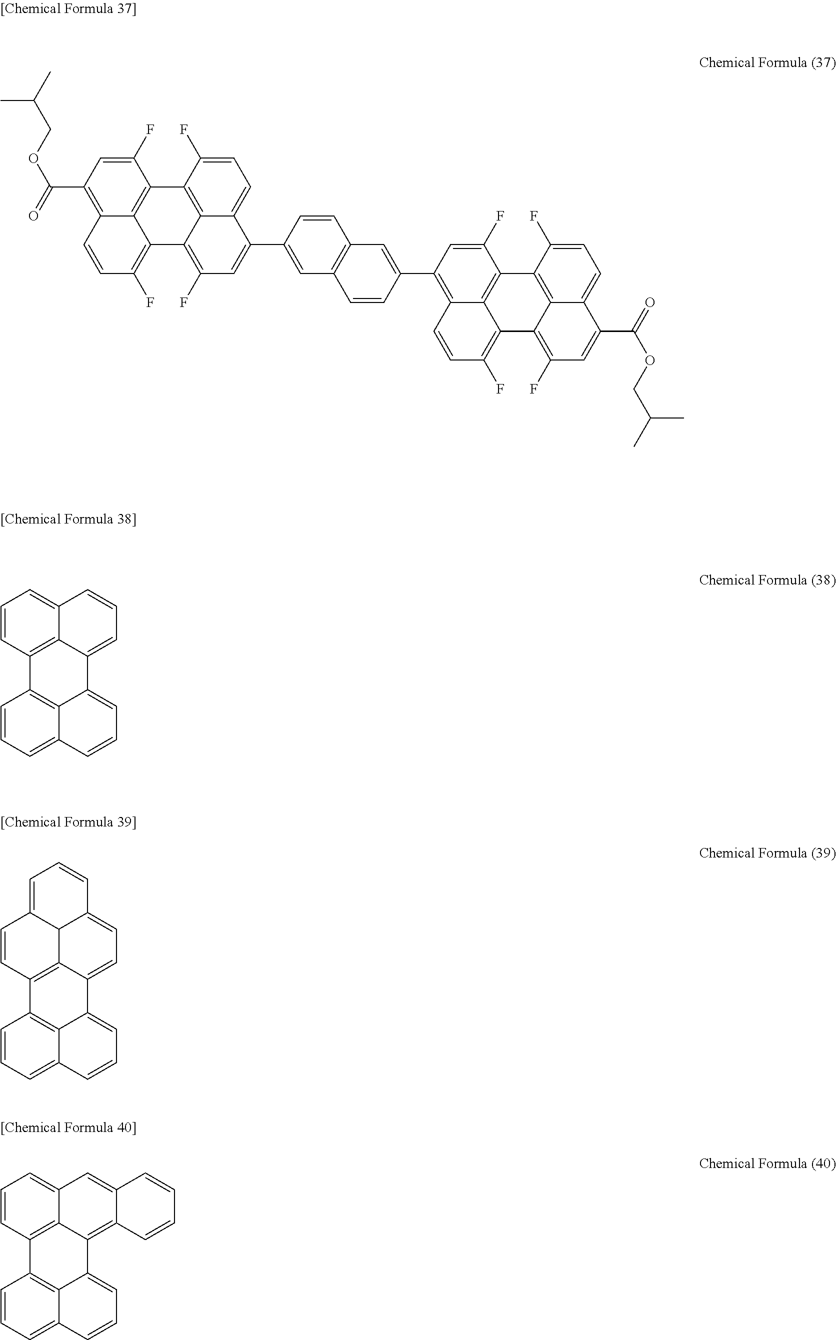

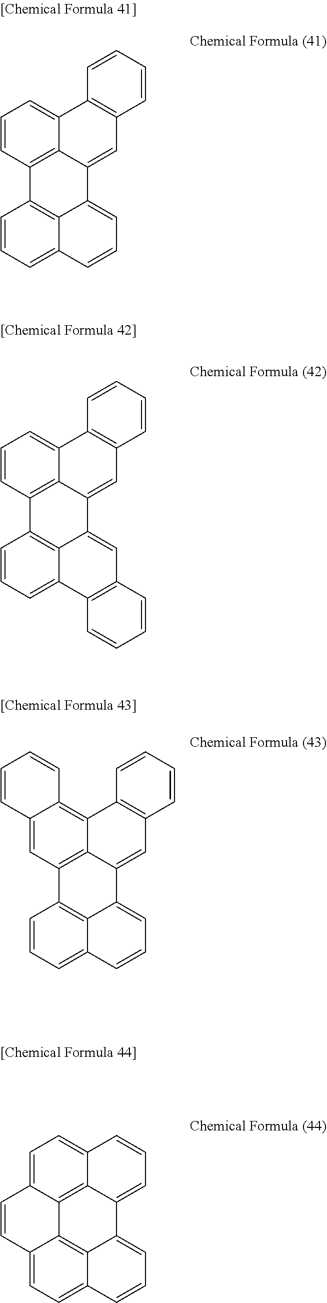

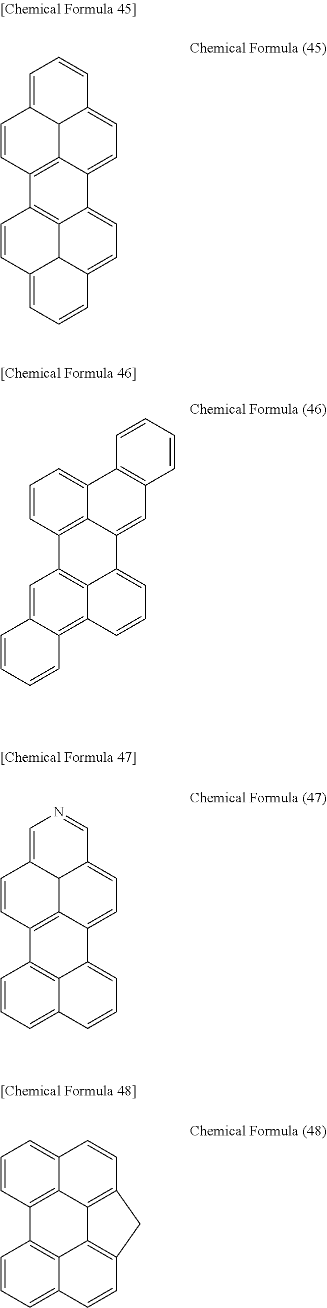

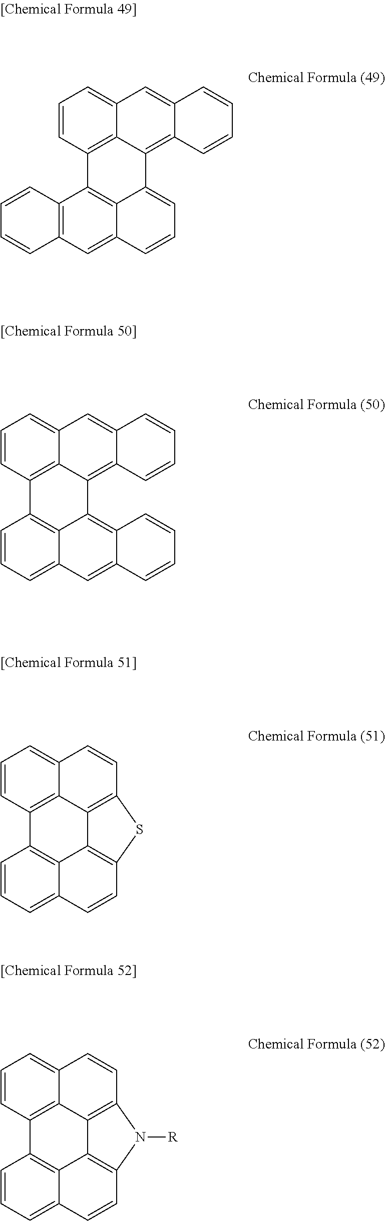

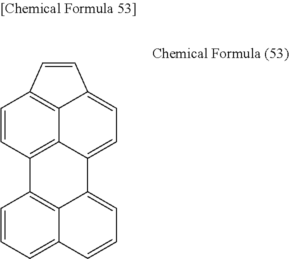 [SMILES: C1=Cc2ccc3c4cccc5cccc(c6ccc1c2c63)c54]

<9> The solid-state imaging element according to any one of <1> to <8>, in which

the organic photoelectric conversion layer strongly absorbs blue light that is light in a wavelength band around 400 to 500 nm, and weakly absorbs green light that is light in a wavelength band around 500 to 600 nm and red light that is light in a wavelength band around 600 to 700 nm.

<10> The solid-state imaging element according to <9>, in which

the organic photoelectric conversion layer has an absorption coefficient of more than 40,000 cm⁻¹ for the blue light and an absorption ratio of more than 80% for the blue light, and an absorption coefficient of less than 10,000 cm⁻¹ for each of the green light and the red light and an absorption ratio of less than 20% for each of the green light and the red light.

<11> The solid-state imaging element according to any one of <1> to <10>, in which

the first organic semiconductor strongly absorbs blue light that is light in a wavelength band around 400 to 500 nm, and weakly absorbs green light that is light in a wavelength band around 500 to 600 nm and red light that is light in a wavelength band around 600 to 700 nm.

<12> The solid-state imaging element according to <11>, in which

the first organic semiconductor has an absorption coefficient of more than 40,000 cm⁻¹ for the blue light and an absorption coefficient of less than 10,000 cm⁻¹ for each of the green light and the red light.

<13> The solid-state imaging element according to any one of <1> to <12>, in which

the second organic semiconductor strongly absorbs blue light that is light in a wavelength band around 400 to 500 nm, and weakly absorbs green light that is light in a wavelength band around 500 to 600 nm and red light that is light in a wavelength band around 600 to 700 nm, is a hole transport material, and exhibits a peak of crystallinity by out-of-plane X-ray measurement.

<14> The solid-state imaging element according to <13>, in which

the second organic semiconductor has an absorption coefficient of more than 40,000 cm⁻¹ for the blue light and an absorption coefficient of less than 10,000 cm⁻¹ for each of the green light and the red light, is a hole transport material having a hole mobility of 1E-6 cm⁻²/Vs or more and a HOMO of 5.3 to 6.0 eV, and has a peak of crystallinity at a position equivalent to that of a single film by out-of-plane X-ray measurement.

<15> The solid-state imaging element according to <14>, in which

the second organic semiconductor contains a substance represented by any one of the following chemical formulas (54) to (70).

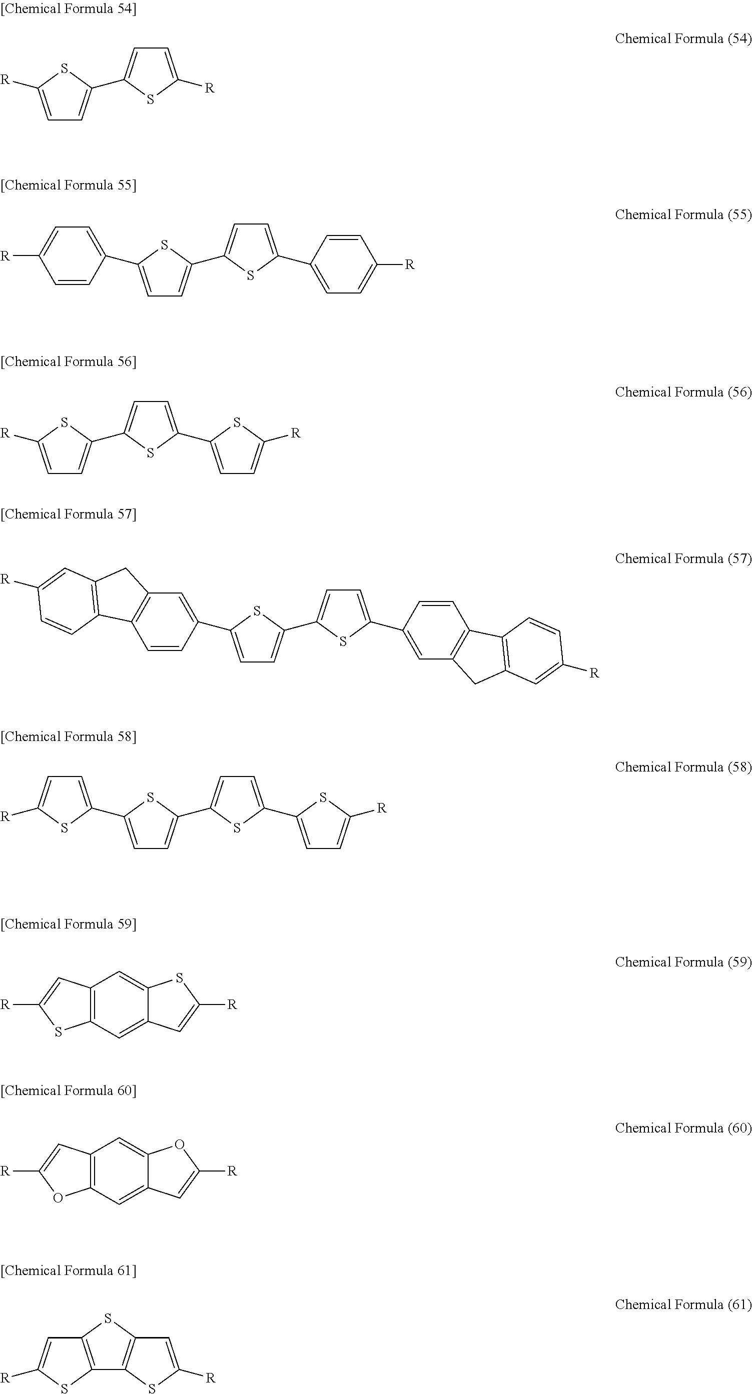

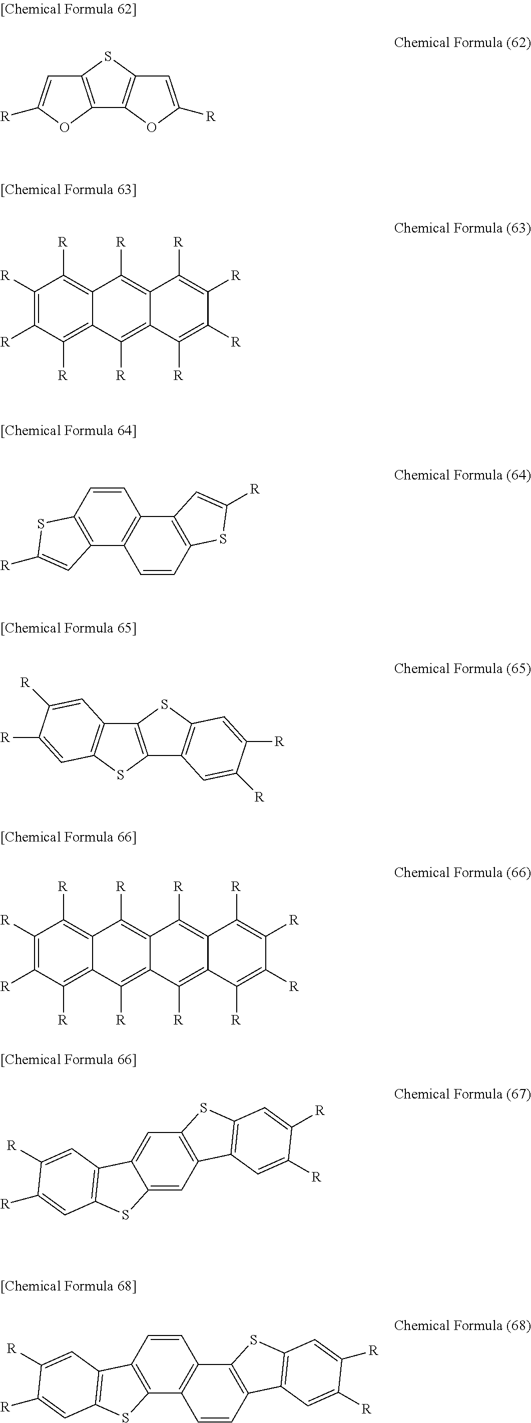

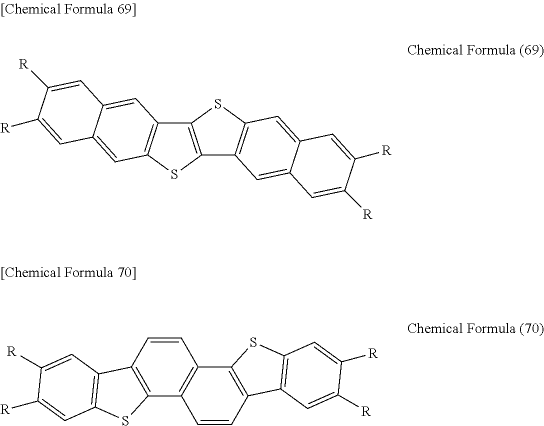

<16> The solid-state imaging element according to any one of <1> to <15>, in which

the third organic semiconductor is a substance represented by the following chemical formula (4) or (71).

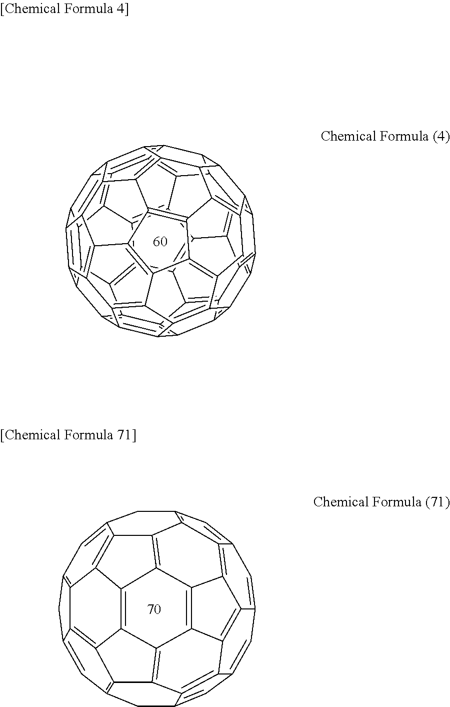

<17> The solid-state imaging element according to any one of <1> to <16>, in which

the first organic semiconductor, the second organic semiconductor, and the third organic semiconductor are mixed at a predetermined ratio, and a film of each of the first organic semiconductor, the second organic semiconductor, and the third organic semiconductor is formed at a predetermined film formation rate so as to form the organic photoelectric conversion layer.

<18> The solid-state imaging element according to <17>, in which

the third organic semiconductor is mixed at a ratio of about 20% of the organic photoelectric conversion layer, and each of the first organic semiconductor and the second organic semiconductor is mixed at a ratio of about 40% of the organic photoelectric conversion layer.

<19> A method for manufacturing a solid-state imaging element, the method including:

a first step of forming a first electrode;

a second step of forming an organic photoelectric conversion layer on an upper layer of the first electrode; and

a third step of forming a second electrode on an upper layer of the organic photoelectric conversion layer, in which

the organic photoelectric conversion layer includes at least a first organic semiconductor, a second organic semiconductor, and a third organic semiconductor,

the first organic semiconductor is a perylene derivative having characteristics of absorbing blue light and represented by the following chemical formula (11),

the second organic semiconductor is a semiconductor having characteristics of absorbing blue light and also having characteristics as a hole transport material having crystallinity, and

the third organic semiconductor is a fullerene derivative.

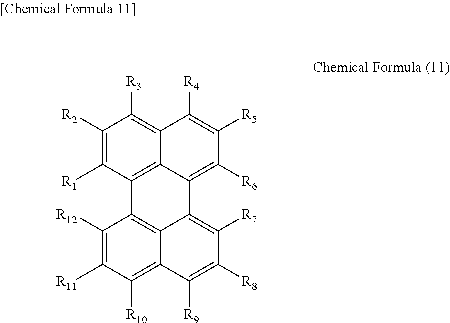

<20> A solid-state imaging apparatus including an organic photoelectric conversion element including at least two electrodes, in which

an organic photoelectric conversion layer is disposed between the two electrodes,

the organic photoelectric conversion layer includes at least a first organic semiconductor, a second organic semiconductor, and a third organic semiconductor,

the first organic semiconductor is a perylene derivative having characteristics of absorbing blue light and represented by the following chemical formula (11),

the second organic semiconductor is a semiconductor having characteristics of absorbing blue light and also having characteristics as a hole transport material having crystallinity,

the third organic semiconductor is a fullerene derivative, and

R1 to R12 in the chemical formula (11) are each independently selected from the group consisting of a hydrogen atom, a halogen atom, a linear, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, an aryl group, a heteroaryl group, a carboxy group, a carboxoamide group, a carboalkoxy group, an acyl group, a sulfonyl group, a cyano group, and a nitro group.

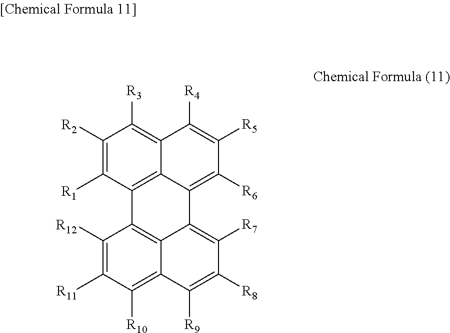

### REFERENCE SIGNS LIST

11 Solid-state imaging element
21 to 23 Photoelectric conversion element (photoelectric conversion film)
31 Photoelectric conversion element (photodiode)
41 First electrode
42 Charge accumulation electrode
43 Insulating layer
44 Semiconductor layer
45 Hole blocking layer
46 Photoelectric conversion layer
47 Work function adjustment layer
48 Second electrode
50 Evaluation element
51 First electrode
52 Hole blocking layer
53 Photoelectric conversion material layer
54 Second electrode
55 Substrate

1. A solid-state imaging element comprising an organic photoelectric conversion element including at least two electrodes, wherein
an organic photoelectric conversion layer is disposed between the two electrodes,
the organic photoelectric conversion layer includes at least a first organic semiconductor, a second organic semiconductor, and a third organic semiconductor,
the first organic semiconductor is a perylene derivative having characteristics of absorbing blue light and represented by the following chemical formula (11),
the second organic semiconductor is a semiconductor having characteristics of absorbing blue light and also having characteristics as a hole transport material having crystallinity,
the third organic semiconductor is a fullerene derivative, and
R1 to R12 in the chemical formula (11) are each independently selected from the group consisting of a hydrogen atom, a halogen atom, a linear, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, an aryl group, a heteroaryl group, a carboxy group, a carboxoamide group, a carboalkoxy group, an acyl group, a sulfonyl group, a cyano group, and a nitro group.

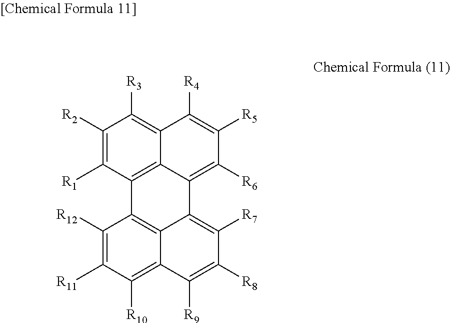

2. The solid-state imaging element according to claim 1, wherein
any of the adjacent R1 to R12 in the chemical formula (11) are a part of a fused aliphatic ring or a fused aromatic ring.

3. The solid-state imaging element according to claim 2, wherein
the fused aliphatic ring or the fused aromatic ring contains one or more atoms other than a carbon atom.

4. The solid-state imaging element according to claim 1, wherein
in the perylene derivative, R1 and R7 that are point-symmetrical with respect to a center ring in the chemical formula (11) as a central axis are the same, R6 and R12 that are point-symmetrical with respect to the center ring are the same, R4 and R10 that are point-symmetrical with respect to the center ring are the same, and R3 and R9 that are point-symmetrical with respect to the center ring are the same.

5. The solid-state imaging element according to claim 4, wherein
in the perylene derivative, R2, R5, R8, and R11 in the chemical formula (11) are each a hydrogen atom or a carbon-bonded substituent.

6. The solid-state imaging element according to claim 1, wherein
in the perylene derivative, when R1 and R7 that are point-symmetrical with respect to a center ring in the chemical formula (11) as a central axis are the same, R6 and R12 that are point-symmetrical with respect to the center ring are the same, R4 and R10 that are point-symmetrical with respect to the center ring are the same, and R3 and R9 that are point-symmetrical with respect to the center ring are the same, R2, R5, R8, and R11 are each independently a hydrogen atom, a substituted or unsubstituted alkyl group having 1 to 20 carbon atoms, a cycloalkyl group, an aryl group, or a heteroaryl group.

7. The solid-state imaging element according to claim 1, wherein
the perylene derivative contains a polymer of a substance represented by the chemical formula (11).

8. The solid-state imaging element according to claim 1, wherein
the perylene derivative contains a substance represented by any one of the following chemical formulas (13) to (53).

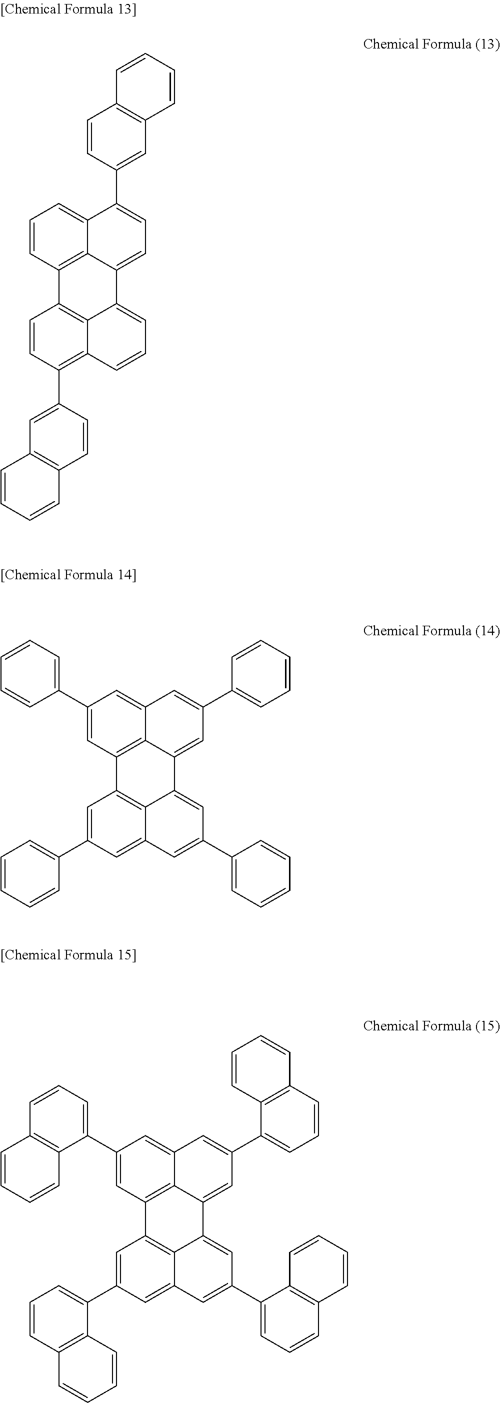

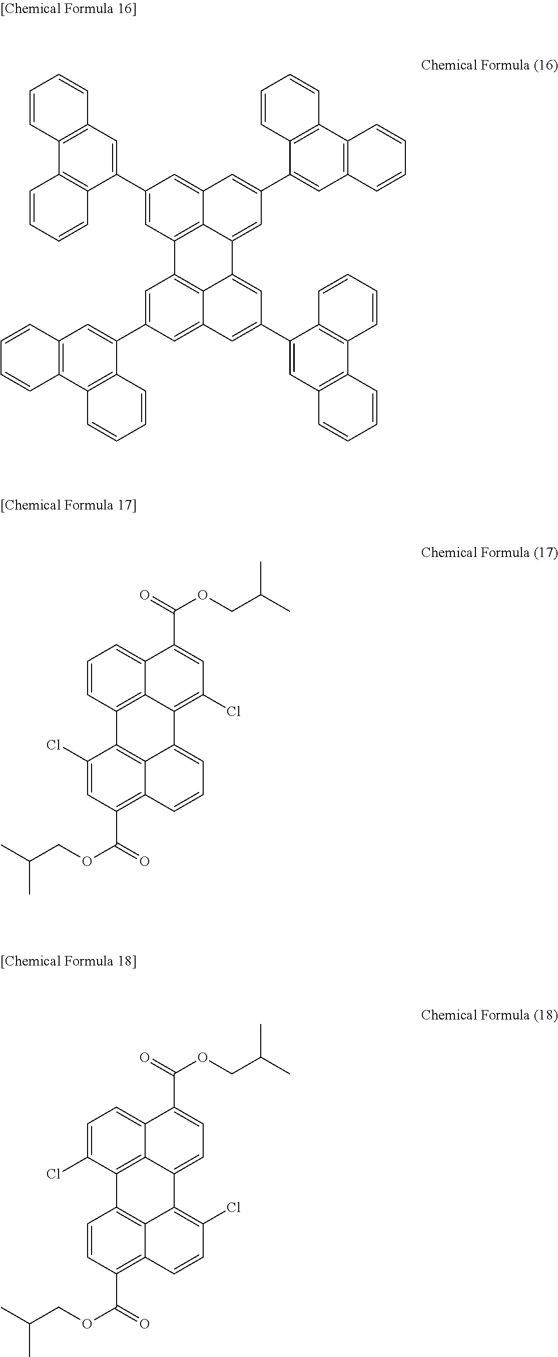

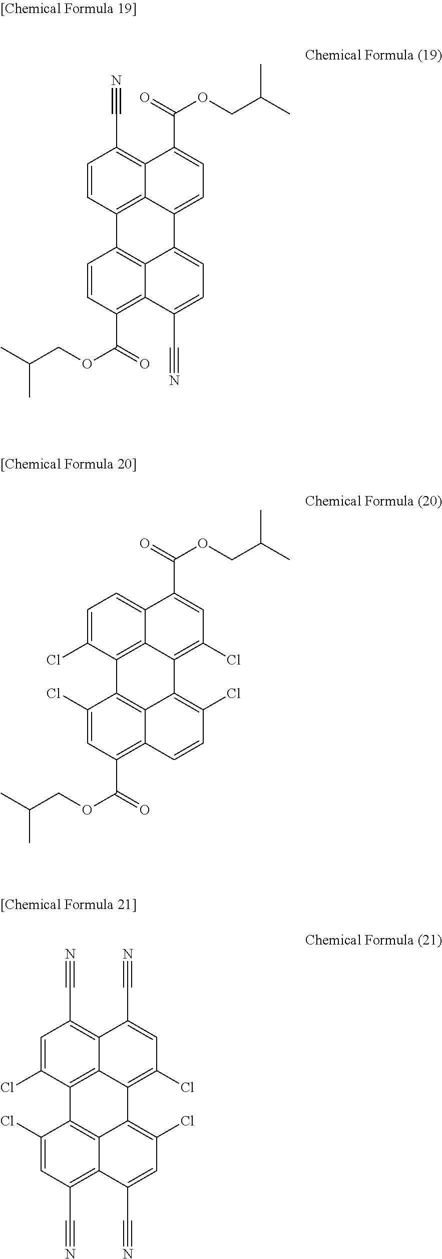

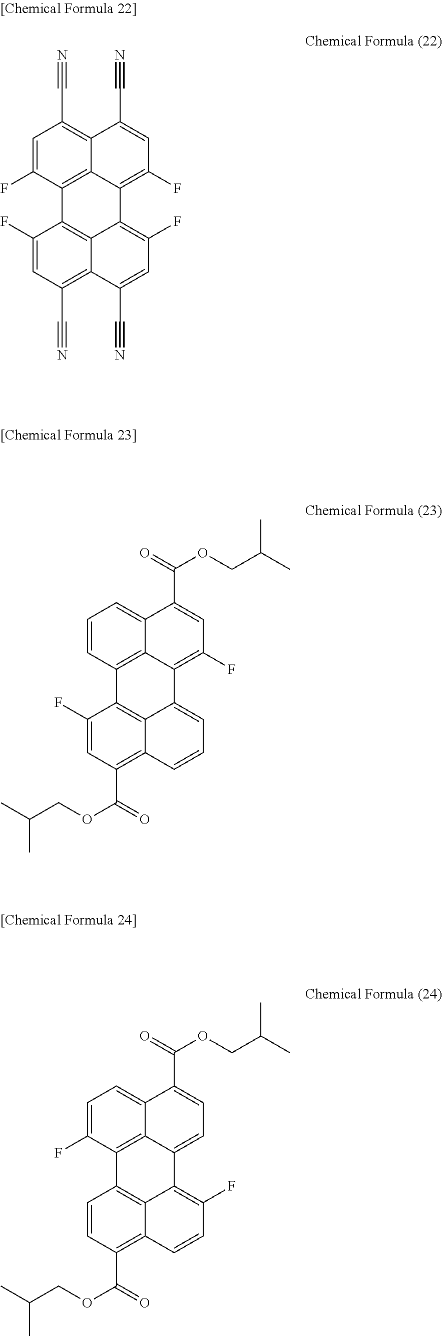

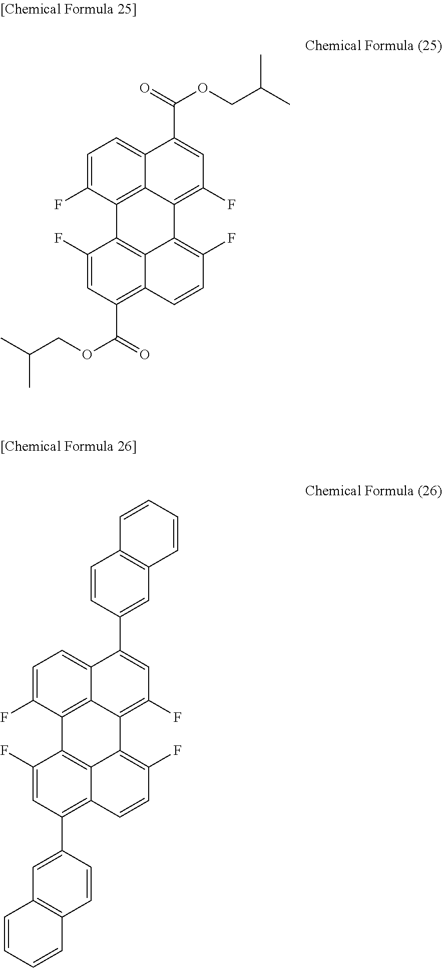 [SMILES: CC(C)COC(=O)c1cc(F)c2c3c(F)ccc4c(C(=O)OCC(C)C)cc(F)c(c5c(F)ccc1c52)c43 ; Fc1ccc2c(-c3ccc4ccccc4c3)cc(F)c3c4c(F)ccc5c(-c6ccc7ccccc7c6)cc(F)c(c1c23)c54]

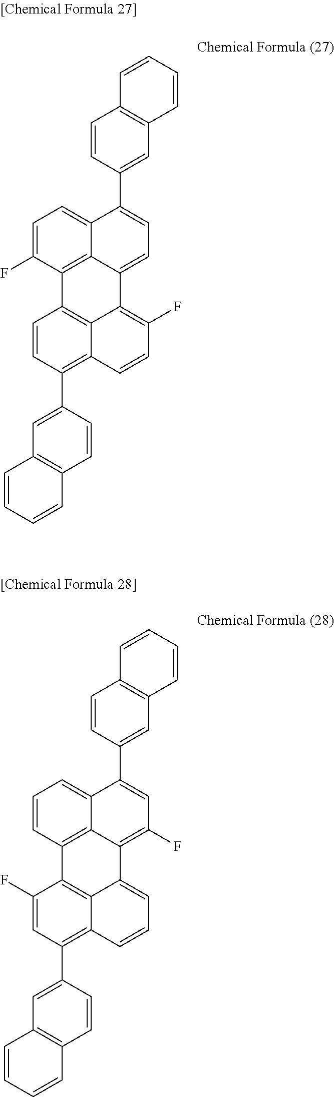 [SMILES: Fc1ccc2c(-c3ccc4ccccc4c3)ccc3c4c(F)ccc5c(-c6ccc7ccccc7c6)ccc(c1c23)c54 ; Fc1cc(-c2ccc3ccccc3c2)c2cccc3c4c(F)cc(-c5ccc6ccccc6c5)c5cccc(c1c23)c54]

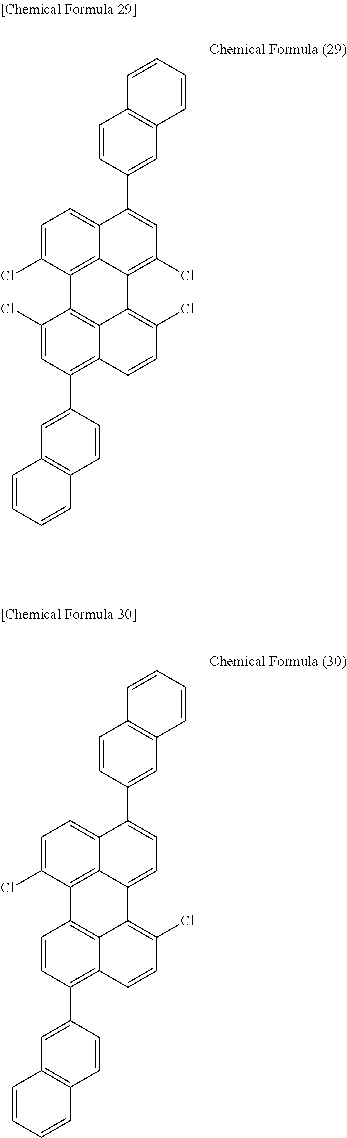 [SMILES: Clc1ccc2c(-c3ccc4ccccc4c3)cc(Cl)c3c4c(Cl)ccc5c(-c6ccc7ccccc7c6)cc(Cl)c(c1c23)c54 ; Clc1ccc2c(-c3ccc4ccccc4c3)ccc3c4c(Cl)ccc5c(-c6ccc7ccccc7c6)ccc(c1c23)c54]

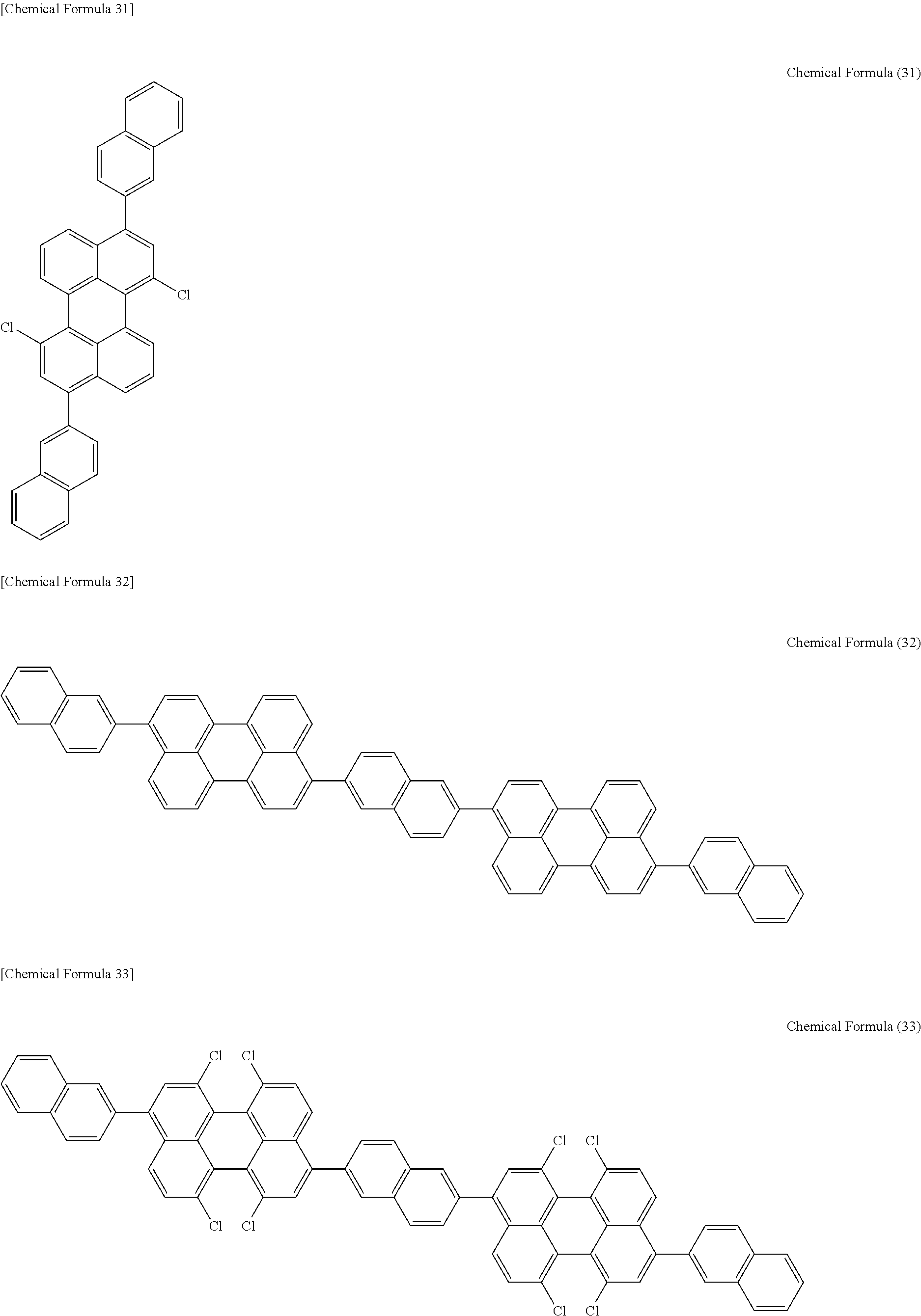

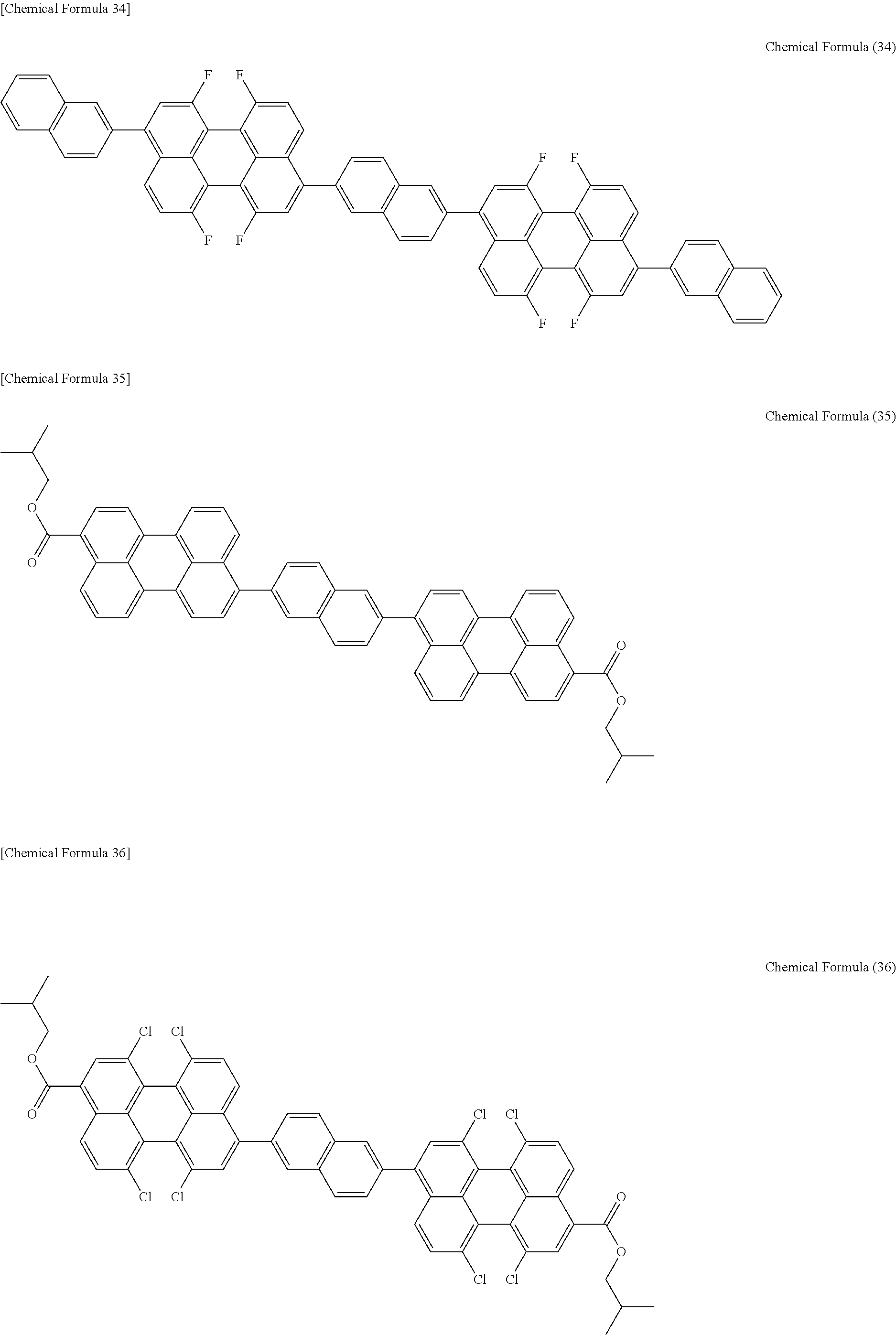

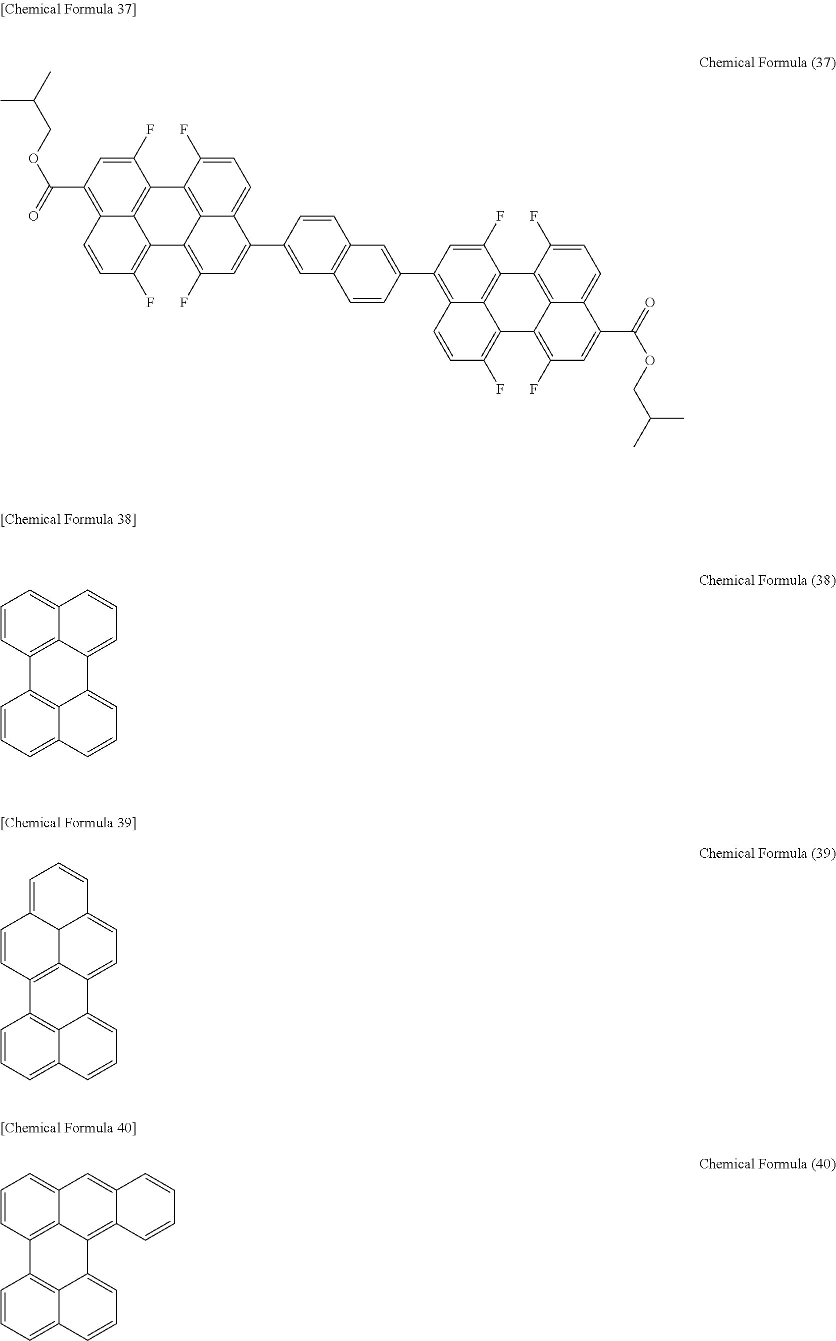

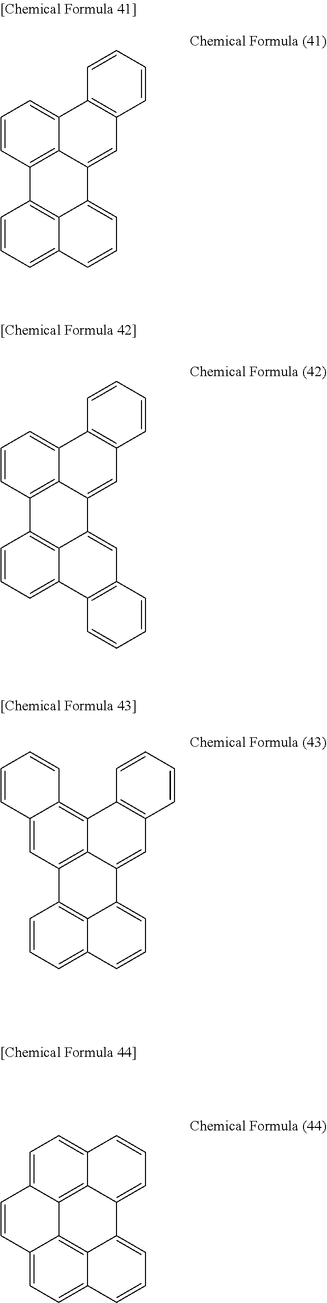

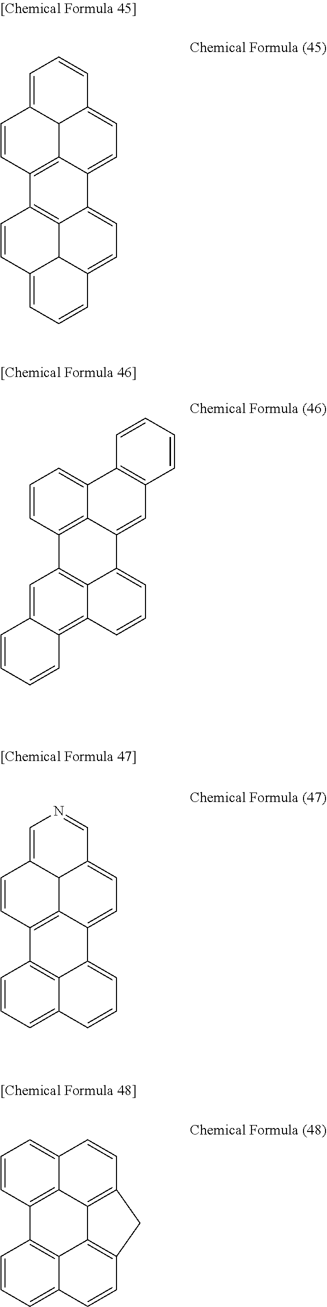

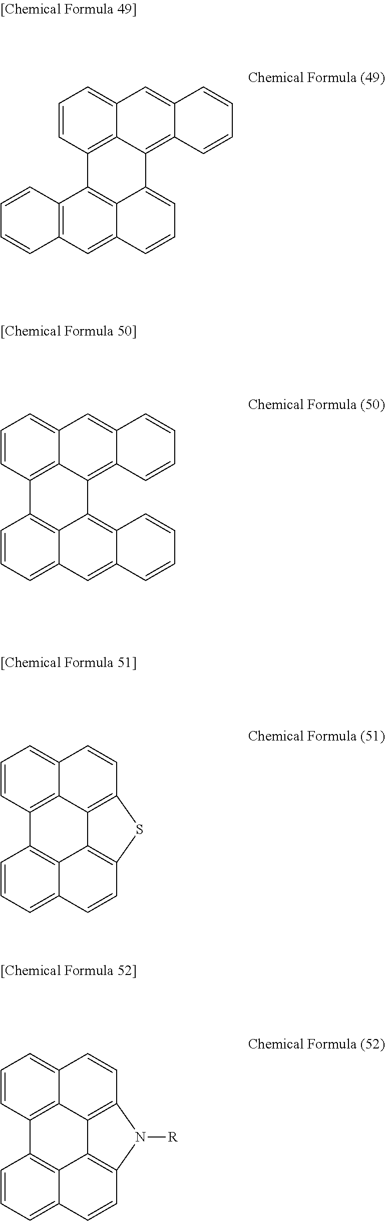

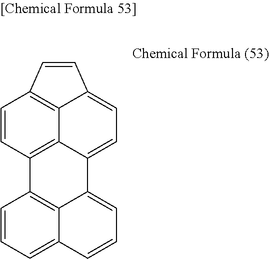 [SMILES: C1=Cc2ccc3c4cccc5cccc(c6ccc1c2c63)c54]

9. The solid-state imaging element according to claim 1, wherein
the organic photoelectric conversion layer strongly absorbs blue light that is light in a wavelength band around 400 to 500 nm, and weakly absorbs green light that is light in a wavelength band around 500 to 600 nm and red light that is light in a wavelength band around 600 to 700 nm.

10. The solid-state imaging element according to claim 9, wherein
the organic photoelectric conversion layer has an absorption coefficient of more than 40,000 cm⁻¹ for the blue light and an absorption ratio of more than 80% for the blue light, and an absorption coefficient of less than 10,000 cm⁻¹ for each of the green light and the red light and an absorption ratio of less than 20% for each of the green light and the red light.

11. The solid-state imaging element according to claim 1, wherein
the first organic semiconductor strongly absorbs blue light that is light in a wavelength band around 400 to 500 nm, and weakly absorbs green light that is light in a wavelength band around 500 to 600 nm and red light that is light in a wavelength band around 600 to 700 nm.

12. The solid-state imaging element according to claim 11, wherein
the first organic semiconductor has an absorption coefficient of more than 40,000 cm⁻¹ for the blue light and an absorption coefficient of less than 10,000 cm⁻¹ for each of the green light and the red light.

13. The solid-state imaging element according to claim 1, wherein
the second organic semiconductor strongly absorbs blue light that is light in a wavelength band around 400 to 500 nm, and weakly absorbs green light that is light in a wavelength band around 500 to 600 nm and red light that is light in a wavelength band around 600 to 700 nm, is a hole transport material, and exhibits a peak of crystallinity by out-of-plane X-ray measurement.

14. The solid-state imaging element according to claim 13, wherein
the second organic semiconductor has an absorption coefficient of more than 40,000 cm⁻¹ for the blue light and an absorption coefficient of less than 10,000 cm⁻¹ for each of the green light and the red light, is a hole transport material having a hole mobility of 1E-6 cm⁻²/Vs or more and a HOMO of 5.3 to 6.0 eV, and has a peak of crystallinity at a position equivalent to that of a single film by out-of-plane X-ray measurement.

15. The solid-state imaging element according to claim 14, wherein
the second organic semiconductor contains a substance represented by any one of the following chemical formulas (54) to (70).

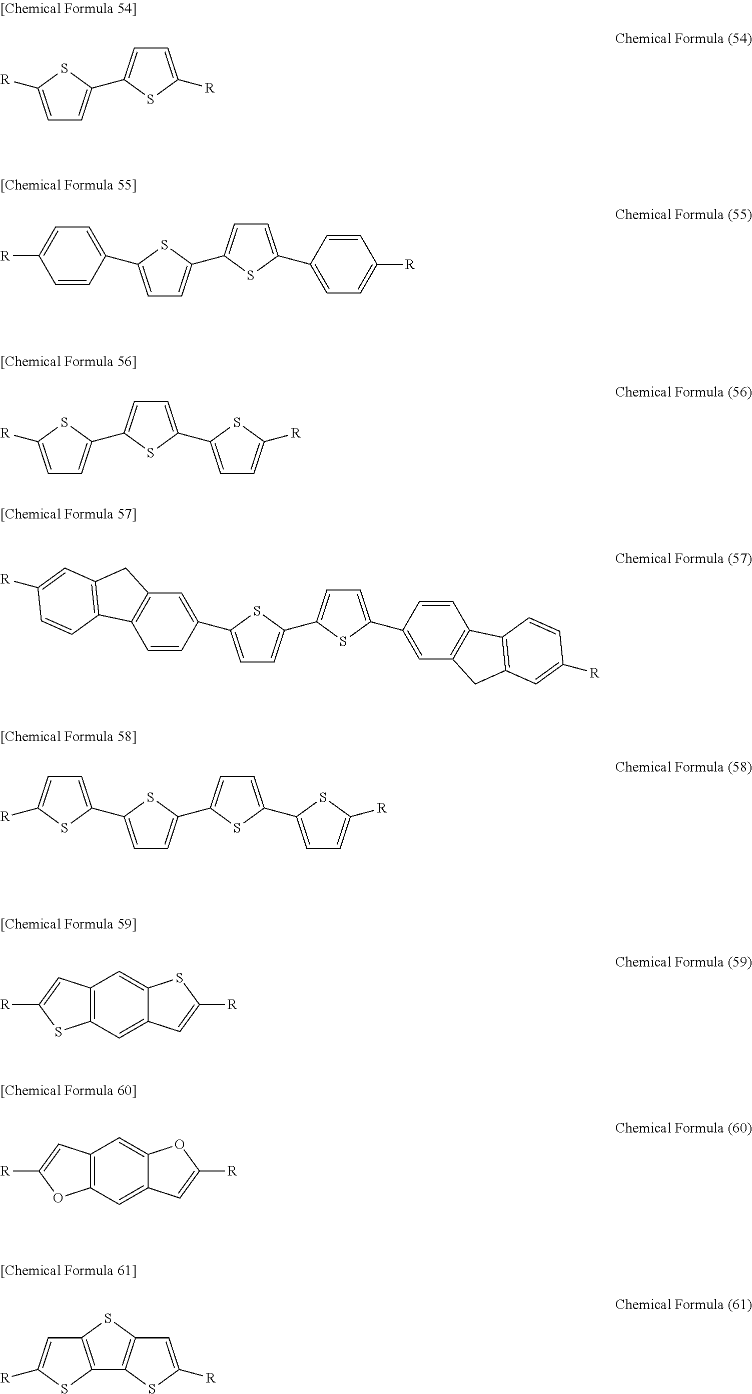

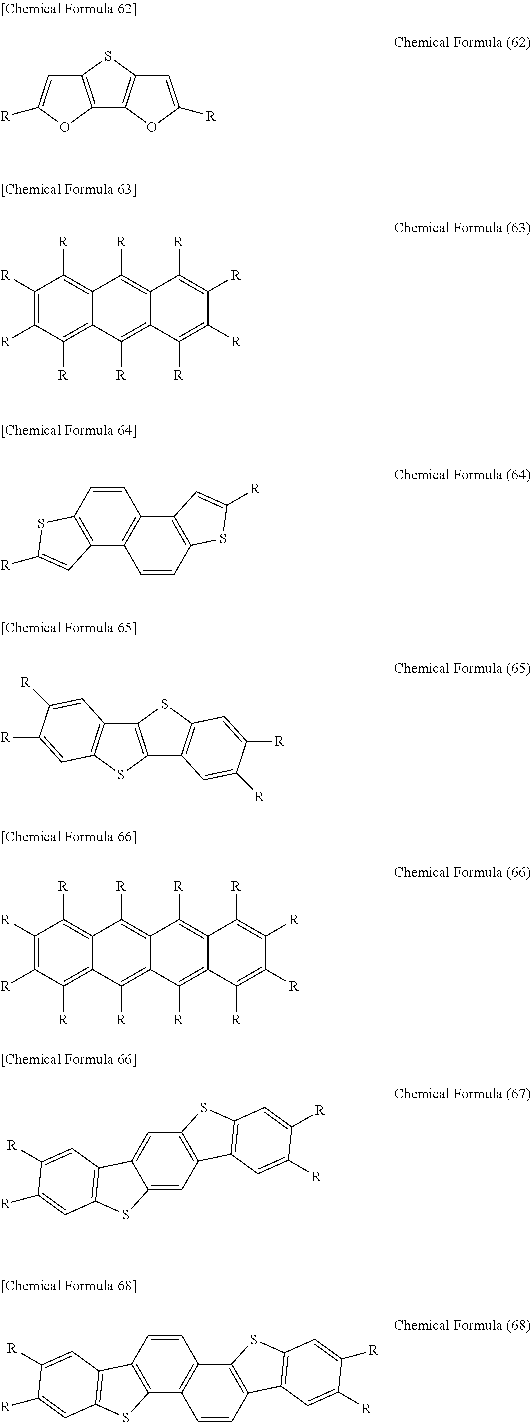

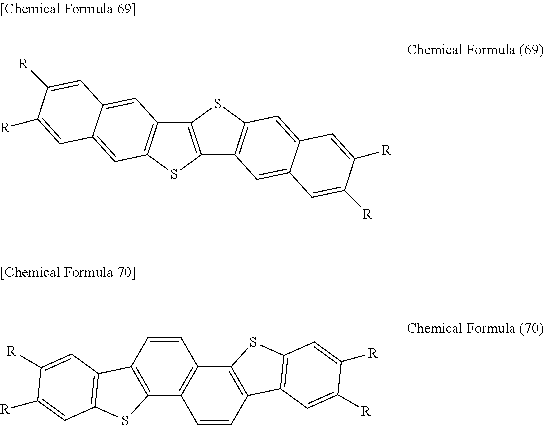

16. The solid-state imaging element according to claim 1, wherein
the third organic semiconductor is a substance represented by the following chemical formula (4) or (71).

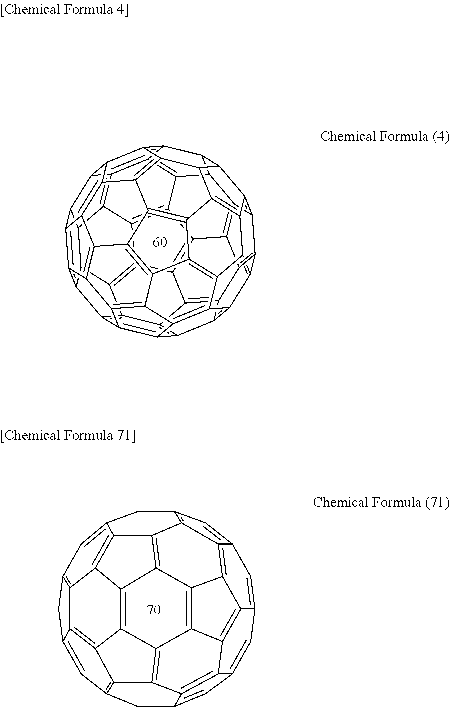

17. The solid-state imaging element according to claim 1, wherein
the first organic semiconductor, the second organic semiconductor, and the third organic semiconductor are mixed at a predetermined ratio, and a film of each of the first organic semiconductor, the second organic semiconductor, and the third organic semiconductor is formed at a predetermined film formation rate so as to form the organic photoelectric conversion layer.

18. The solid-state imaging element according to claim 17, wherein
the third organic semiconductor is mixed at a ratio of about 20% of the organic photoelectric conversion layer, and each of the first organic semiconductor and the second organic semiconductor is mixed at a ratio of about 40% of the organic photoelectric conversion layer.

19. A method for manufacturing a solid-state imaging element, the method comprising:
a first step of forming a first electrode;
a second step of forming an organic photoelectric conversion layer on an upper layer of the first electrode; and
a third step of forming a second electrode on an upper layer of the organic photoelectric conversion layer, wherein
the organic photoelectric conversion layer includes at least a first organic semiconductor, a second organic semiconductor, and a third organic semiconductor,
the first organic semiconductor is a perylene derivative having characteristics of absorbing blue light and represented by the following chemical formula (11),
the second organic semiconductor is a semiconductor having characteristics of absorbing blue light and also having characteristics as a hole transport material having crystallinity, and
the third organic semiconductor is a fullerene derivative.

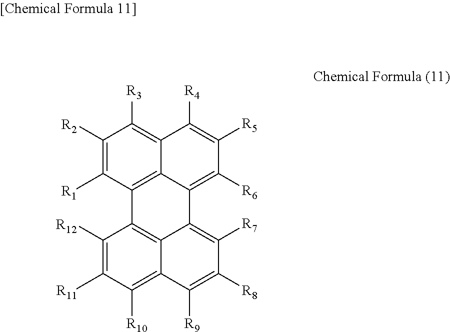

20. A solid-state imaging apparatus comprising an organic photoelectric conversion element including at least two electrodes, wherein
an organic photoelectric conversion layer is disposed between the two electrodes,
the organic photoelectric conversion layer includes at least a first organic semiconductor, a second organic semiconductor, and a third organic semiconductor,
the first organic semiconductor is a perylene derivative having characteristics of absorbing blue light and represented by the following chemical formula (11),
the second organic semiconductor is a semiconductor having characteristics of absorbing blue light and also having characteristics as a hole transport material having crystallinity,
the third organic semiconductor is a fullerene derivative, and
R1 to R12 in the chemical formula (11) are each independently selected from the group consisting of a hydrogen atom, a halogen atom, a linear, branched, or cyclic alkyl group, a thioalkyl group, a thioaryl group, an arylsulfonyl group, an alkylsulfonyl group, an amino group, an alkylamino group, an arylamino group, a hydroxy group, an alkoxy group, an acylamino group, an acyloxy group, an aryl group, a heteroaryl group, a carboxy group, a carboxoamide group, a carboalkoxy group, an acyl group, a sulfonyl group, a cyano group, and a nitro group. [chemical structure]
